(19) United States
(12) Patent Application Publication
(10) Pub. No.: US 2025/0231489 A1
(43) Pub. Date: Jul. 17, 2025

(54) RESIST UNDERLAYER FILM-FORMING COMPOSITION

(71) Applicant: NISSAN CHEMICAL CORPORATION, Tokyo (JP)

(72) Inventor: Hikaru TOKUNAGA, Toyama-shi (JP)

(73) Assignee: NISSAN CHEMICAL CORPORATION, Tokyo (JP)

(21) Appl. No.: 19/171,969

(22) Filed: Apr. 7, 2025

Related U.S. Application Data
(63) Continuation-in-part of application No. PCT/JP2023/036072, filed on Oct. 3, 2023.

(30) Foreign Application Priority Data
Oct. 6, 2022 (JP) 2022-161866

(51) Int. Cl. G03F 7/11; C09D 161/32

(52) U.S. Cl. CPC G03F 7/11; C09D 161/32

(57) ABSTRACT

[Problem] The purpose of the present invention is to provide a resist underlayer film-forming composition that can further improve properties of a resist underlayer film, such as curing properties, heat resistance, etching resistance, planarization properties and embedding properties. [Solution] Provided is a resist underlayer film-forming composition characterized by containing a solvent and a novolac resin containing a side chain having a structure represented by formula (D). In formula (D), Ar² is an aromatic ring. Formula (D): —O—Ar². The novolac resin contains a conjugated unit structure A-B represented by formula (AB). A unit structure A contains a phenol unit structure and/or an amine unit structure.

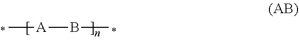

### TECHNICAL FIELD

The present invention relates to a resist underlayer film-forming composition, a resist underlayer film obtained by baking a coating film formed of the composition, and a method for producing a semiconductor device using the composition.

### BACKGROUND ART

Production of semiconductor devices involves microfabrication through a lithography process. It is known that the lithography process has such a problem that when a resist layer on a substrate is exposed to an ultraviolet laser such as a KrF excimer laser or an ArF excimer laser, a resist pattern having a desired shape is not formed due to standing waves caused by reflection of the ultraviolet laser on the surface of the substrate. In order to solve such a problem, a method has been used in which a resist underlayer film (anti-reflective coating) is interposed between a substrate and a resist layer. It is known that various organic resins are used for compositions for forming a resist underlayer film.

Also, a lithography process intended to reduce the thickness of a resist layer to form a finer resist pattern is known in which at least two layers are formed as resist underlayer films, and the resist underlayer films are used as a mask material. Examples of a material for forming the at least two layers include organic resins (e.g., acrylic resins, novolac resins, polyether resins, polyester resins), silicon resins (e.g., organopolysiloxanes), and inorganic silicon compounds (e.g., SiON, SiO₂). When dry etching is performed using, as a mask, a pattern formed by the organic resin layer, the pattern is required to have etching resistance against an etching gas (e.g., fluorocarbon, oxygen).

As an example of a composition for forming such a resist underlayer film, Patent Document 1 discloses a resist underlayer film-forming composition containing a solvent and a polymer having a structural unit of the following Formula (1):

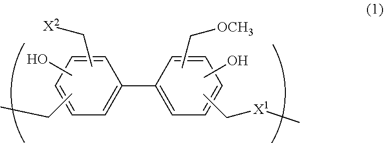

(wherein X¹ is a C₆₋₂₀ divalent organic group having at least one aromatic ring that is not substituted or substituted with a halogeno group, a nitro group, an amino group, or a hydroxy group and X² is a methoxy group or a C₆₋₂₀ organic group having at least one aromatic ring that is not substituted or substituted with a halogeno group, a nitro group, an amino group, or a hydroxy group).

Patent Document 2 discloses a resist underlayer film-forming composition containing a polymer containing two or more structural units that are the same or different from each other and that have a methoxymethyl group and a ROCH₂— group (R is a monovalent organic group, a hydrogen atom, or a mixture thereof) other than the methoxymethyl group and a linking group that links the structural units.

Patent Document 3 reports that a resist underlayer film-forming composition containing an epoxy resin having a methylol moiety, two or more film materials that can crosslink with the epoxy resin, an acid catalyst, and a solvent has excellent embeddability, and it is possible to provide a crosslinking agent for forming a resist underlayer film that is used in a lithography process and has high dry etching resistance and heat resistance.

### PRIOR ART DOCUMENTS

### Patent Documents

Patent Document 1: WO2014-171326
Patent Document 2: WO2021-172295
Patent Document 3: JP 2020-148891 A

### SUMMARY OF THE INVENTION

### Problem to be Solved by the Invention

However, with the rapid progress of semiconductor production processes, there are strong demands for higher-quality resist underlayer films or resist underlayer films having improved characteristics. For example, resist underlayer films are required to have characteristics such as curability, heat resistance, etching resistance, flattenability, and embeddability, but these characteristics still have room for improvement.

### Means for Solving the Problem

The present invention is conceived to solve the above problem. Specifically, the present invention includes the following aspects.

A first aspect of the present invention relates to a resist underlayer film-forming composition characterized by comprising a novolac resin containing a side chain having a structure of the following Formula (D) and a solvent:

—O—Ar² Formula (D)

(wherein Ar² is an aromatic ring).

A second aspect of the present invention relates to the resist underlayer film-forming composition according to the first aspect, wherein Ar² is an aromatic ring having an aromatic hydrocarbon ring and/or an aromatic heterocycle.

A third aspect of the present invention relates to the resist underlayer film-forming composition according to the second aspect, wherein
the aromatic hydrocarbon ring is an aromatic hydrocarbon ring including a benzene structure, a naphthalene structure, an anthracene structure, a pyrene structure, a phenanthrene structure, a fluorene structure, a benzofluorene structure, or a dibenzofluorene structure, and
the aromatic heterocycle is an aromatic heterocycle including an indole structure, a phenylindole structure, a carbazole structure, an indolocarbazole structure, a furan structure, a thiophene structure, a pyrrole structure, or a phenothiazine structure.

A fourth aspect of the present invention relates to the resist underlayer film-forming composition according to the second aspect, wherein
the aromatic hydrocarbon ring is benzene, naphthalene, anthracene, pyrene, phenanthrene, fluorene, benzofluorene, or dibenzofluorene, and
the aromatic heterocycle is any one selected from among indole, phenylindole, carbazole, indolocarbazole, furan, thiophene, pyrrole, and phenothiazine.

A fifth aspect of the present invention relates to the resist underlayer film-forming composition according to the first aspect, wherein Ar² is an aromatic ring having an aromatic hydrocarbon ring and/or an aromatic heterocycle substituted with —CH₂—OR¹² (wherein R¹² is a hydrogen atom or a linear, branched, or cyclic alkyl group that has a carbon atom number of 1 to 20 and that arbitrarily contains a heteroatom such as a nitrogen atom, an oxygen atom, or a sulfur atom).

A sixth aspect of the present invention relates to the resist underlayer film-forming composition according to the fifth aspect, wherein R¹² is a hydrogen atom or a methyl group.

A seventh aspect of the present invention relates to the resist underlayer film-forming composition according to the fifth aspect, wherein
the aromatic hydrocarbon ring is an aromatic hydrocarbon ring including a benzene structure, a naphthalene structure, an anthracene structure, a pyrene structure, a phenanthrene structure, a fluorene structure, a benzofluorene structure, or a dibenzofluorene structure, and
the aromatic heterocycle is an aromatic heterocycle including an indole structure, a phenylindole structure, a carbazole structure, an indolocarbazole structure, a furan structure, a thiophene structure, a pyrrole structure, or a phenothiazine structure.

An eighth aspect of the present invention relates to the resist underlayer film-forming composition according to the fifth aspect, wherein
the aromatic hydrocarbon ring is benzene, naphthalene, anthracene, pyrene, phenanthrene, fluorene, benzofluorene, or dibenzofluorene, and
the aromatic heterocycle is any one selected from among indole, phenylindole, carbazole, indolocarbazole, furan, thiophene, pyrrole, and phenothiazine.

A ninth aspect of the present invention relates to the resist underlayer film-forming composition according to the first aspect, wherein the novolac resin is a novolac resin that has a repeating composite unit structure A-B of the following Formula (AB) and further has a side chain having a structure of Formula (D):

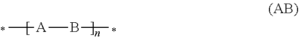

### (in Formula (AB),

n is the number of composite unit structures A-B,
a unit structure A includes a phenol unit structure and/or an amine unit structure,
a unit structure B is one or two or more unit structures each including a structure of the following Formula (B1), (B2), or (B3), and
an asterisk * denotes a bond);

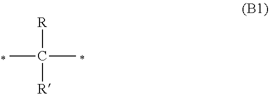

### [in Formula (B1),

R and R′ are each independently a hydrogen atom, a C₆₋₃₀ aromatic ring residue that arbitrarily has a substituent, a C₃₋₃₀ heterocycle residue that arbitrarily has a substituent, or a linear, branched, or cyclic alkyl group that has a carbon atom number of 10 or less and arbitrarily has a substituent, and
an asterisk * denotes a bond];

*-J¹-Z⁰-J²-* (B2)

### [in Formula (B2),

Z⁰ is a C₆₋₃₀ aromatic ring residue that arbitrarily has a substituent, an aliphatic ring residue, or an organic group in which two aromatic ring residues or aliphatic ring residues are linked by a single bond,
J¹ and J² are each independently a direct bond or a divalent organic group that arbitrarily has a substituent, and
an asterisk * denotes a bond];

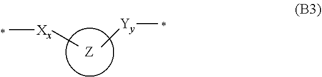

### [in Formula (B3),

Z is a C₄₋₂₅ monocycle that arbitrarily has a substituent or a C₄₋₂₅ bicyclic, tricyclic, or tetracyclic condensed ring that arbitrarily has a substituent, the monocycle is a non-aromatic monocycle, at least one monocycle constituting the bicyclic, tricyclic, or tetracyclic condensed ring is a non-aromatic monocycle and a residual monocycle is an aromatic monocycle or a non-aromatic monocycle, the monocycle or the bicyclic, tricyclic, or tetracyclic condensed ring is arbitrarily further condensed with one or more aromatic rings to form a pentacyclic or higher polycyclic condensed ring,
X and Y are same or different from each other and are each a —CR¹R² group in which R¹ and R² are same or different from each other and are each a hydrogen atom or a C₁₋₆ hydrocarbon group,
x and y are respectively the number of Xs and the number of Ys and are each independently 0 or 1,
—Xₓ
binds to any one of carbon atoms (referred to as a “carbon atom 1”) constituting the non-aromatic monocycle of Z (when x=1) or extends from the carbon atom 1 (when x=0),
Y_{y}—*
binds to any one of carbon atoms (referred to as a “carbon atom 2”) constituting the non-aromatic monocycle of Z (when y=1) or extends from the carbon atom 2 (when y=0),
the carbon atom 1 and the carbon atom 2 are arbitrarily same or different from each other, and when the carbon atom 1 and the carbon atom 2 are different, the carbon atom 1 and the carbon atom 2 arbitrarily belong to a same non-aromatic monocycle or different non-aromatic monocycles, and
an asterisk * denotes a bond].

A tenth aspect of the present invention relates to the resist underlayer film-forming composition according to the ninth aspect, wherein
the phenol unit structure is a chemical structure having at least one aromatic ring that is selected from among a benzene ring, a naphthalene ring, an anthracene ring, a pyrene ring, a fluorene ring, a benzofluorene ring, and a dibenzofluorene ring and that has at least one hydroxyl group bound to the aromatic ring, and
the aromatic rings are arbitrarily condensed with each other or arbitrarily bound to each other by a single bond or a linear, branched, or cyclic alkyl group having a carbon atom number of 1 to 8.

An eleventh aspect of the present invention relates to the resist underlayer film-forming composition according to the ninth aspect, wherein
the phenol unit structure includes a structure derived from at least one monomer selected from the group consisting of monomers of the following Formulas 1 to 36 that each arbitrarily have a substituent, and
H in OH in Formulas 1 to 36 is arbitrarily replaced with any one of substituents shown below.

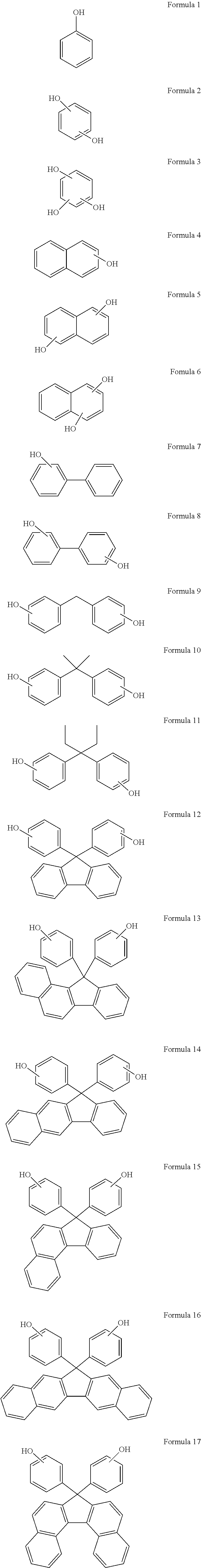

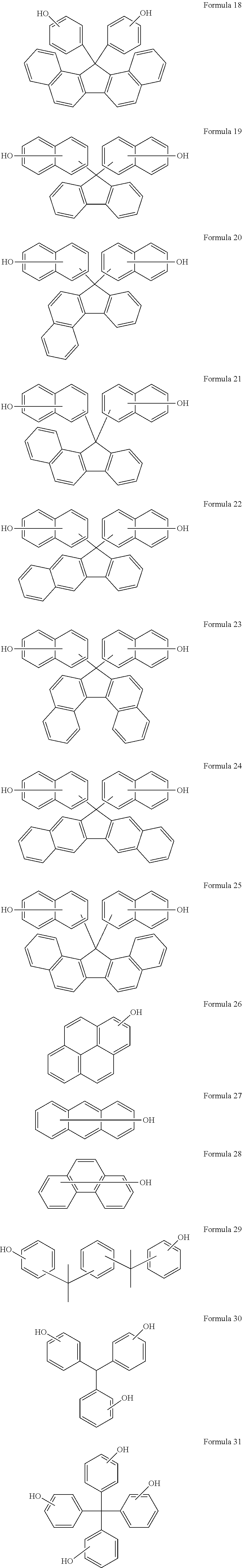

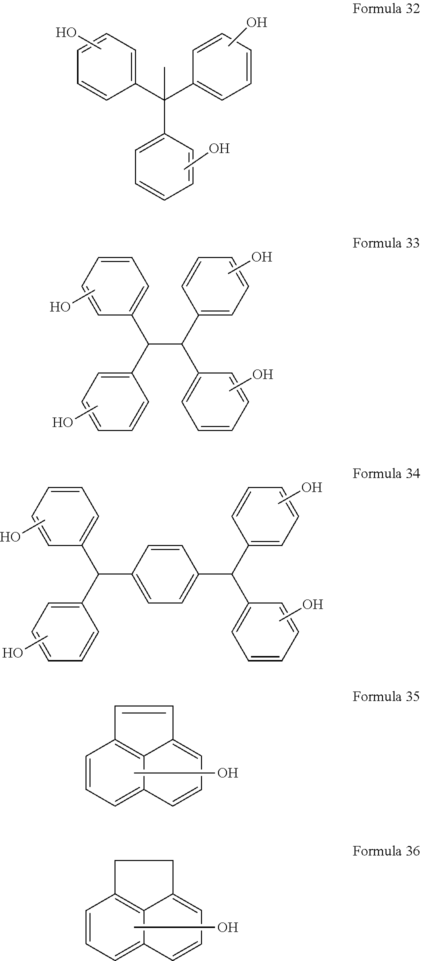

### Substituents

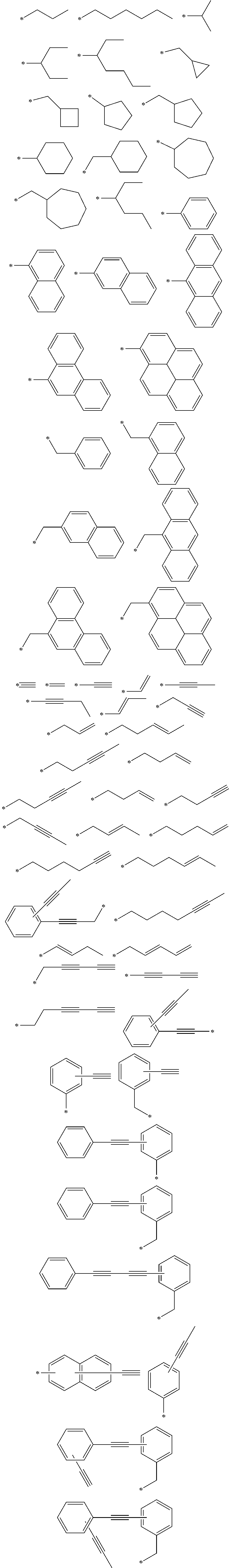

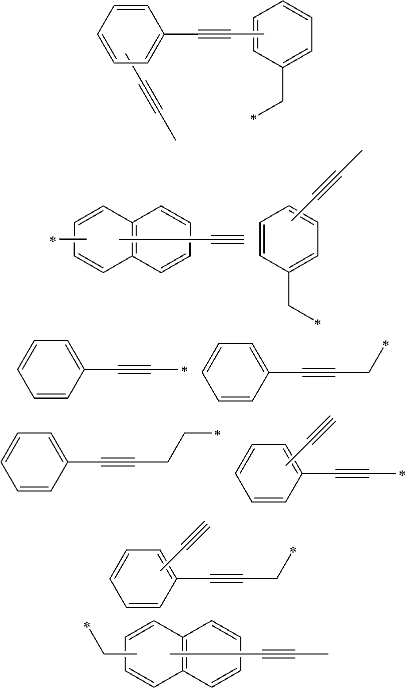

An asterisk * denotes a bond.

### Substituents

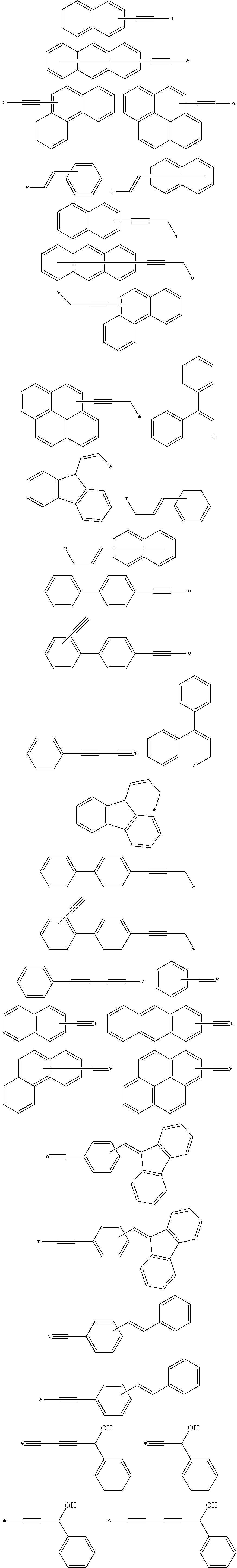

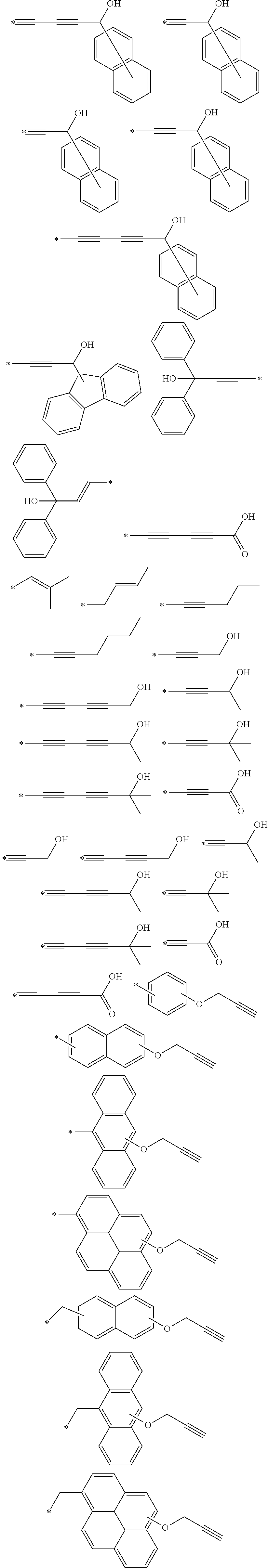

An asterisk * denotes a bond.

A twelfth aspect of the present invention relates to the resist underlayer film-forming composition according to the ninth aspect, wherein the amine unit structure is a chemical structure having at least one heterocycle selected from among a pyrrole ring, an indole ring, and a carbazole ring or a unit structure in which two or more benzene rings or two or more naphthalene rings as aromatic rings are bound to each other through a nitrogen atom or the heterocycle and an aromatic ring are condensed with each other or the heterocycle and an aromatic ring are bound through a single bond, a quaternary carbon, or a C₅₋₇ aliphatic ring or condensed with each other.

A thirteenth aspect of the present invention relates to the resist underlayer film-forming composition according to the ninth aspect, wherein
the amine unit structure includes a structure derived from at least one monomer selected from the group consisting of monomers of the following Formulas 37 to 75 that each arbitrarily have a substituent, and
H in NH in Formulas 37 to 75 is replaced with any one of substituents shown below.

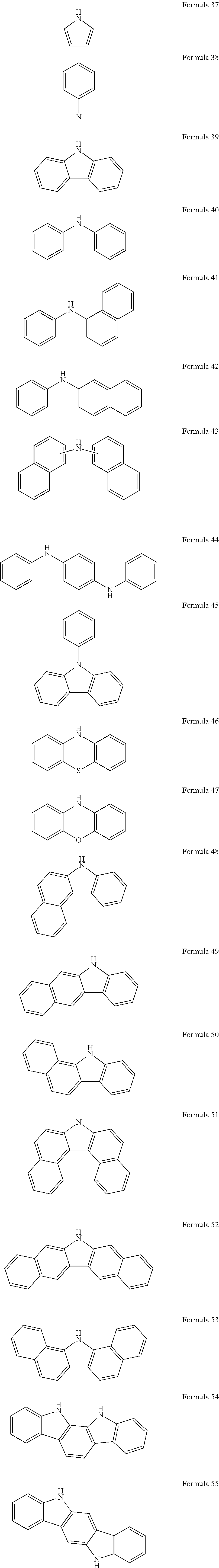

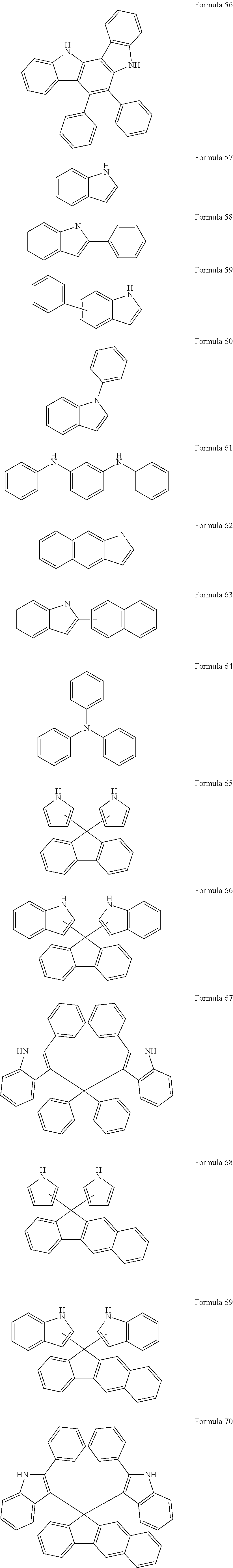

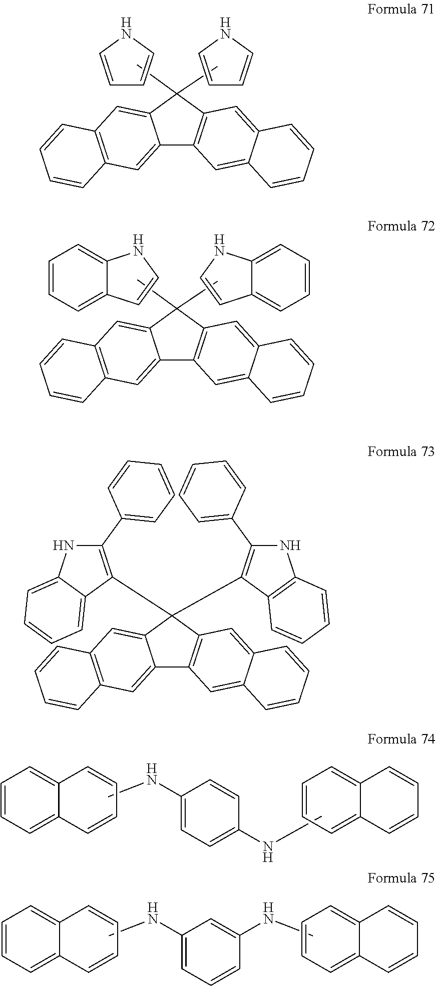

### Substituents

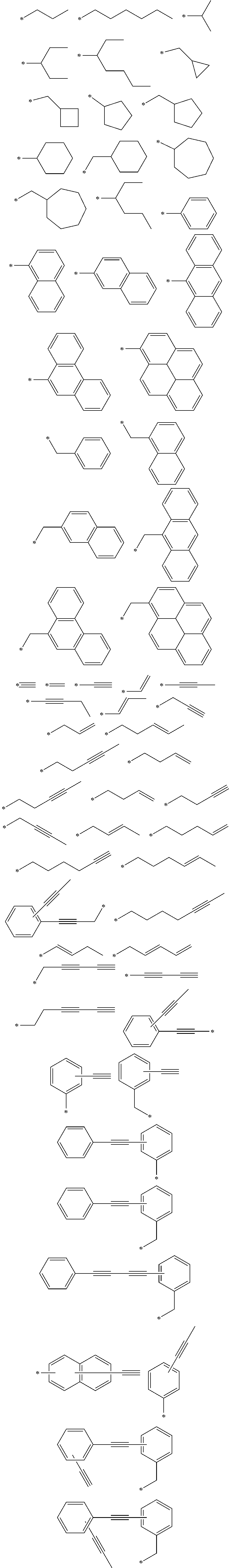

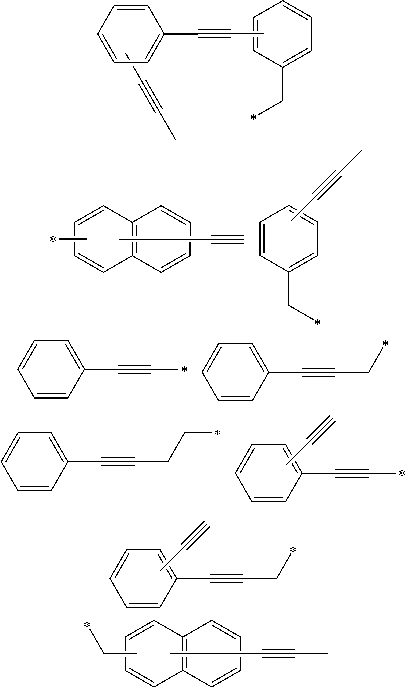

An asterisk * denotes a bond.

### Substituents

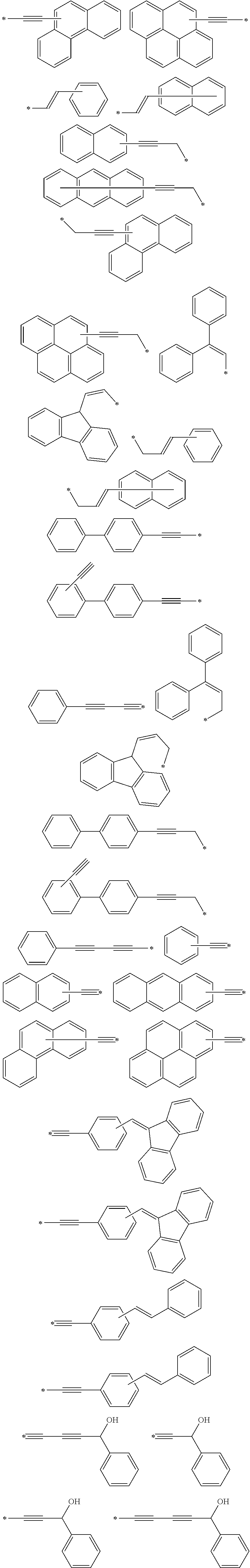

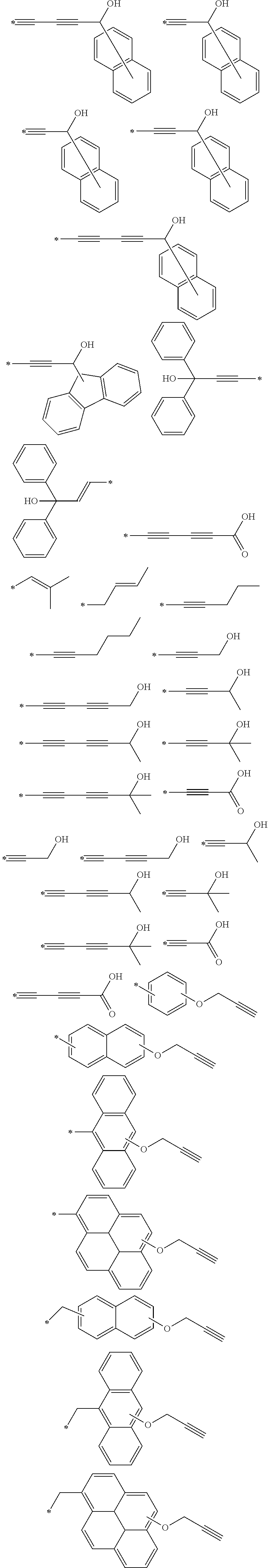

An asterisk * denotes a bond.

A fourteenth aspect of the present invention relates to the resist underlayer film-forming composition according to the first aspect, wherein the solvent is a solvent having a boiling point of 160° C., or more.

A fifteenth aspect of the present invention relates to the resist underlayer film-forming composition according to the first aspect, further comprising a crosslinking agent.

A sixteenth aspect of the present invention relates to the resist underlayer film-forming composition according to the fifteenth aspect, wherein the crosslinking agent is an aminoplast crosslinking agent or a phenoplast crosslinking agent.

A seventeenth aspect of the present invention relates to the resist underlayer film-forming composition according to the first aspect, further comprising a surfactant.

An eighteenth aspect of the present invention relates to the resist underlayer film-forming composition according to the first aspect, further comprising an acid and/or a salt of the acid and/or an acid generator.

A nineteenth aspect of the present invention relates to a resist underlayer film obtained by baking a coating film formed of the composition according to any one of the first aspect to the eighteenth aspect.

A twentieth aspect of the present invention relates to a method for forming a resist pattern for use in production of a semiconductor, the method comprising the step of applying the resist underlayer film-forming composition according to any one of the first aspect to the eighteenth aspect onto a semiconductor substrate and baking the composition to form a resist underlayer film.

A twenty-first aspect of the present invention relates to a method for producing a semiconductor device, the method comprising the steps of:
forming a resist underlayer film on a semiconductor substrate with use of the resist underlayer film-forming composition according to any one of the first aspect to the eighteenth aspect;
forming a resist film on the resist underlayer film;
forming a resist pattern in the resist film;
subjecting the resist underlayer film to etching using the resist pattern; and
subjecting the semiconductor substrate to processing using the patterned resist underlayer film.

A twenty-second aspect of the present invention relates to the method for producing a semiconductor device according to the twenty-first aspect, wherein the forming of a resist pattern in the resist film is performed by light or electron beam irradiation and development.

A twenty-third aspect of the present invention relates to the method for producing a semiconductor device according to the twenty-first aspect, wherein the forming of a pattern in the resist film is performed by nanoimprinting or a self-assembled film.

A twenty-fourth aspect of the present invention relates to a method for producing a semiconductor device, the method comprising the steps of:
forming a resist underlayer film on a semiconductor substrate with use of the resist underlayer film-forming composition according to any one of the first aspect to the eighteenth aspect;
forming a hard mask on the resist underlayer film;
further forming a resist film on the hard mask;
forming a resist pattern in the resist film;
subjecting the hard mask to etching using the resist pattern;
subjecting the resist underlayer film to etching using the patterned hard mask; and
subjecting the semiconductor substrate to processing using the patterned resist underlayer film.

A twenty-fifth aspect of the present invention relates to the method for producing a semiconductor device according to the twenty-fourth aspect, wherein the hard mask is formed by application of an inorganic material or vapor deposition of an inorganic material.

A twenty-sixth aspect of the present invention relates to the method for producing a semiconductor device according to the twenty-fourth aspect, wherein the forming of a resist pattern in the resist film is performed by light or electron beam irradiation and development.

A twenty-seventh aspect of the present invention relates to the method for producing a semiconductor device according to the twenty-fourth aspect, wherein the forming of a pattern in the resist film is performed by nanoimprinting or a self-assembled film.

A twenty-eighth aspect of the present invention relates to a method for producing a semiconductor device, the method comprising the steps of:
forming a resist underlayer film on a semiconductor substrate with use of the resist underlayer film-forming composition according to any one of the first aspect to the eighteenth aspect;
forming a hard mask on the resist underlayer film;
further forming a resist film on the hard mask;
forming a resist pattern in the resist film;
subjecting the hard mask to etching using the resist pattern;
subjecting the resist underlayer film to etching using the patterned hard mask;
removing the hard mask; and
subjecting the semiconductor substrate to processing using the patterned resist underlayer film.

A twenty-ninth aspect of the present invention relates to the method for producing a semiconductor device according to the twenty-eighth aspect, wherein the hard mask is formed by application of a composition containing an inorganic material or vapor deposition of a composition containing an inorganic material.

A thirtieth aspect of the present invention relates to the method for producing a semiconductor device according to the twenty-eighth aspect, wherein the forming of a resist pattern in the resist film is performed by light or electron beam irradiation and development.

A thirty-first aspect of the present invention relates to the method for producing a semiconductor device according to the twenty-eighth aspect, wherein the forming of a pattern in the resist film is performed by nanoimprinting or a self-assembled film.

A thirty-second aspect of the present invention relates to the method for producing a semiconductor device according to the twenty-eighth aspect, wherein the removing of the hard mask is performed by etching or an alkali solution.

A thirty-third aspect of the present invention relates to a method for producing a semiconductor device, the method comprising the steps of:
forming a resist underlayer film on a semiconductor substrate with use of the resist underlayer film-forming composition according to any one of the first aspect to the eighteenth aspect;
forming a hard mask on the resist underlayer film;
further forming a resist film on the hard mask;
forming a resist pattern in the resist film;
subjecting the hard mask to etching using the resist pattern;
subjecting the resist underlayer film to etching using the patterned hard mask;
removing the hard mask;
forming a vapor-deposited film (spacer) on the resist underlayer film after removing the hard mask;
processing the vapor-deposited film (spacer) by etching;
removing the patterned resist underlayer film such that the patterned vapor-deposited film (spacer) remains; and
subjecting the semiconductor substrate to processing using the patterned vapor-deposited film (spacer).

A thirty-fourth aspect of the present invention relates to the method for producing a semiconductor device according to the thirty-third aspect, wherein the hard mask is formed by application of a composition containing an inorganic material or vapor deposition of a composition containing an inorganic material.

A thirty-fifth aspect of the present invention relates to the method for producing a semiconductor device according to the thirty-third aspect, wherein the forming of a resist pattern in the resist film is performed by light or electron beam irradiation and development.

A thirty-sixth aspect of the present invention relates to the method for producing a semiconductor device according to the thirty-third aspect, wherein the forming of a pattern in the resist film is performed by nanoimprinting or a self-assembled film.

A thirty-seventh aspect of the present invention relates to the method for producing a semiconductor device according to the thirty-third aspect, wherein the removing of the hard mask is performed by etching or an alkali solution.

### Effects of the Invention

The novolac resin having a methylol ether side chain according to the present invention exhibits self-crosslinkability by itself without containing a crosslinking agent or a curing catalyst and therefore can exhibit adequate curability even in an atmosphere of nitrogen as compared to a novolac resin having no methylol ether side chain. Therefore, adequate curability can be achieved not only in an atmosphere of air in which the novolac resin is usually used but also in an atmosphere of nitrogen. This makes it possible to widely use the novolac resin in semiconductor production processes that have become diverse. Further, the novolac resin has high heat resistance and therefore exhibits excellent applicability onto a silicon wafer even during high-temperature baking, and also has high etching resistance. Further, the novolac resin exhibits excellent applicability even onto various vapor-deposited substrates having a stepped surface and therefore also has excellent flattenability and embeddability. By changing the skeleton of the novolac resin or a skeleton to be methylolated, an optical constant can be adjusted to an appropriate value for suppressing reflection during exposure.

### MODES FOR CARRYING OUT THE INVENTION

A resist underlayer film-forming composition according to the present invention is characterized by including a novolac resin having a methylol ether structure in its side chain and a solvent. The resist underlayer film-forming composition may further include a crosslinking agent, an acid generator, or a surfactant.

Hereinbelow, each of the components will be described in detail.

### Definitions of Terms

The definitions of major terms related to the novolac resin according to one aspect of the present invention used herein will be described below. Unless otherwise specified, the definitions of the terms related to the novolac resin are as follows.

### “Novolac Resin”

The term “novolac resin” is used not only in a narrow sense to refer to a phenol/formaldehyde resin (a so-called novolac-type phenol resin) or an aniline/formaldehyde resin (a so-called novolac-type aniline resin) but also in a broad sense including various polymers generally formed, in the presence of an acid catalyst or under reaction conditions equivalent to it, through covalent bond formation (e.g., substitution reaction, addition reaction, condensation reaction, or addition-condensation reaction) between an organic compound having a functional group that allows covalent binding to an aromatic ring [e.g., an aldehyde group, a ketone group, an acetal group, a ketal group, a hydroxyl group or an alkoxy group bound to a secondary or tertiary carbon, a hydroxyl group, an alkoxy group, or a halo group bound to an α-carbon atom (e.g., a benzyl-position carbon atom) of an alkylaryl group; a carbon-carbon unsaturated bond in divinylbenzene or dicyclopentadiene] and an aromatic ring in an aromatic ring-containing compound (which preferably has a substituent containing a heteroatom, such as an oxygen atom, a nitrogen atom, or a sulfur atom, bound to its aromatic ring).

Therefore, the novolac resin is herein a polymer formed by linking a plurality of aromatic ring-containing compounds through covalent bond formation between an organic compound containing a carbon atom derived from the functional group described above (sometimes referred to as a “linking carbon atom”) and an aromatic ring in the aromatic ring-containing compound through the linking carbon atom.

The terms “unit structure A”, “unit structure B”, and “unit structure C” are herein used to refer to unit structures constituting the “novolac resin”. The unit structure A is a unit structure derived from a compound having an aromatic ring. The unit structure B is a unit structure derived from a compound having a functional group that allows covalent binding to the aromatic ring of the unit structure A. The unit structure C is a unit structure equivalent in binding mode to a composite unit structure A-B and is a unit structure derived from a compound having an aromatic ring and a functional group that allows covalent binding to the aromatic ring of the unit structure A. The unit structure C can be replaced with the composite unit structure A-B because its binding mode is the same as that of the composite unit structure A-B.

### “Residue”

The term “residue” refers to an organic group whose hydrogen atom attached to a carbon atom or a heteroatom (e.g., a nitrogen atom, an oxygen atom, or a sulfur atom) is replaced with a bond, and the organic group may be a monovalent group or a polyvalent group. For example, a monovalent organic group is formed by replacing one hydrogen atom with one bond, and a divalent organic group is formed by replacing two hydrogen atoms with two bonds.

### “Aromatic Ring” (Aromatic Group, Aryl Group, Arylene Group)

The term “aromatic ring” means a concept including an aromatic hydrocarbon ring, an aromatic heterocycle, and their residues [sometimes referred to as an “aromatic group”, an “aryl group” (in the case of a monovalent group), or an “arylene group” (in the case of a divalent group)], and includes not only a monocyclic aromatic ring (an aromatic monocycle) but also a polycyclic aromatic ring (an aromatic polycycle). In the case of a polycyclic aromatic ring, at least one monocycle is an aromatic monocycle, but a residual monocycle(s) forming a condensed ring with the aromatic monocycle may be a monocyclic heterocycle(s) (a heteromonocycle(s)) or a monocyclic alicyclic hydrocarbon(s) (an alicyclic monocycle(s)).

Examples of the aromatic ring include, but are not limited to: aromatic hydrocarbon rings such as benzene, indene, naphthalene, azulene, styrene, toluene, xylene, mesitylene, cumene, anthracene, phenanthrene, triphenylene, benzanthracene, pyrene, chrysene, fluorene, biphenyl, corannulene, perylene, fluoranthene, benzo[k]fluoranthene, benzo[b]fluoranthene, benzo[ghi]perylene, coronene, dibenzo[g,p]chrysene, acenaphthylene, acenaphthene, naphthacene, pentacene, and cyclooctatetraene, more typically aromatic hydrocarbon rings such as benzene, naphthalene, anthracene, phenanthrene, and pyrene; and aromatic heterocycles such as furan, thiophene, pyrrole, N-alkylpyrrole, N-arylpyrrole, imidazole, pyridine, pyrimidine, pyrazine, triazine, thiazole, indole, phenylindole, purine, quinoline, isoquinoline, chromene, thianthrene, phenothiazine, phenoxazine, xanthene, acridine, phenazine, carbazole, and indolocarbazole, typically indole, phenylindole, carbazole, indolocarbazole, furan, thiophene, pyrrole, imidazole, pyran, pyridine, pyrimidine, pyrazine, pyrrolidine, piperidine, piperazine, morpholine, and phenothiazine, more typically indole, phenylindole, carbazole, indolocarbazole, furan, thiophene, pyrrole, and phenothiazine.

The aromatic ring (e.g., a benzene ring, a naphthalene ring) may have a substituent, and examples of the substituent include a halogen atom, a saturated or unsaturated linear, branched, or cyclic hydrocarbon group (—R) (whose hydrocarbon chain may be interrupted once or more by one or more oxygen atoms and whose examples include alkyl group, alkenyl group, alkynyl group, and propargyl group), an alkoxy group or an aryloxy group (—OR wherein R is the hydrocarbon group —R described above), an alkylamino group [—NHR or —NR₂ (two Rs may be the same or different from each other) wherein R is the hydrocarbon group —R described above], a hydroxyl group, an amino group (—NH₂), a carboxyl group, a cyano group, a nitro group, an ester group (—CO₂R or —OCOR wherein R is the hydrocarbon group —R described above), an amide group [—NHCOR, —CONHR, —NRCOR (two Rs may be the same or different from each other), or —CONR₂ (two Rs may be the same or different from each other) wherein R is the hydrocarbon group —R described above], a sulfonyl group (—SO₂R wherein R is the hydrocarbon group —R described above), a sulfonic acid group (—SO₃H), a sulfide group (—SR wherein R is the hydrocarbon group —R described above), a thiol group (—SH), an ether bond-containing organic group [an ether compound residue represented by R¹¹—O—R¹¹ (R¹¹s are each independently a C₁₋₆ alkyl group such as a methyl group or an ethyl group, a phenyl group, a naphthyl group, an anthranil group, or a pyrenyl group); e.g., an ether bond-containing organic group containing a methoxy group, an ethoxy group, or a phenoxy group], and an aryl group.

The aromatic ring may also be an organic group having a condensed ring between one or more aromatic rings (e.g., benzene, naphthalene, anthracene, pyrene) and one or more aliphatic rings or heterocycles. Examples of the aliphatic rings include cyclobutane, cyclobutene, cyclopentane, cyclopentene, cyclohexane, cyclohexene, methylcyclohexane, methylcyclohexene, cycloheptane, and cycloheptene, and examples of the heterocycles include furan, thiophene, pyrrole, imidazole, pyran, pyridine, pyrimidine, pyrazine, pyrrolidine, piperidine, piperazine, and morpholine.

The aromatic ring may also be an organic group having a structure in which two or more aromatic rings are linked by a divalent linking group such as an alkylene group.

### “Heterocycle”

The term “heterocycle” includes both an aliphatic heterocycle and an aromatic heterocycle and means a concept including not only a monocyclic heterocycle (a heteromonocycle) but also a polycyclic heterocycle (a heteropolycycle). In the case of a polycyclic heterocycle, at least one monocycle is a heteromonocycle, but a residual monocycle(s) may be an aromatic hydrocarbon monocycle(s) or an alicyclic monocycle(s). For examples of the aromatic heterocycle, refer to the above definition of the term “aromatic ring”. Similarly to the aromatic ring described above with reference to the term “aromatic ring”, the heterocycle may have a substituent.

### “Non-Aromatic Ring” (Aliphatic Ring)

The term “non-aromatic monocycle” refers to a monocyclic hydrocarbon that does not belong to aromatic series and typically refers to a monocycle of an alicyclic compound. The non-aromatic monocycle may be referred to also as an aliphatic monocycle (which may be an aliphatic heteromonocycle and may contain an unsaturated bond as long as it does not belong to aromatic compounds). Similarly to the aromatic ring described above with reference to the term “aromatic ring”, the non-aromatic monocycle may have a substituent.

Examples of the non-aromatic monocycle (aliphatic ring, aliphatic monocycle) include cyclopropane, cyclobutane, cyclobutene, cyclopentane, cyclopentene, cyclohexane, methylcyclohexane, cyclohexene, methylcyclohexene, cycloheptane, and cycloheptene.

The term “non-aromatic polycycle” refers to a polycyclic hydrocarbon that does not belong to aromatic series and typically refers to a polycycle of an alicyclic compound. The non-aromatic polycycle may be referred to also as an aliphatic polycycle [which may be an aliphatic heteropolycycle (whose at least one monocycle is an aliphatic heterocycle) and may contain an unsaturated bond as long as it does not belong to aromatic compounds]. The term “non-aromatic polycycle” includes a non-aromatic bicycle, a non-aromatic tricycle, and a non-aromatic tetracycle.

The term “non-aromatic bicycle” refers to a condensed ring constituted from two monocyclic hydrocarbons that do not belong to aromatic series and typically refers to a condensed ring of two alicyclic compounds. The non-aromatic bicycle is herein sometimes referred to as an aliphatic bicycle (which may be an aliphatic heterobicycle and may contain an unsaturated bond as long as it does not belong to aromatic compounds). Examples of the non-aromatic bicycle include bicyclopentane, bicyclooctane, and bicycloheptene.

The term “non-aromatic tricycle” refers to a condensed ring constituted from three monocyclic hydrocarbons that do not belong to aromatic series and typically refers to a condensed ring of three alicyclic compounds (each of which may be a heterocycle and may contain an unsaturated bond as long as it does not belong to aromatic compounds). Examples of the non-aromatic tricycle include tricyclooctane, tricyclononane, and tricyclodecane.

The term “non-aromatic tetracycle” refers to a condensed ring constituted from four monocyclic hydrocarbons that do not belong to aromatic series and typically refers to a condensed ring of four alicyclic compounds (each of which may be a heterocycle and may contain an unsaturated bond as long as it does not belong to aromatic compounds). Examples of the non-aromatic tetracycle include hexadecahydropyrene and the like.

The term “carbon atoms constituting a ring (moiety)” means carbon atoms constituting a hydrocarbon ring having no substituent (which may be any one of an aromatic ring, an aliphatic ring, and a heterocycle).

The term “hydrocarbon group” refers to a group obtained by removing one or more hydrogen atoms from a hydrocarbon, and the hydrocarbon may be any one of a saturated or unsaturated aliphatic hydrocarbon, a saturated or unsaturated alicyclic hydrocarbon, and an aromatic hydrocarbon.

A chemical structural formula showing a unit structure of the novolac resin may herein include a bond (denoted by *) for convenience. Unless otherwise specified, such a bond can be at any bindable position in the unit structure, and a binding position in the unit structure is not limited.

### <Resist Underlayer Film-Forming Composition>

The resist underlayer film-forming composition according to one aspect of the present invention includes a specific novolac resin and a solvent.

### <Novolac Resin>

The novolac resin includes a composite unit structure A-B of the following Formula (AB).

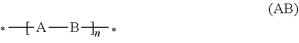

in Formula (AB), n is the number of composite unit structures A-B, a unit structure A is a divalent organic group including a phenol unit structure and/or an amine unit structure, and a unit structure B has a structure described below.

### <Unit Structure A>

The unit structure A is a structural unit having an aromatic ring. The aromatic ring preferably has a carbon atom number of 6 to 30 and more preferably has a carbon atom number of 6 to 24.

The aromatic ring is preferably at least one benzene ring, naphthalene ring, anthracene ring, or pyrene ring; or a condensed ring between a benzene ring, a naphthalene ring, an anthracene ring, or a pyrene ring and a heterocycle or an aliphatic ring.

The aromatic ring may have a substituent, and the substituent preferably contains a heteroatom. The aromatic ring may be constituted from two or more aromatic rings linked by a linking group, and the linking group preferably contains a heteroatom. Examples of the heteroatom include an oxygen atom, a nitrogen atom, and a sulfur atom.

The “aromatic ring” is preferably a C₆₋₃₀ or C₆₋₂₄ organic group that contains, on or in its ring or between its rings, at least one heteroatom selected from among a nitrogen atom, a sulfur atom, and an oxygen atom.

Examples of the heteroatom on its ring include: a nitrogen atom contained in an amino group (e.g., a propargylamino group) or a cyano group; an oxygen atom contained in an oxygen-containing substituent such as a formyl group, a hydroxyl group, a carboxyl group, or an alkoxy group (e.g., a propargyloxy group); and a nitrogen atom and an oxygen atom contained in an oxygen- and nitrogen-containing substituent such as a nitro group. Examples of the heteroatom in its ring include an oxygen atom contained in xanthene and a nitrogen atom contained in carbazole. Examples of the heteroatom contained in a linking group between its two or more aromatic rings include a nitrogen atom, an oxygen atom, and a sulfur atom contained in bonds such as —NH—, —NHCO—, —O—, —COO—, —CO—, —S—, —SS—, and —SO₂—.

The unit structure A is preferably a unit structure having an aromatic ring having the oxygen-containing substituent described above, a unit structure having two or more aromatic rings linked by —NH—, or a unit structure having a condensed ring between one or more aromatic hydrocarbon rings and one or more heterocycles.

The unit structure A preferably includes a phenol unit structure and/or an amine unit structure.

The phenol unit structure is a chemical structure having at least one aromatic ring that is selected from among a benzene ring, a naphthalene ring, an anthracene ring, a pyrene ring, a fluorene ring, a benzofluorene ring, and a dibenzofluorene ring and that has at least one hydroxyl group bound to the aromatic ring, and the aromatic rings may be condensed with each other or may be bound to each other by a single bond or a linear, branched, or cyclic alkyl group having a carbon atom number of 1 to 8.

The amine unit structure is a chemical structure having at least one heterocycle selected from among a pyrrole ring, an indole ring, and a carbazole ring or a unit structure in which two or more benzene rings or two or more naphthalene rings as aromatic rings are bound to each other through a nitrogen atom or the heterocycle and an aromatic ring are condensed with each other or the heterocycle and an aromatic ring are bound through a single bond, a quaternary carbon, or a C₅₋₇ aliphatic ring or condensed with each other.

Examples of a monomer having such a phenol unit structure and examples of a monomer having such an amine unit structure are as shown below.

It should be noted that structures shown below are examples, and the number of hydroxyl groups of each of the compounds having at least one aromatic ring that may have a hydroxyl group as a substituent is not limited to that of the structure of the compound shown below as a specific example and substitution with hydroxyl groups may be performed to the extent that it is theoretically possible, and any substituent described below that can theoretically bind to an aromatic ring may also bind to an aromatic ring(s) of each of the structures shown below.

### (Examples of Monomer Having Phenol Unit Structure)

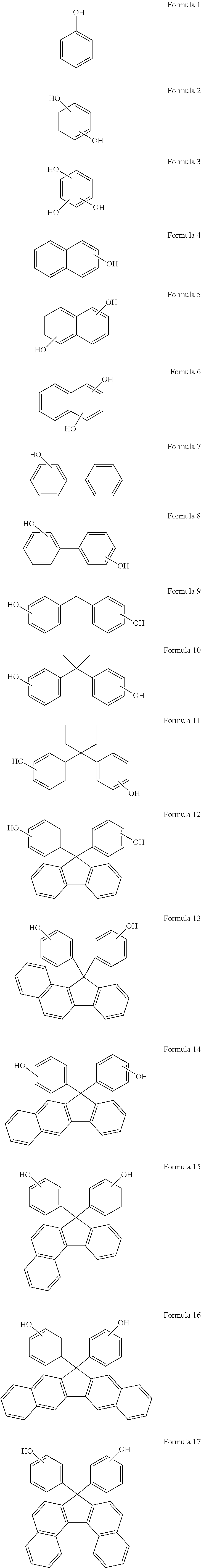

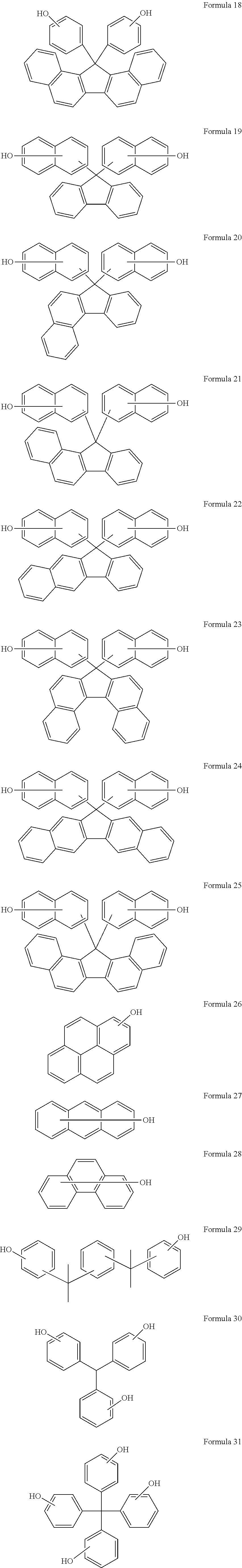

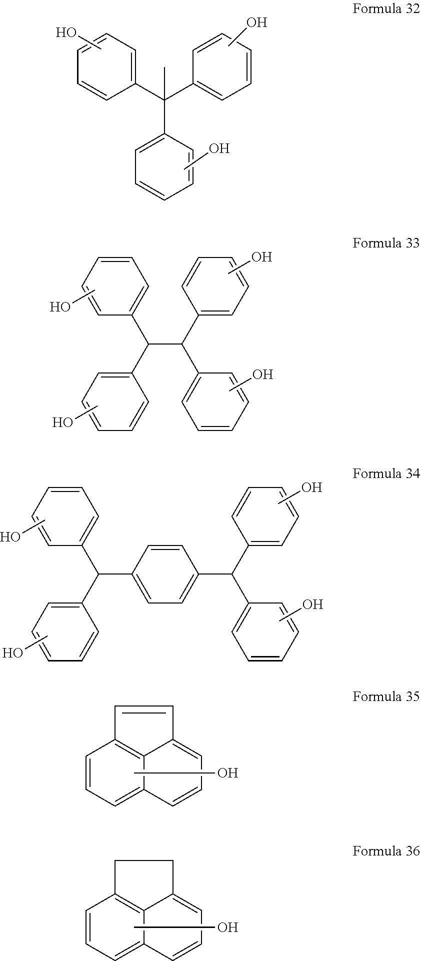

### (Examples of Monomer Having Amine Unit Structure)

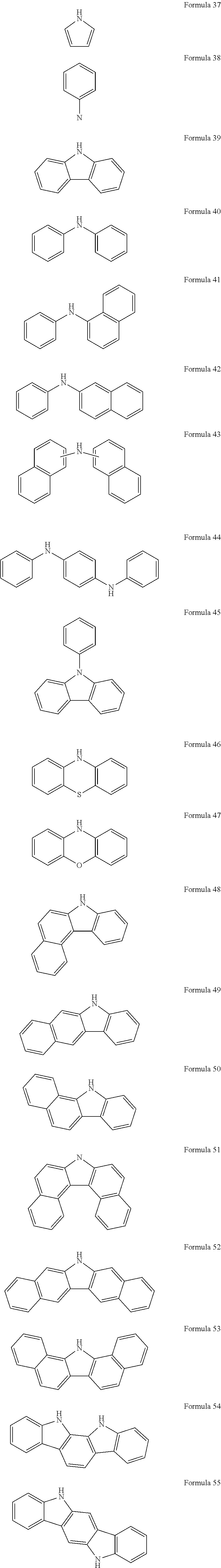

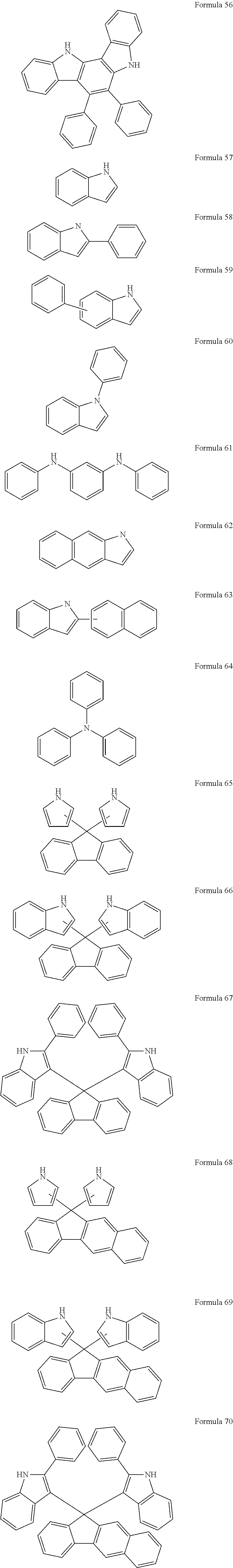

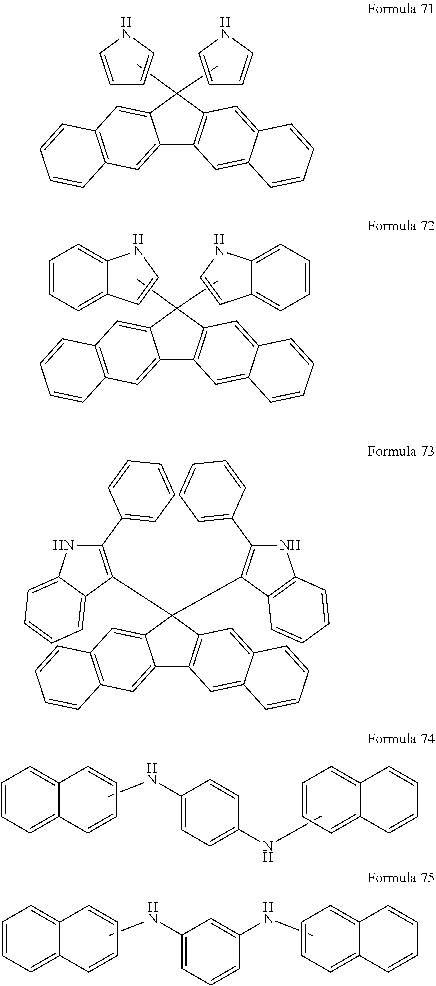

Further, H in NH in each of the monomers having an amine unit structure shown above and H in OH in each of the monomers having a phenol unit structure shown above may be replaced with any one of substituents shown below.

### Substituents

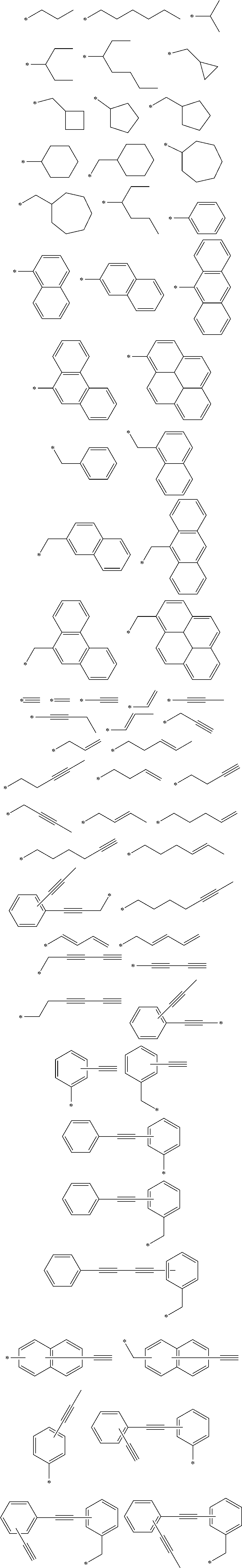

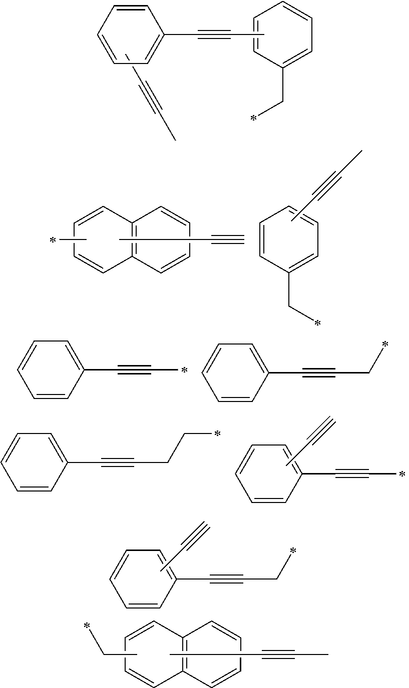

An asterisk * denotes a bond.

### Substituents

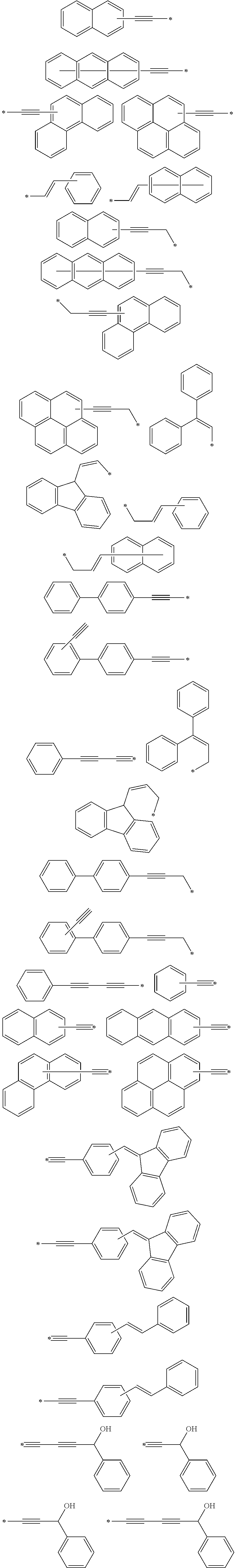

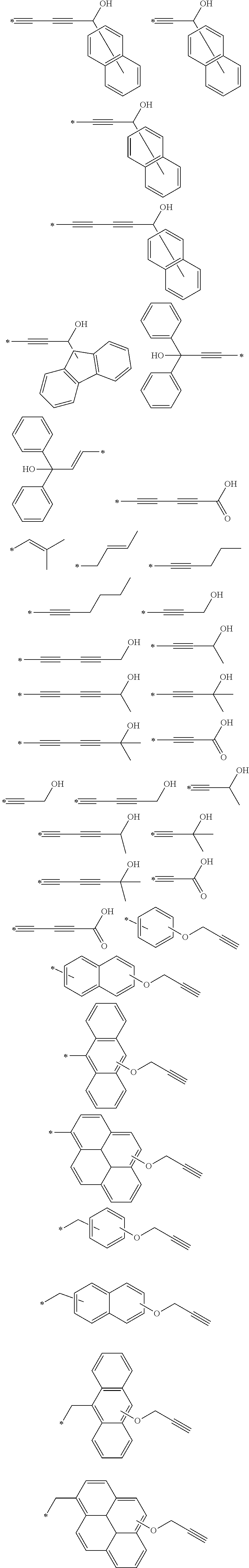

An asterisk * denotes a bond.

Also, the unit structure A is preferably at least one selected from among unit structures shown below. It should be noted that the positions of two bonds in each of the unit structures shown below are merely shown for convenience and are not limited, and each of the bonds can extend from any possible carbon atom.

(Examples of Unit Structure Derived from Heterocycle)

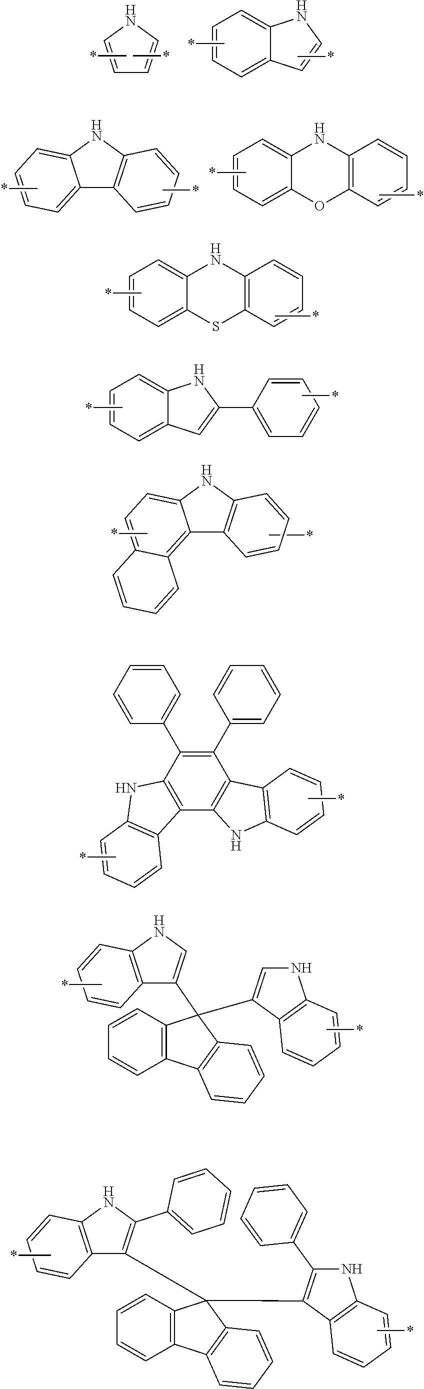

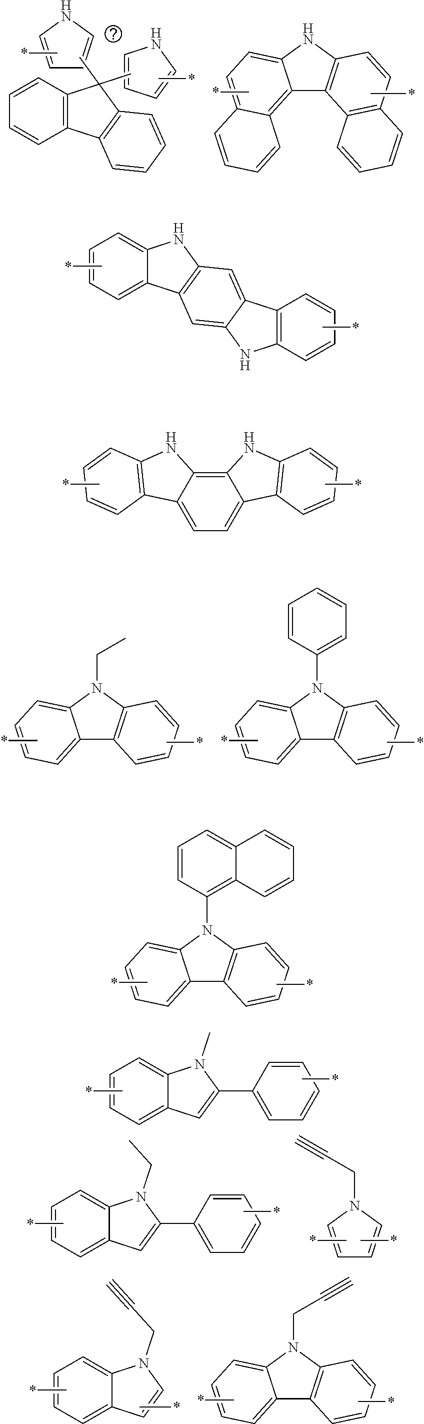

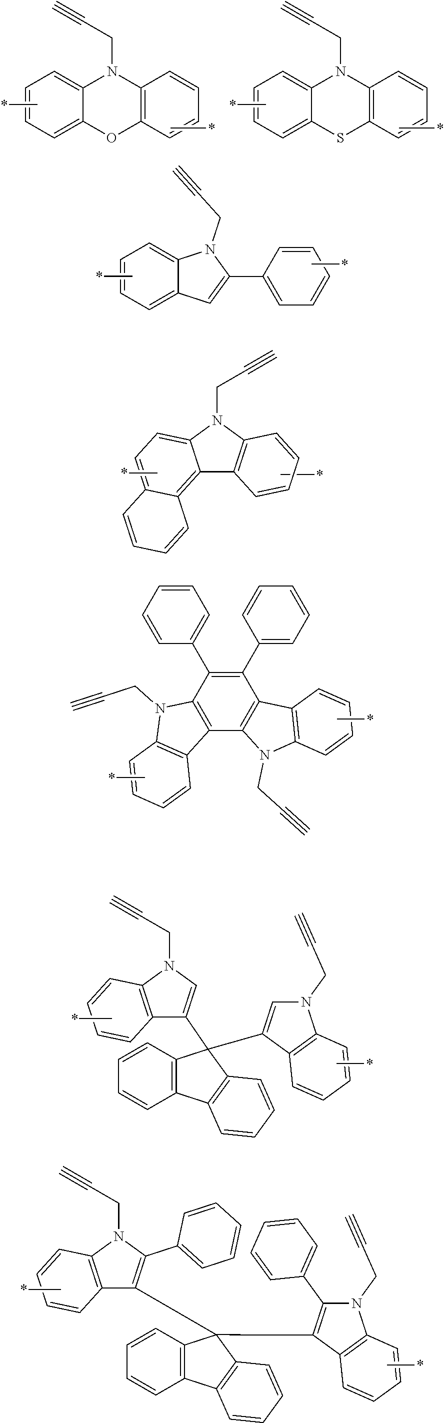

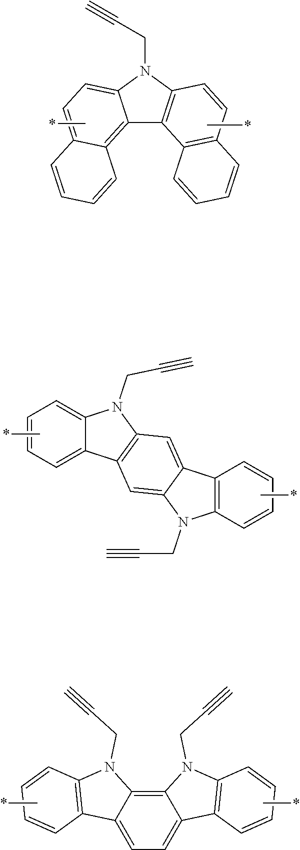

(Examples of Unit Structure Derived from Aromatic Hydrocarbon Having Oxygen-Containing Substituent)

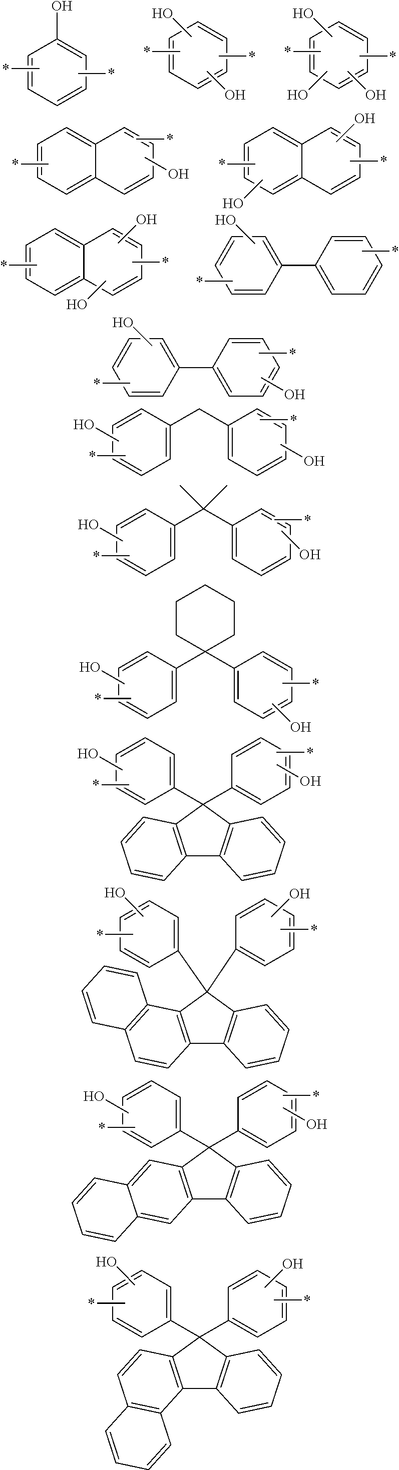

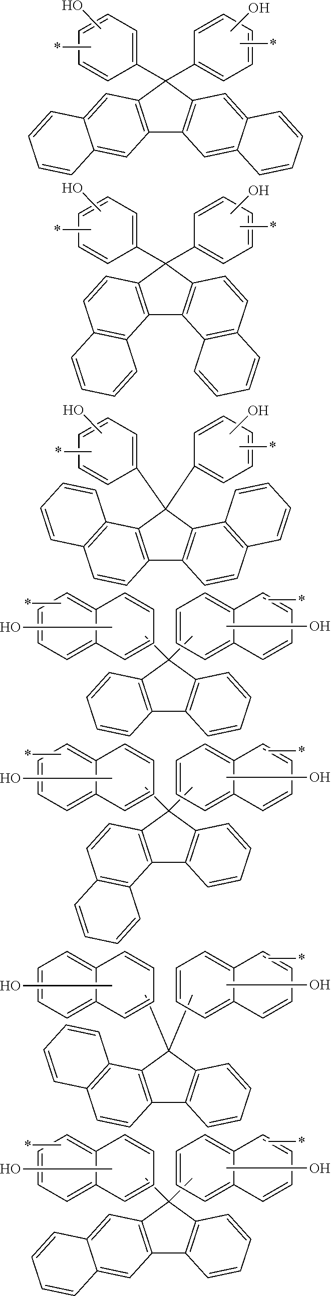

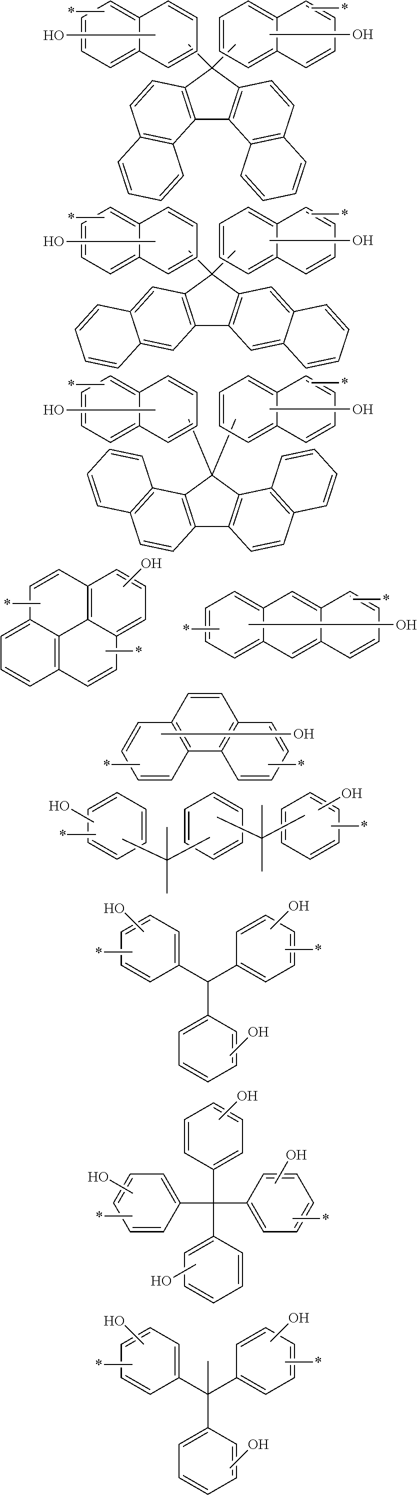

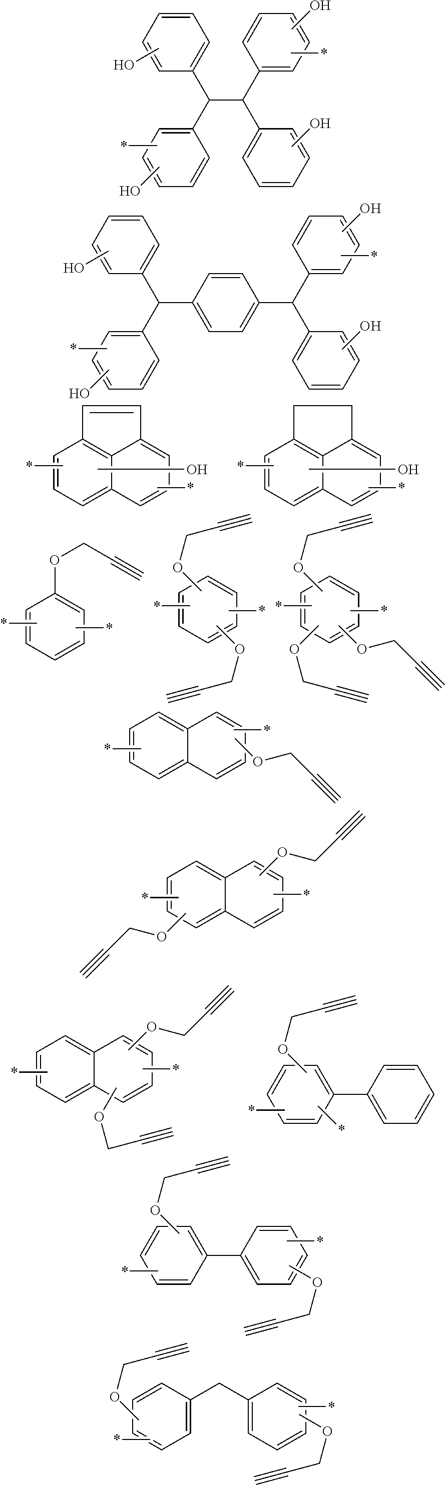

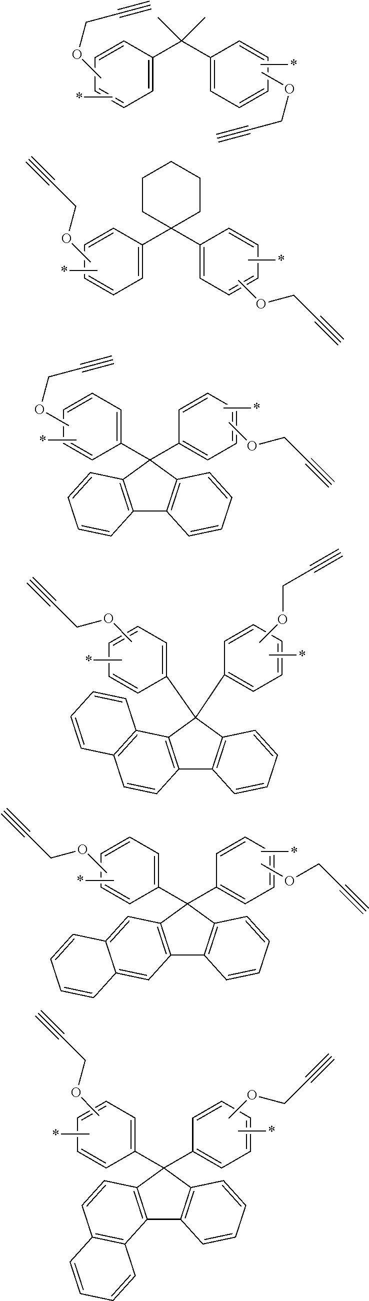

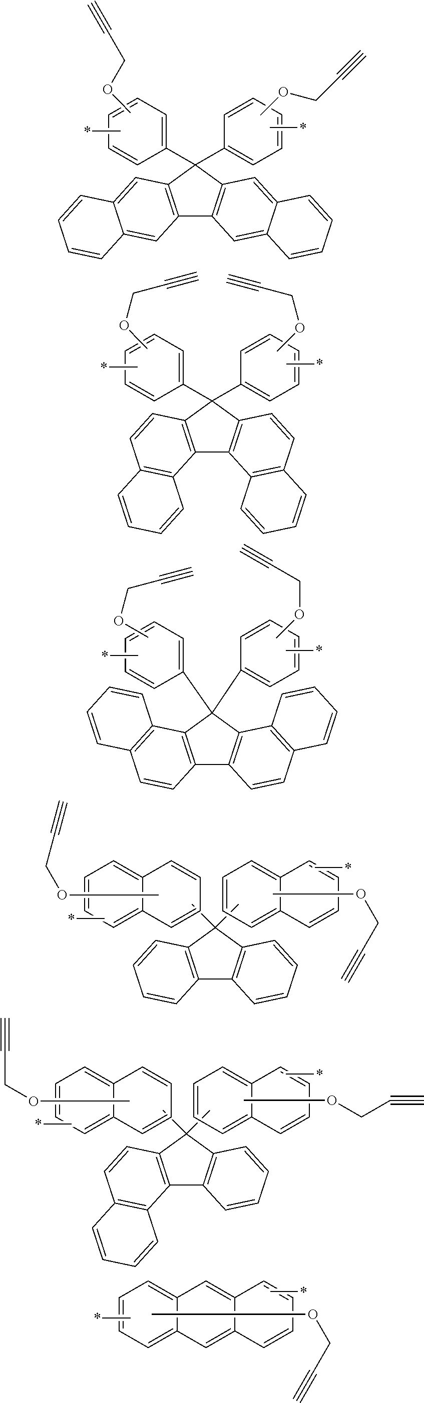

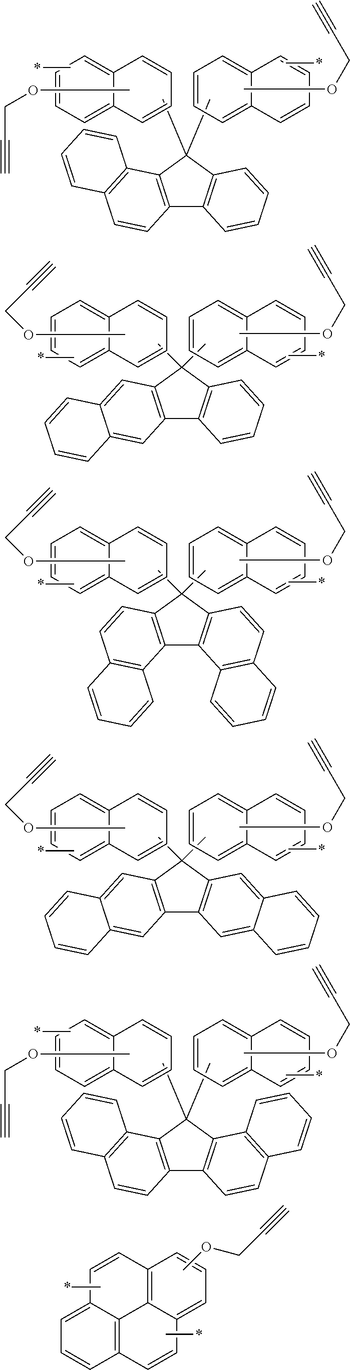

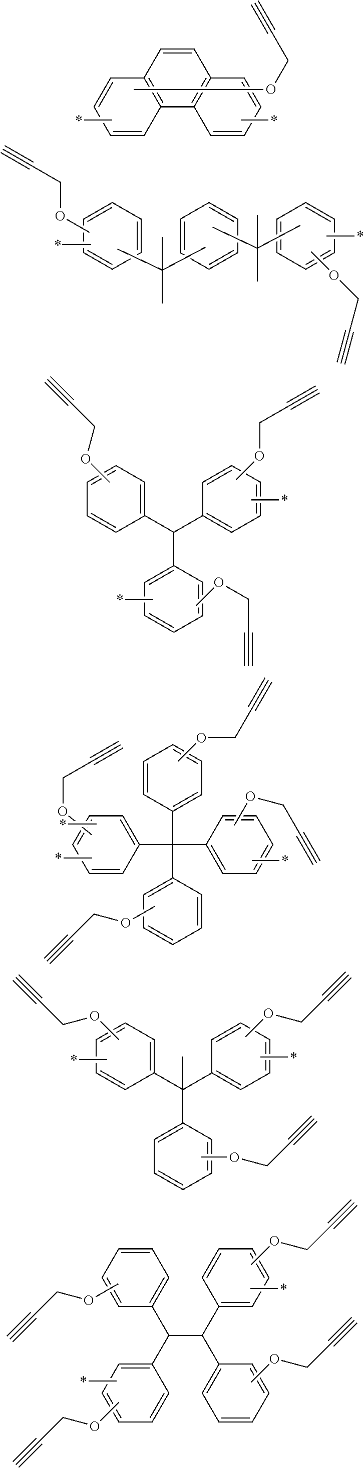

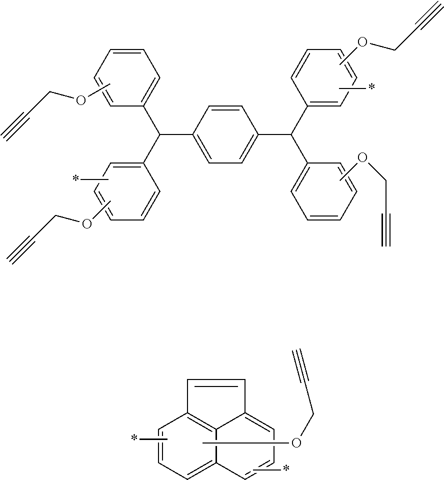

(Examples of Unit Structure Derived from Aromatic Hydrocarbons Linked by —NH—)

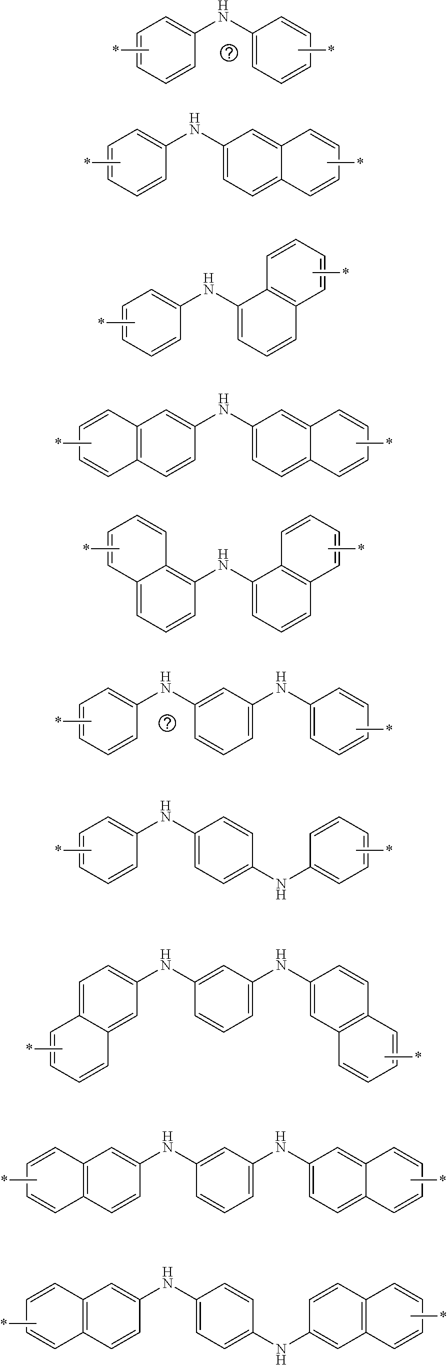

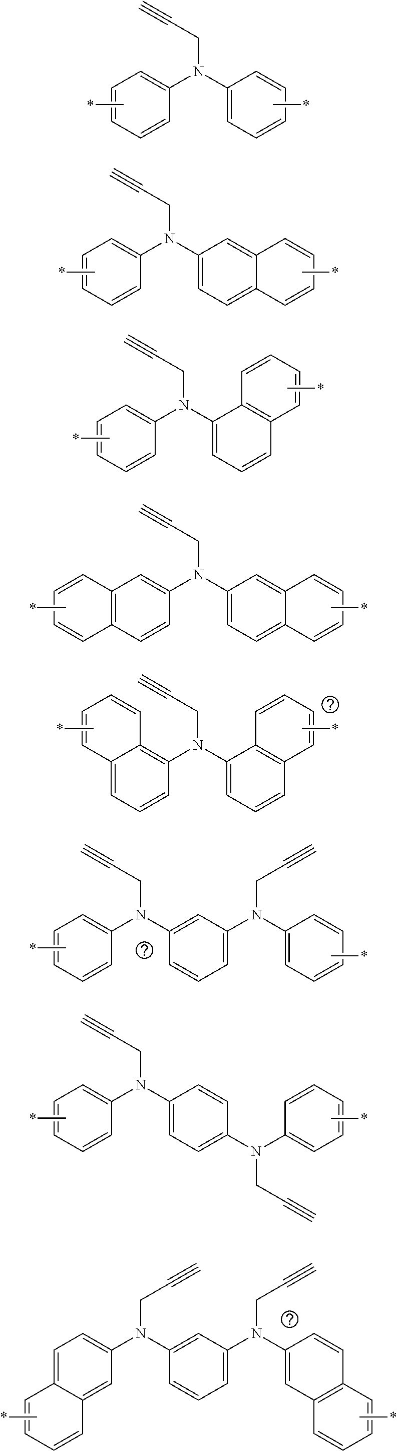

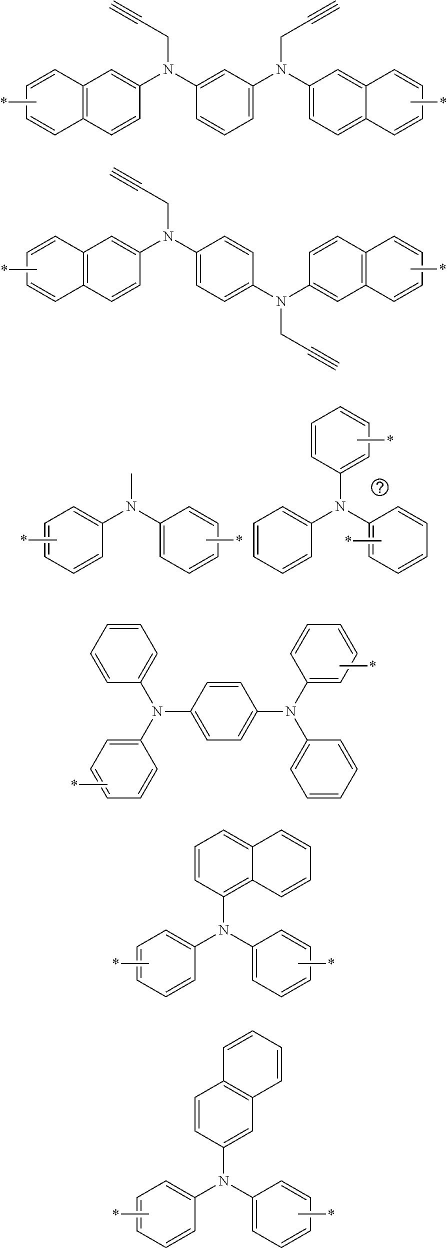

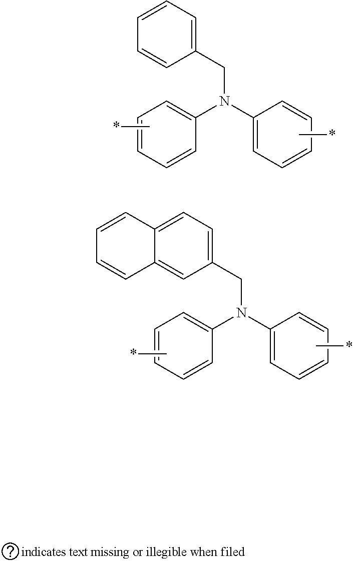

—NH— may have a structure in which a hydrogen atom on N is substituted.

### <Unit Structure B>

The unit structure B is one or two or more unit structures each containing a linking carbon atom [refer to the above section <Definitions of Terms>] that binds to the aromatic ring in the unit structure A, and includes a structure of the following Formula (B1), (B2), or (B3). The unit structure B can link two unit structures A through covalent binding to carbon atoms on the aromatic rings of the unit structures A.

At least one composite unit structure A-B may be replaced with, as a unit structure equivalent to it, one or two or more unit structures C each including a structure of the following Formula (C1), (C2), or (C3).

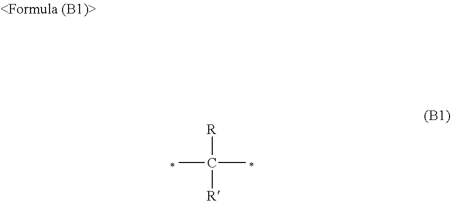

in Formula (B1),
R and R′ are each independently a hydrogen atom, a C₆₋₃₀ aromatic ring that may have a substituent, a C₃₋₃₀ heterocycle that may have a substituent, or a linear, branched, or cyclic alkyl group that has a carbon atom number of 10 or less and that may have a substituent.

Two bonds in Formula (B1) can covalently bind to the aromatic ring in the unit structure A.

For the “aromatic ring” and the “heterocycle” described in the definition of R and R′ in Formula (B1), refer to the above section “Definitions of terms”.

Examples of the “alkyl group” described in the definition of R and R′ in Formula (B1) include methyl group, ethyl group, n-propyl group, i-propyl group, cyclopropyl group, n-butyl group, i-butyl group, s-butyl group, t-butyl group, cyclobutyl group, 1-methyl-cyclopropyl group, 2-methyl-cyclopropyl group, n-pentyl group, 1-methyl-n-butyl group, 2-methyl-n-butyl group, 3-methyl-n-butyl group, 1,1-dimethyl-n-propyl group, 1,2-dimethyl-n-propyl group, 2,2-dimethyl-n-propyl group, 1-ethyl-n-propyl group, cyclopentyl group, 1-methyl-cyclobutyl group, 2-methyl-cyclobutyl group, 3-methyl-cyclobutyl group, 1,2-dimethyl-cyclopropyl group, 2,3-dimethyl-cyclopropyl group, 1-ethyl-cyclopropyl group, 2-ethyl-cyclopropyl group, n-hexyl group, 1-methyl-n-pentyl group, 2-methyl-n-pentyl group, 3-methyl-n-pentyl group, 4-methyl-n-pentyl group, 1,1-dimethyl-n-butyl group, 1,2-dimethyl-n-butyl group, 1,3-dimethyl-n-butyl group, 2,2-dimethyl-n-butyl group, 2,3-dimethyl-n-butyl group, 3,3-dimethyl-n-butyl group, 1-ethyl-n-butyl group, 2-ethyl-n-butyl group, 1,1,2-trimethyl-n-propyl group, 1,2,2-trimethyl-n-propyl group, 1-ethyl-1-methyl-n-propyl group, 1-ethyl-2-methyl-n-propyl group, cyclohexyl group, 1-methyl-cyclopentyl group, 2-methyl-cyclopentyl group, 3-methyl-cyclopentyl group, 1-ethyl-cyclobutyl group, 2-ethyl-cyclobutyl group, 3-ethyl-cyclobutyl group, 1,2-dimethyl-cyclobutyl group, 1,3-dimethyl-cyclobutyl group, 2,2-dimethyl-cyclobutyl group, 2,3-dimethyl-cyclobutyl group, 2,4-dimethyl-cyclobutyl group, 3,3-dimethyl-cyclobutyl group, 1-n-propyl-cyclopropyl group, 2-n-propyl-cyclopropyl group, 1-i-propyl-cyclopropyl group, 2-i-propyl-cyclopropyl group, 1,2,2,-trimethyl-cyclopropyl group, 1,2,3-trimethyl-cyclopropyl group, 2,2,3-trimethyl-cyclopropyl group, 1-ethyl-2-methyl-cyclopropyl group, 2-ethyl-1-methyl-cyclopropyl group, 2-ethyl-2-methyl-cyclopropyl group, 2-ethyl-3-methyl-cyclopropyl group, n-heptyl group, n-octyl group, n-nonyl group, and n-decyl group.
R and R′ are preferably each independently phenyl, naphthalenyl, anthracenyl, phenanthrenyl, naphthacenyl, or pyrenyl.

The unit structure including a structure of Formula (B1) may include, for example, a dimer or trimer structure in which two or three structures of Formula (B1) shown above, which are the same or different from each other, bind to a divalent or trivalent linking group.

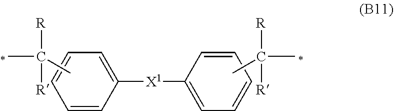

In this case, as shown below in Formula (B11), one of two bonds in each of the structures of Formula (B1) shown above binds to the linking group.

Such a linking group may be, for example, one having two or three aromatic rings (which corresponds to the unit structure A). A specific example of the divalent or trivalent linking group is a divalent linking group (L1) shown below that is also shown above in Formula (B11) as an example:

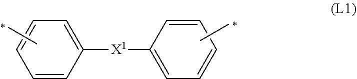

[wherein X¹ is a single bond, a methylene group, an oxygen atom, a sulfur atom, or —N(R′)— wherein R¹ is a hydrogen atom or a C₁₋₂₀ hydrocarbon group (which may be a chain hydrocarbon group or a cyclic hydrocarbon group (which may be aromatic or non-aromatic))].

Other examples include divalent or trivalent linking groups of the following Formulas (L2) and (L3):

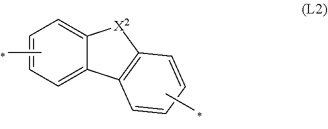

[wherein X² is a methylene group, an oxygen atom, or —N(R²)— wherein R² is a hydrogen atom, a C₁₋₁₀ aliphatic hydrocarbon group or a C₅₋₂₀ aromatic hydrocarbon group]; and

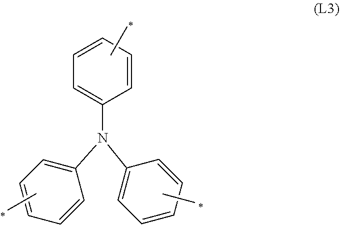

Still another example is a divalent linking group of the following Formula (L4) that is formed through addition reaction between an acetylide and a ketone so as to be covalently bind to linking carbon atoms.

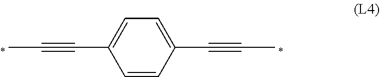

It should be noted that when at least one of R and R′ in Formula (B1) is an aromatic ring, the aromatic ring [see, for example, Ar in the following Formula (B12)] may additionally bind to another unit structure B.

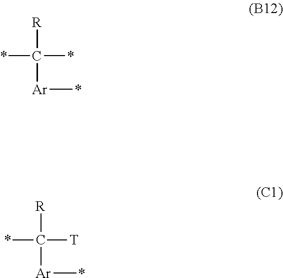

In this case, when one of the bonds of a linking carbon atom binds to a polymer terminal T (e.g., a hydrogen atom, any functional group such as a hydroxyl group or an unsaturated aliphatic hydrocarbon group, a terminal unit structure A, or a unit structure A in another polymer chain) as shown below in Formula (C1), at least one composite unit structure A-B may be replaced with, as a unit structure C equivalent to a composite unit structure A-B, a unit structure having a structure of Formula (C1). Specifically, the polymer chain may be extended by both of binding between the aromatic ring in Formula (C1) [Ar in Formula (C1)] and another unit structure B and binding to the aromatic ring of the unit structure A through the other bond of the linking carbon atom shown in Formula (C1).

Some specific examples of the unit structure B including a structure of Formula (B1) are as shown below. An asterisk * basically denotes a binding site to the unit structure A. Needless to say, the unit structure B may partially include at least one of the structures shown as examples.

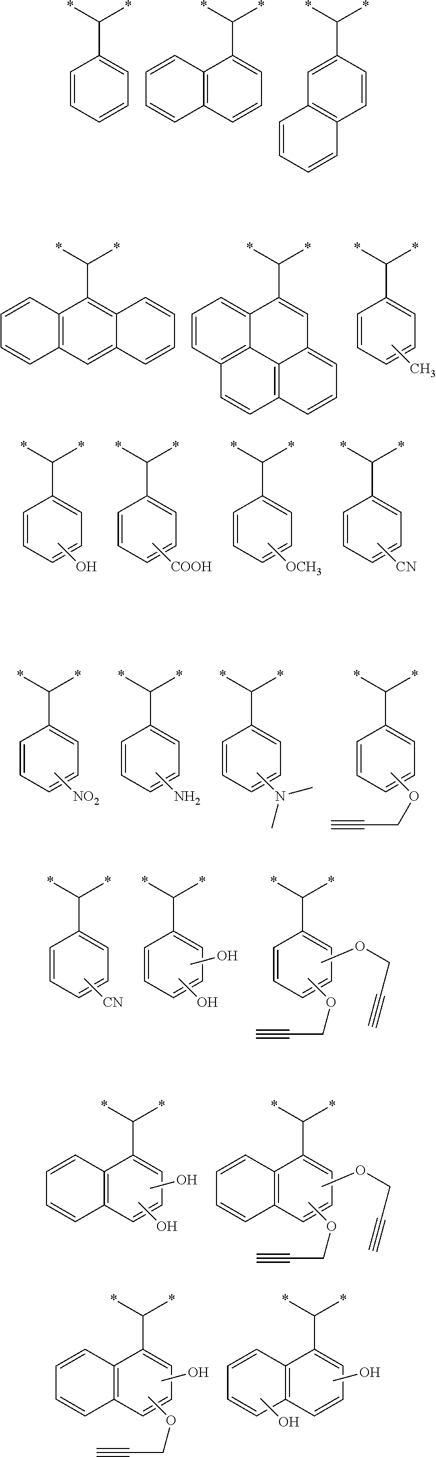

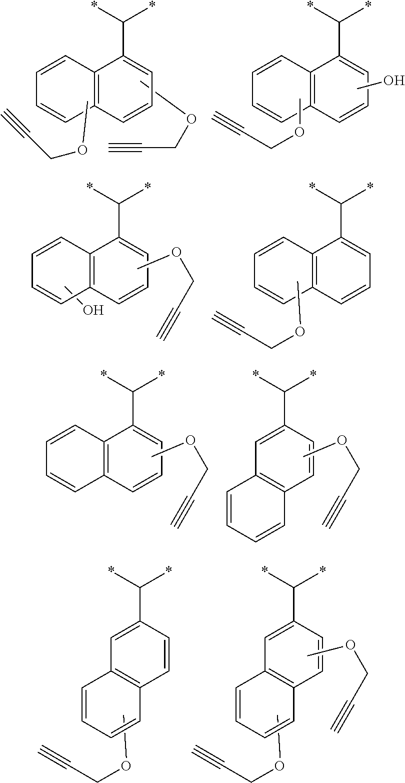

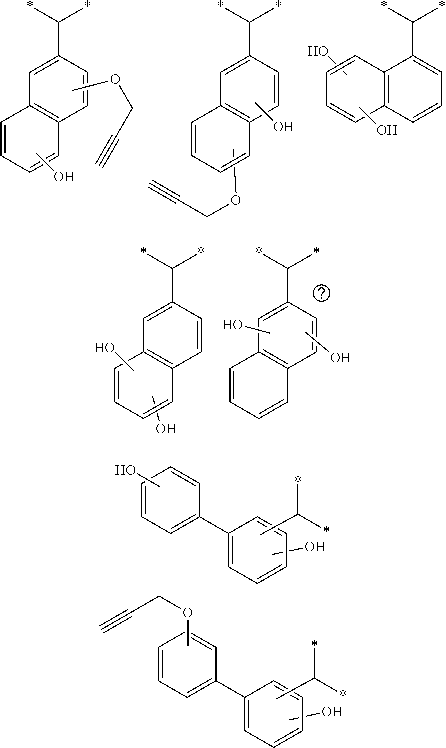

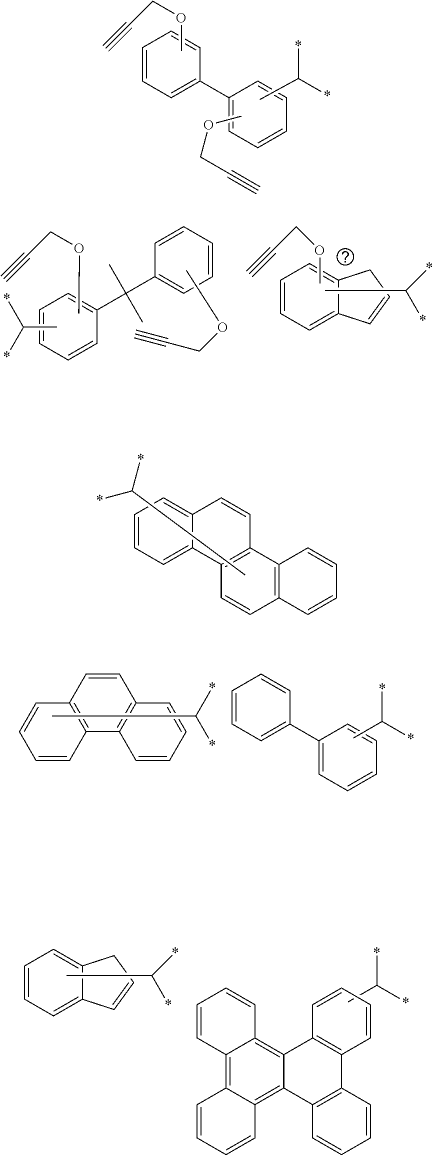

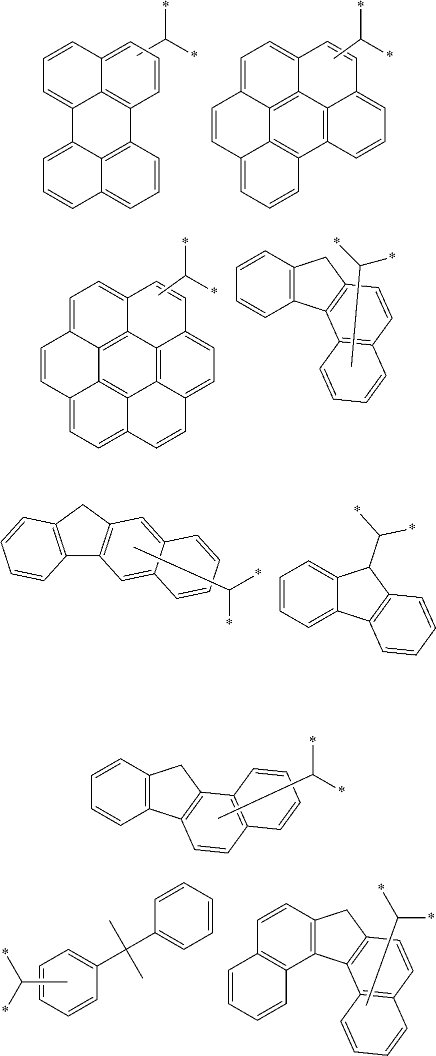

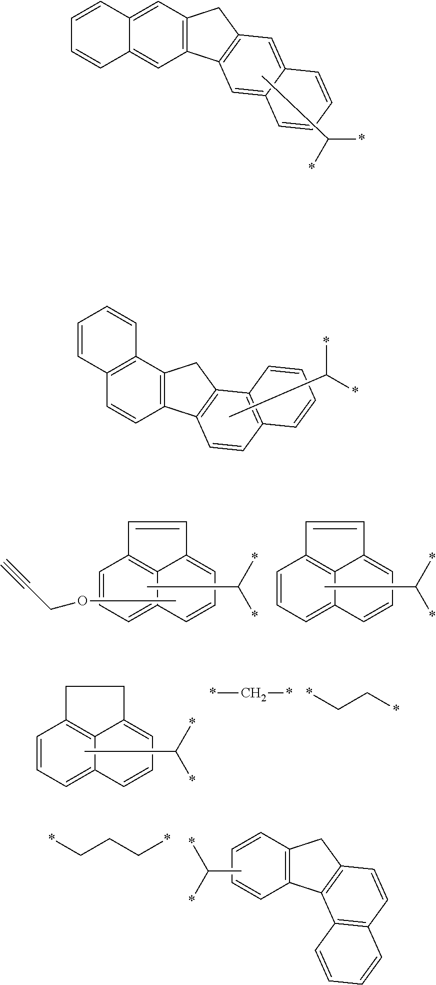

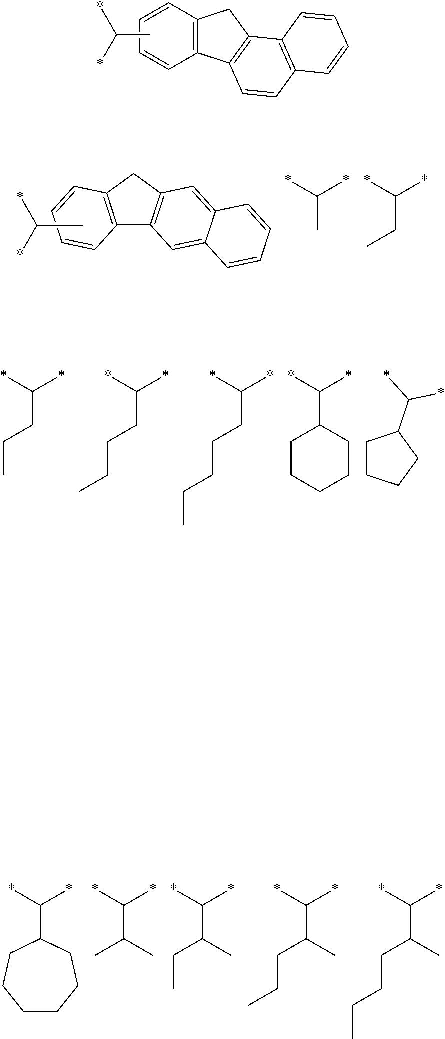

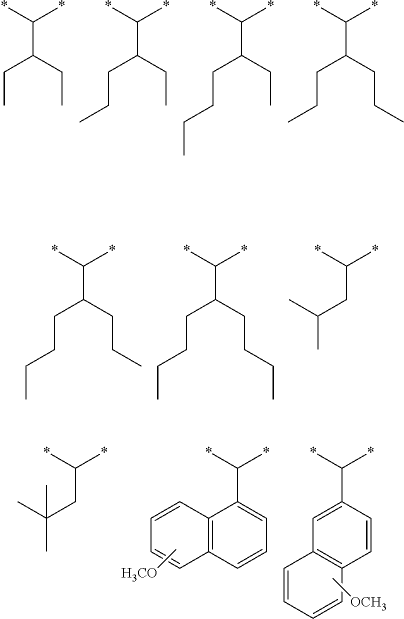

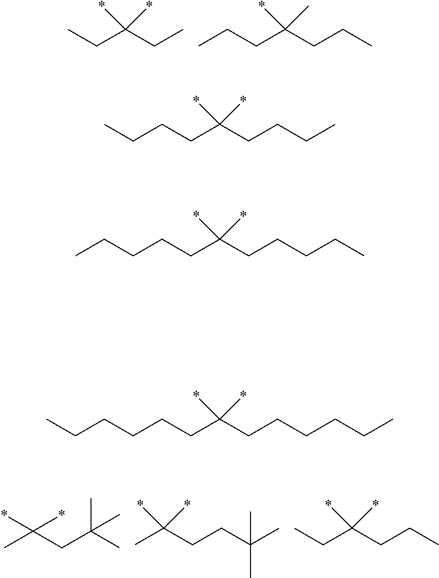

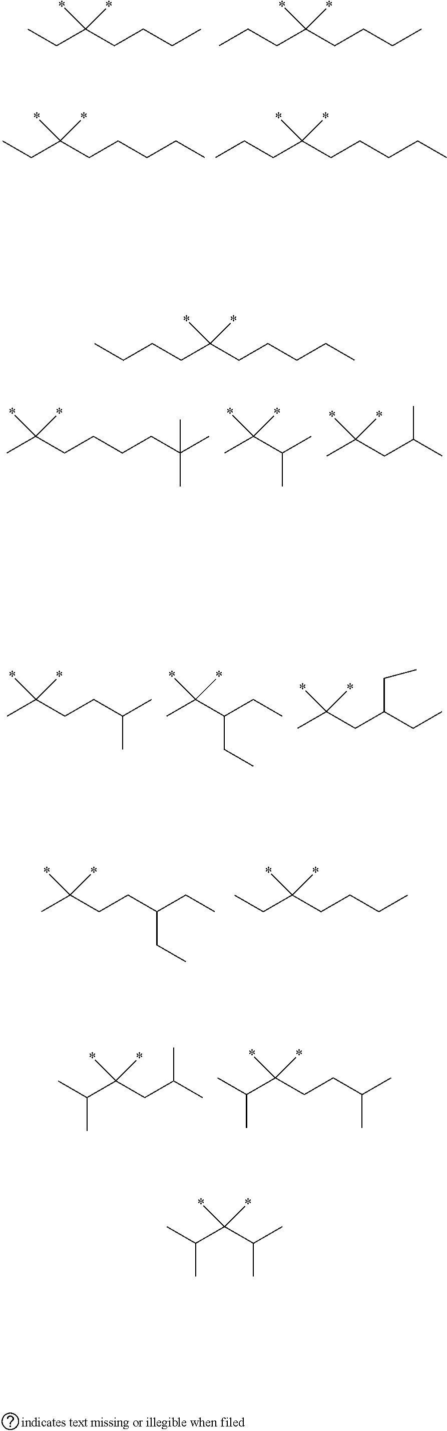

### <Formula (B2)>

*-J¹-Z⁰-J²-* (B2)
in Formula (B2),
Z⁰ is a C₆₋₃₀ aromatic ring residue that may have a substituent, an aliphatic ring residue, or an organic group in which two aromatic or aliphatic rings are linked by a single bond. The organic group in which two aromatic rings or aliphatic rings are linked by a single bond may be a divalent residue of biphenyl, cyclohexylphenyl, or bicyclohexyl.
J¹ and J² are each independently a direct bond or a divalent organic group that may have a substituent. The divalent organic group is preferably a linear or branched alkylene group that has a carbon atom number of 1 to 6 and that may have, as a substituent, a hydroxyl group, an aryl group (e.g., a phenyl group or a substituted phenyl group) or a halo group (e.g., fluorine). Examples of the linear alkylene group include methylene group, ethylene group, propylene group, butylene group, pentylene group, and hexylene group.

Similarly to Formula (B1) shown above, the unit structure including a structure of Formula (B2) may include a dimer or trimer structure in which two or three structures of Formula (B2) shown above, which are the same or different from each other, bind to a divalent or trivalent linking group.

It should be noted that Formula (B2) may include an aromatic ring [Z⁰ in Formula (B2)], and therefore similarly to Formula (B1) shown above, the aromatic ring [e.g., an aromatic ring in Z⁰_{Ar} in the following Formula (B21)] may additionally bind to another unit structure B [through a bond vertically shown in Formula (B21)].

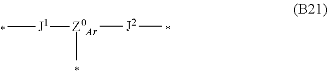

[in Formula (B21),
Z⁰_{Ar} is a C₆₋₃₀ aromatic ring residue that may have a substituent or an organic group in which two aromatic rings or aliphatic rings are linked by a single bond, the aromatic group having at least one aromatic ring, and a bond that extends downward from Z⁰_{Ar} extends from an aromatic ring in Z⁰_{Ar}, and
J¹ and J² are the same as those defined with reference to Formula (B2)]

In this case, when one of the bonds of a linking carbon atom binds to a polymer terminal T (e.g., a hydrogen atom, any functional group such as a hydroxyl group or an unsaturated aliphatic hydrocarbon group, a terminal unit structure A, or a unit structure A in another polymer chain) as shown below in Formula (C2), at least one composite unit structure A-B may be replaced with, as a unit structure C equivalent to a composite unit structure A-B, a unit structure having a structure of Formula (C2). Specifically, the polymer chain may be extended by both of binding between the aromatic ring in Formula (C2) [an aromatic ring in Z⁰_{Ar} in Formula (C2)] and another unit structure B and binding to the aromatic ring of the unit structure A through the other bond of the linking carbon atom shown in Formula (C2).

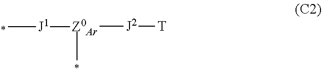

[in Formula (C2),
Z⁰_{Ar}, J¹, and J² are the same as those defined with reference to Formula (B21), and T is a polymer terminal.]

Some specific examples of the unit structure including a structure of Formula (B2) are as shown below. An asterisk * denotes a binding site to the unit structure A. Needless to say, the unit structure B may partially include at least one of the structures shown as examples.

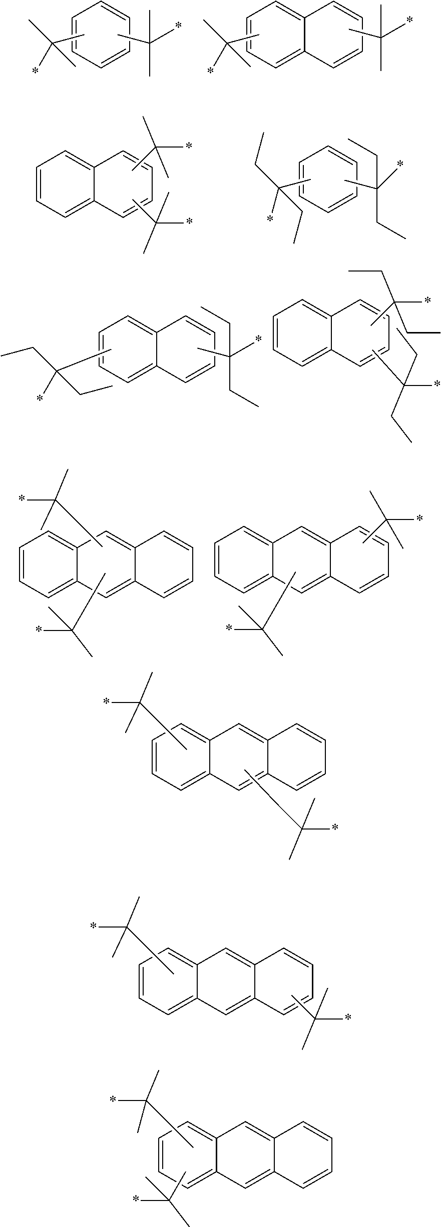

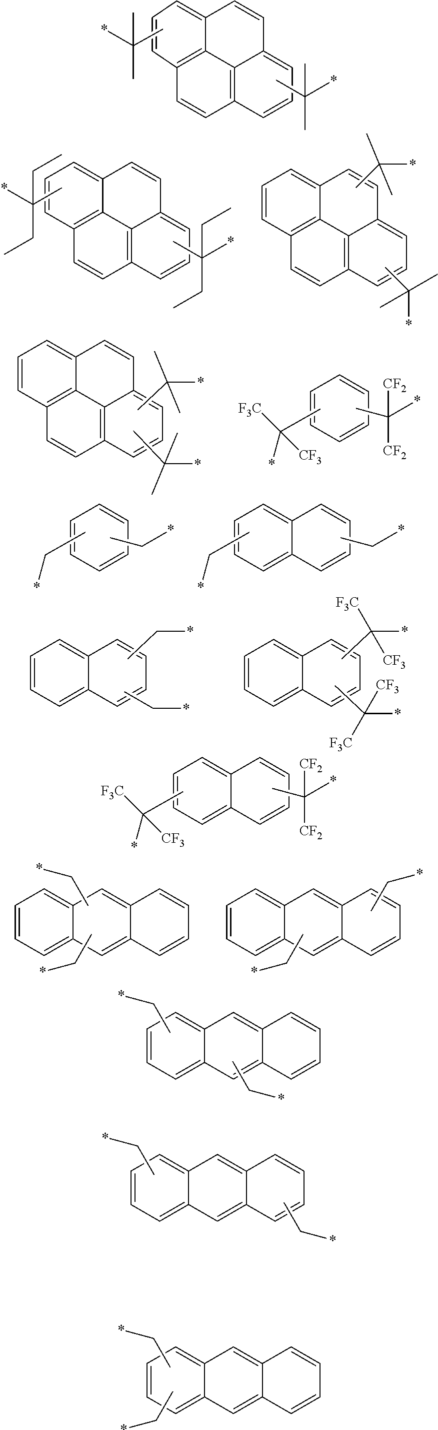

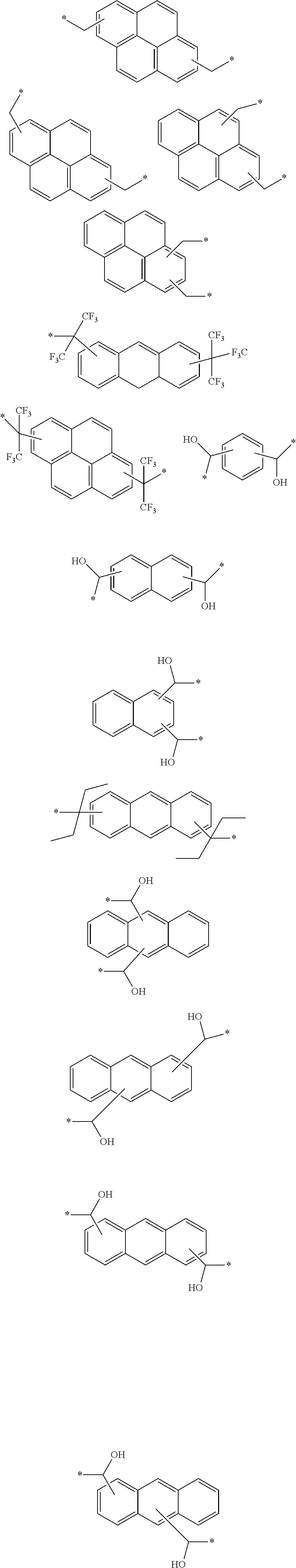

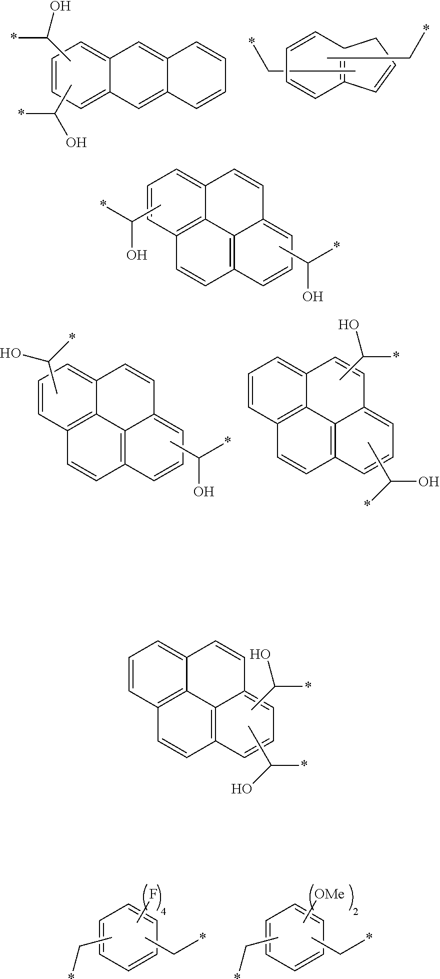

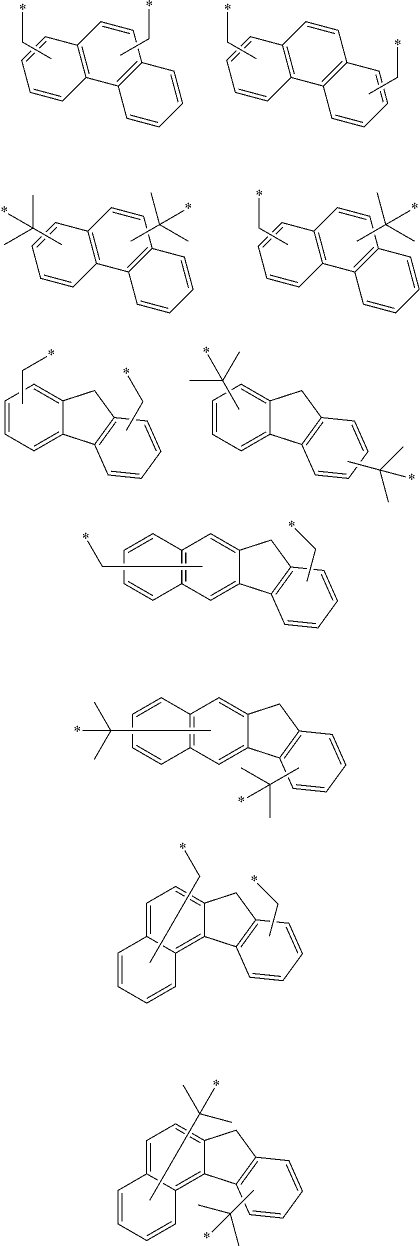

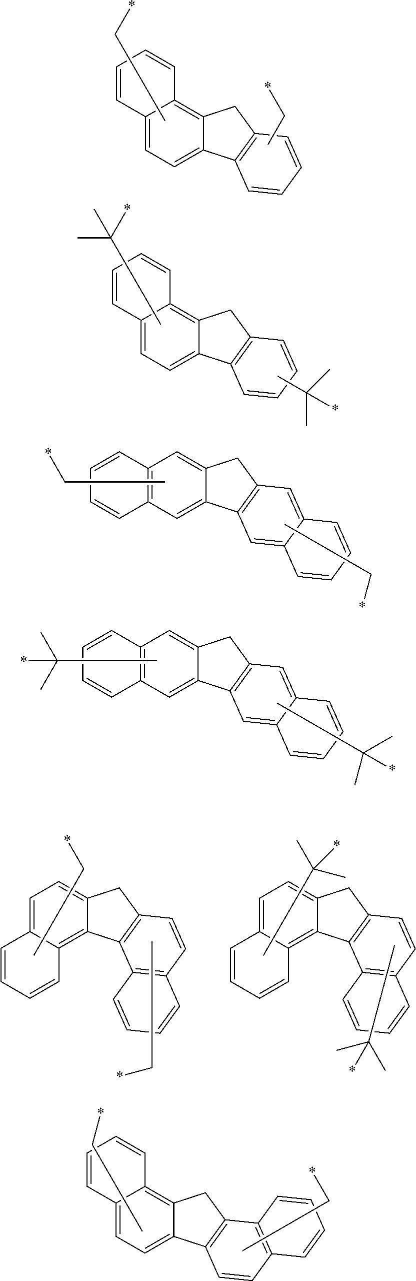

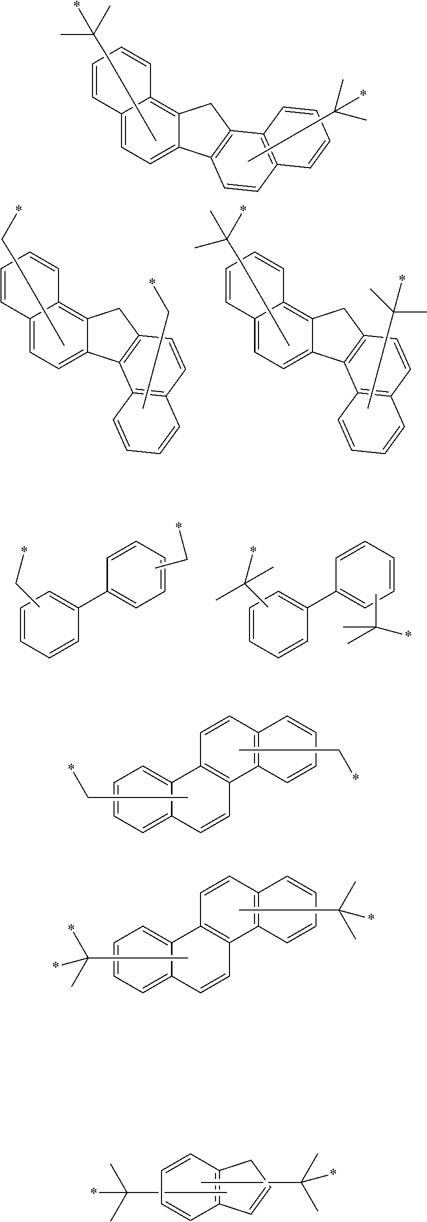

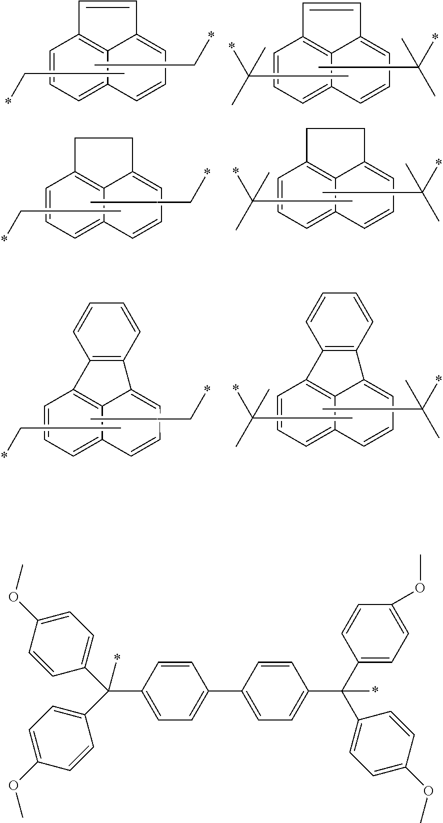

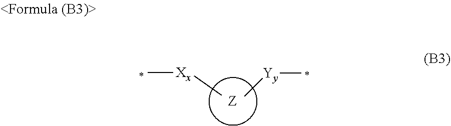

in Formula (B3),
Z is a C₄₋₂₅ monocycle that may have a substituent or a C₄₋₂₅ bicyclic, tricyclic, or tetracyclic condensed ring that may have a substituent. The carbon atom number here means the number of only carbon atoms constituting the cyclic skeleton of the monocycle or the bicyclic, tricyclic, or tetracyclic condensed ring excluding the substituent, and when the monocycle or the condensed ring is a heterocycle, the carbon atom number does not include the number of heteroatoms constituting the heterocycle.

The monocycle is a non-aromatic monocycle; and at least one monocycle constituting the bicyclic, tricyclic, or tetracyclic condensed ring is a non-aromatic monocycle, and a residual monocycle(s) may be an aromatic monocycle(s) or a non-aromatic monocycle(s).

The monocycle or the bicyclic, tricyclic, or tetracyclic condensed ring may further be condensed with one or more aromatic rings to form a pentacyclic or higher polycyclic condensed ring, and the carbon atom number of the pentacyclic or higher polycyclic condensed ring is preferably 40 or less. The carbon atom number here means the number of only carbon atoms constituting the cyclic skeleton of the pentacyclic or higher polycyclic condensed ring excluding the substituent, and when the pentacyclic or higher polycyclic condensed ring is a heterocycle, the carbon atom number does not include the number of heteroatoms constituting the heterocycle.

X and Y are the same or different from each other and are each a —CR³R⁴— group wherein R³ and R⁴ are the same or different from each other and are each a hydrogen atom or a C₁₋₆ hydrocarbon group.
x and y are respectively the number of Xs and the number of Ys and are each independently 0 or 1.
*—Xₓ
binds to any one of carbon atoms (referred to as a “carbon atom 1”) constituting the non-aromatic monocycle of Z (when x=1) or extends from the carbon atom 1 (when x=0),
Y_{y}—*
binds to any one of carbon atoms (referred to as a “carbon atom 2”) constituting the non-aromatic monocycle of Z (when y=1) or extends from the carbon atom 2 (when y=0), and the carbon atom 1 and the carbon atom 2 may be the same or different from each other, and when the carbon atom 1 and the carbon atom 2 are different, the carbon atom 1 and the carbon atom 2 may belong to the same non-aromatic monocycle or different non-aromatic monocycles.

Formula (B3) may optionally include a freely-selected linking carbon atom other than the carbon atom 1 and the carbon atom 2.

It should be noted that when Z is a tricyclic or higher polycyclic condensed ring, the positional relationship between one or two non-aromatic monocycles, to which the carbon atom 1 and the carbon atom 2 belong, and a residual monocycle(s) arranged in the condensed ring in Formula (B3) is not limited, and when the carbon atom 1 and the carbon atom 2 belong to different non-aromatic monocycles (respectively referred to as a “non-aromatic monocycle 1” and a “non-aromatic monocycle 2”), the positional relationship between the non-aromatic monocycle 1 and the non-aromatic monocle 2 arranged in the condensed ring is not limited, either.

Similarly to Formula (B1) shown above, the unit structure including a structure of Formula (B3) may be a dimer or trimer structure in which two or three structures of Formula (B3) shown above, which are the same or different from each other, bind to a divalent or trivalent linking group.

Some specific examples of the organic group including a structure of Formula (B3) are as shown below. The binding site to the unit structure A is not limited. Needless to say, the unit structure B may partially include at least one of the structures shown as examples.

It should be noted that some of the structures shown as examples contain more than two bonds (*), but such an excess bond(s) can be used for, for example, binding to an aromatic ring in another polymer chain or crosslinking.

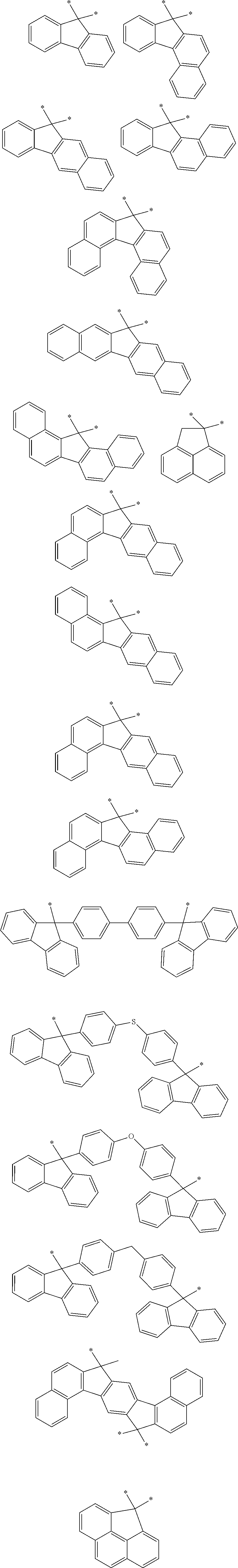

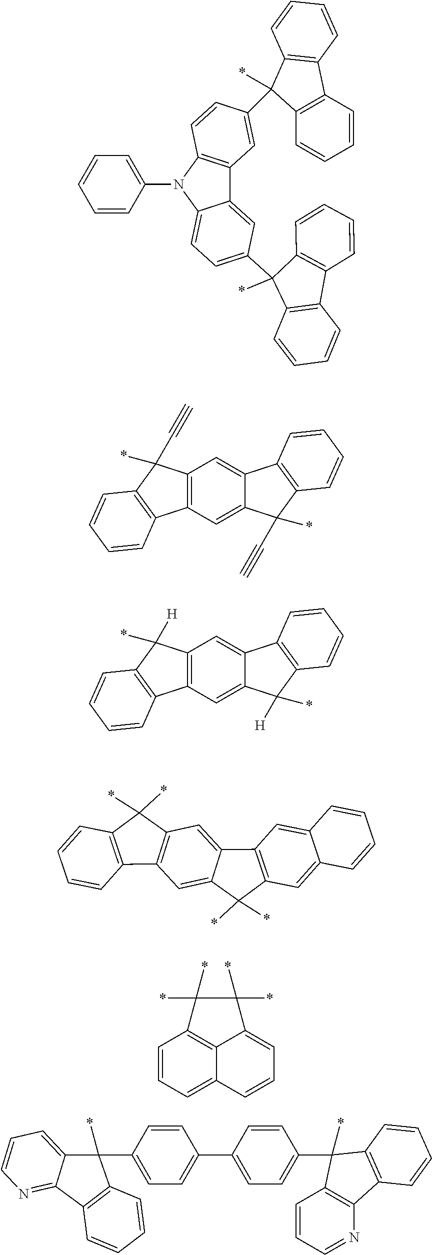

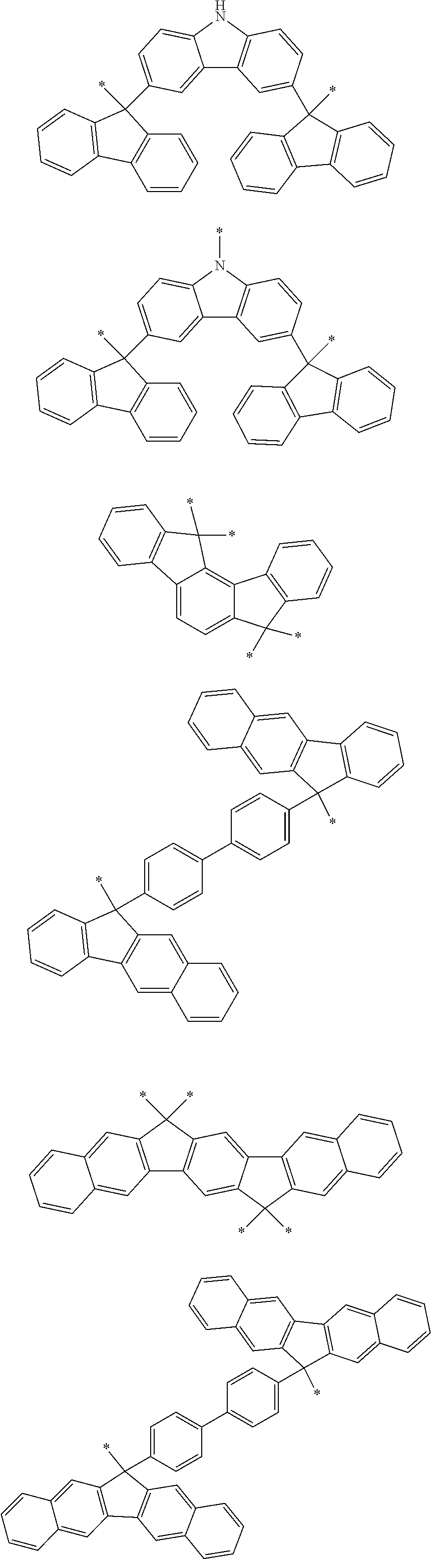

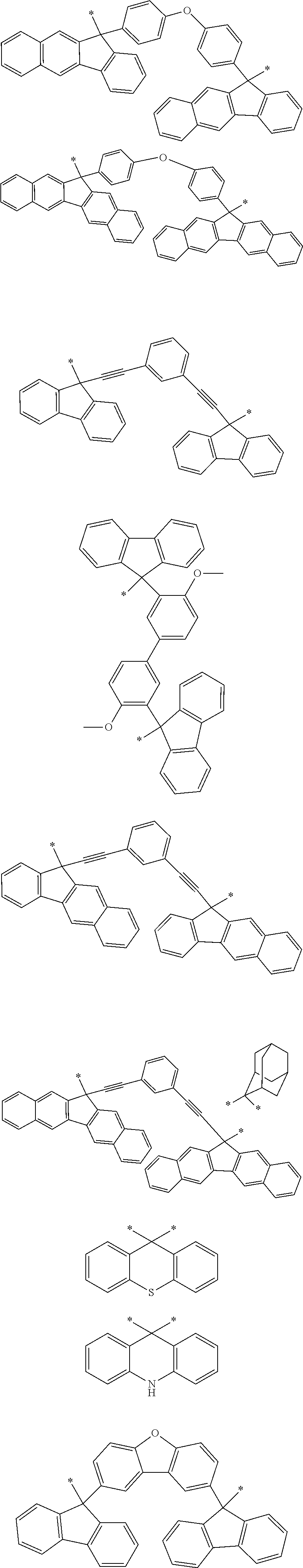

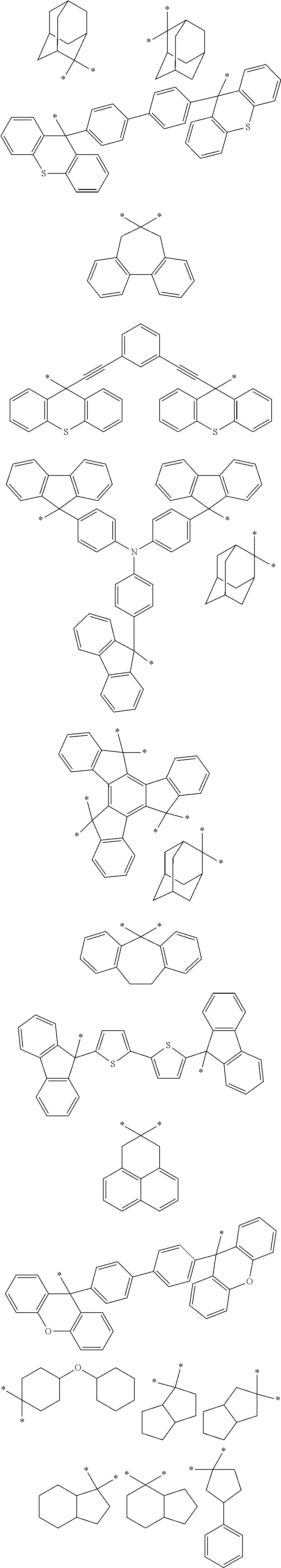

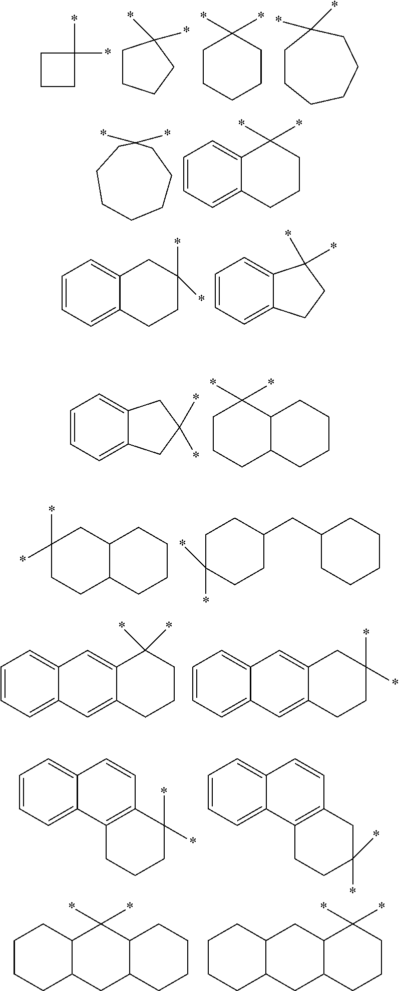

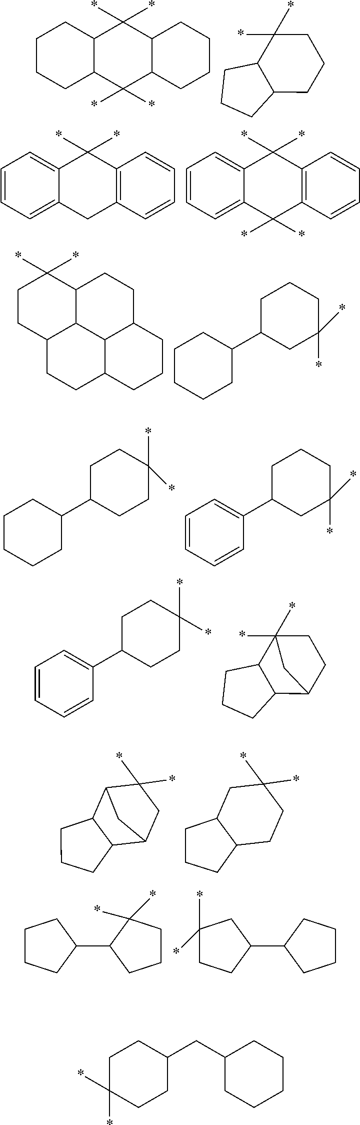

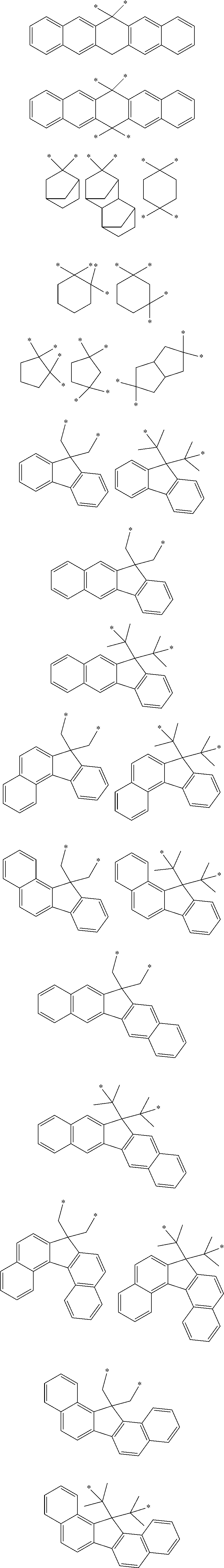

It should be noted that when Z in Formula (B33) contains an aromatic ring, the aromatic ring [see, for example, Ar¹ in the following Formula (B32)] may additionally bind to another unit structure B.

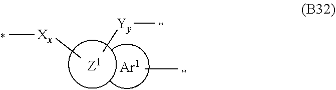

in Formula (B332),
Z¹ is at least one non-aromatic monocycle. Ar¹ is at least one aromatic monocycle condensed with the non-aromatic monocycle of Z¹ to form a condensed ring, and Z and Ar¹ together form a bicyclic, tricyclic, tetracyclic, or pentacyclic condensed ring that has a carbon atom number of 8 to 25 and that may have a substituent. The carbon atom number here means the number of only carbon atoms constituting the cyclic skeleton of the bicyclic, tricyclic, or tetracyclic condensed ring excluding the substituent, and when the bicyclic, tricyclic, or tetracyclic condensed ring is a heterocycle, the carbon atom number does not include the number of heteroatoms constituting the heterocycle.

The bicyclic, tricyclic, tetracyclic, or pentacyclic organic group may further be condensed with one or more aromatic rings to form a hexacyclic or higher polycyclic condensed ring, and the carbon atom number of the hexacyclic or higher polycyclic condensed ring is preferably 40 or less. The carbon atom number here means the number of only carbon atoms constituting the cyclic skeleton of the pentacyclic or higher polycyclic condensed ring excluding the substituent, and when the hexacyclic or higher polycyclic condensed ring is a heterocycle, the carbon atom number does not include the number of heteroatoms constituting the heterocycle.

The positional relationship between one or more non-aromatic monocycles belonging to Z¹ and one or more aromatic monocycles belonging to Ar¹ arranged in the cyclic organic group is not limited. For example, when two or more non-aromatic monocycles belong to Z¹ and two or more aromatic monocycles belong to Ar¹, a condensed ring may be formed in which the non-aromatic monocycles belonging to Z¹ and the aromatic monocycles belonging to Ar¹ are alternately arranged.

X, Y, x, and y in Formula (B32) are the same as those defined with reference to Formula (B3).

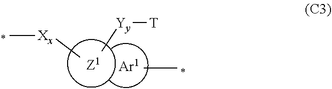

In this case, when one of the bonds of a linking carbon atom binds to a polymer terminal T (e.g., a hydrogen atom, any functional group such as a hydroxyl group or an unsaturated aliphatic hydrocarbon group, a terminal unit structure A, or a unit structure A in another polymer chain) as shown below in Formula (C3):
[in Formula (C3),
Z¹, Ar¹, X, Y, x, and y are the same as those defined with reference to Formula (B32) and T is a polymer terminal], at least one composite unit structure A-B may be replaced with, as a unit structure C equivalent to a composite unit structure A-B, a unit structure having a structure of Formula (C3). Specifically, the polymer chain may be extended by both of binding between the aromatic ring in Formula (C3) [Ar¹ in Formula (C3)] and another unit structure B and binding to the aromatic ring of the unit structure A through the other bond from the linking carbon atom shown in Formula (C3).

A more specific structure of Formula (C3) is, for example, a structure of the following Formula (C31) wherein a hydrogen atom as a terminal group corresponds to T in Formula (C3) and p, k₁, and k₂ are possible bonds. When containing p and k₁ or p and k₂, the structure of Formula (C31) may be a unit structure C equivalent to a composite unit structure A-B.

It should be noted that when containing kᵢ and k₂, the structure of Formula (C31) can function also as a unit structure A.

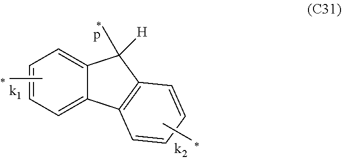

A structure of the following Formula (C32) is a case where T in Formula (C3) is a phenyl group. In this case, p, k₁, k₂, and m are possible bonds, and when containing p and k₁, p and k₂, or p and m, the structure of Formula (C32) may be a unit structure C equivalent to a composite unit structure A-B.

It should be noted that when containing k₁ and k₂, k₁ and m, or k₂ and m, the structure of Formula (C32) can function also as a unit structure A.

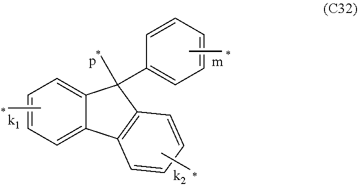

Some more specific examples of a unit structure C of Formula (C3) (a unit structure equivalent to a composite unit structure (A-B) are as shown below. An asterisk * denotes a binding site to the unit structure A.

The unit structure C contains another bond that extends from an aromatic ring contained therein to bind to the unit structure B, but such bonds are not shown in the specific examples shown below. Needless to say, the unit structure C may partially include at least one of the structures shown as examples.

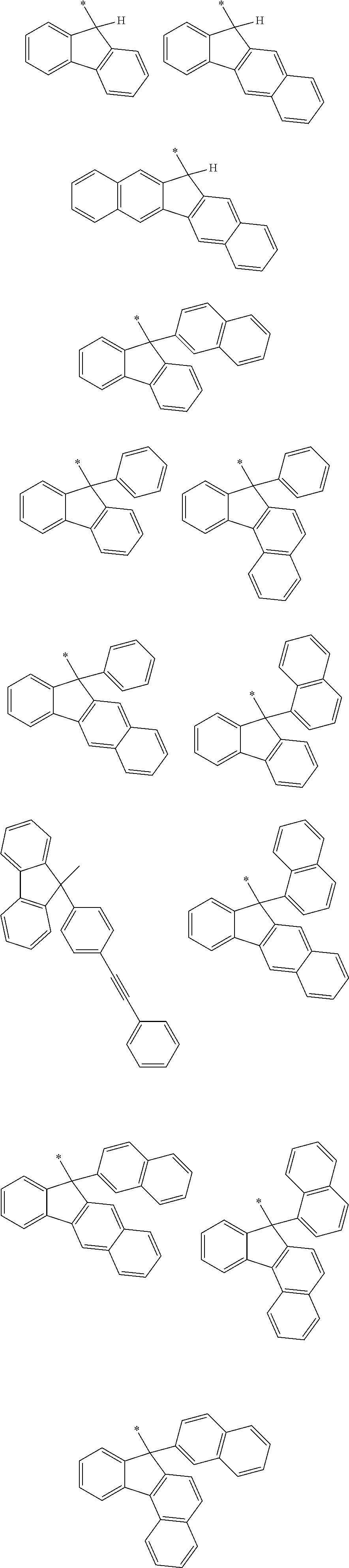

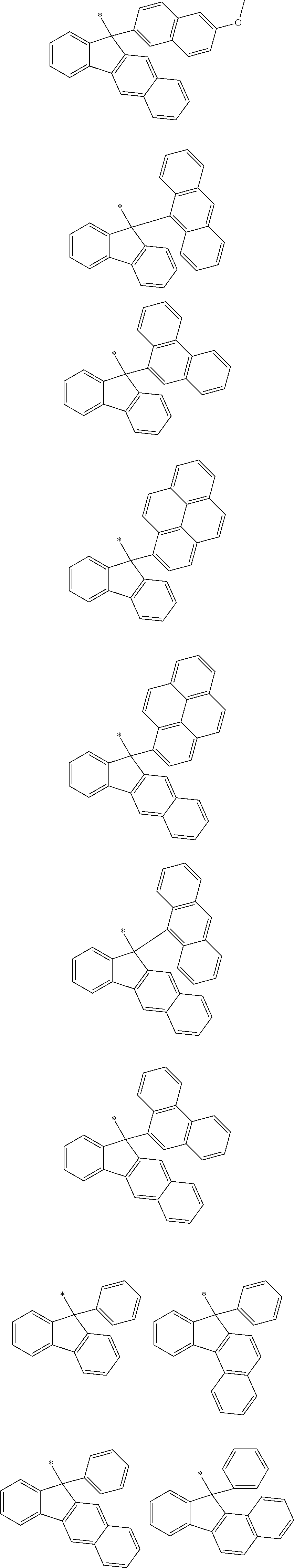

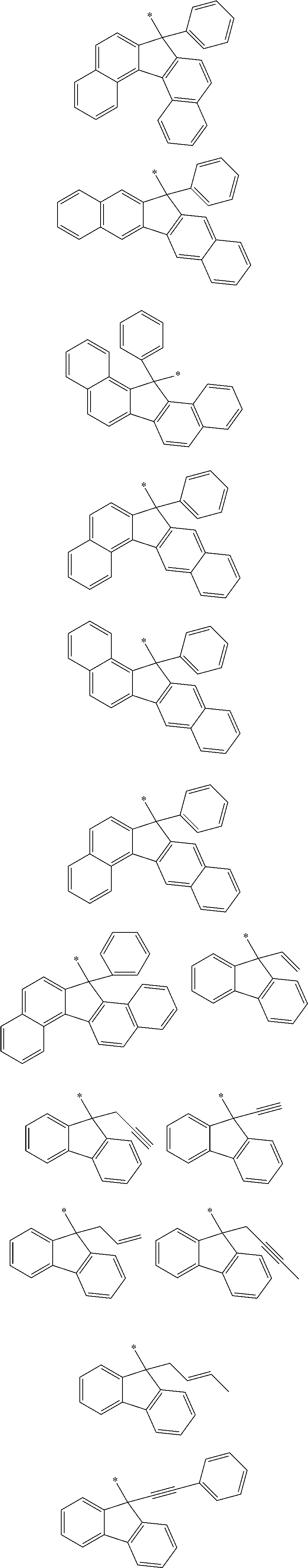

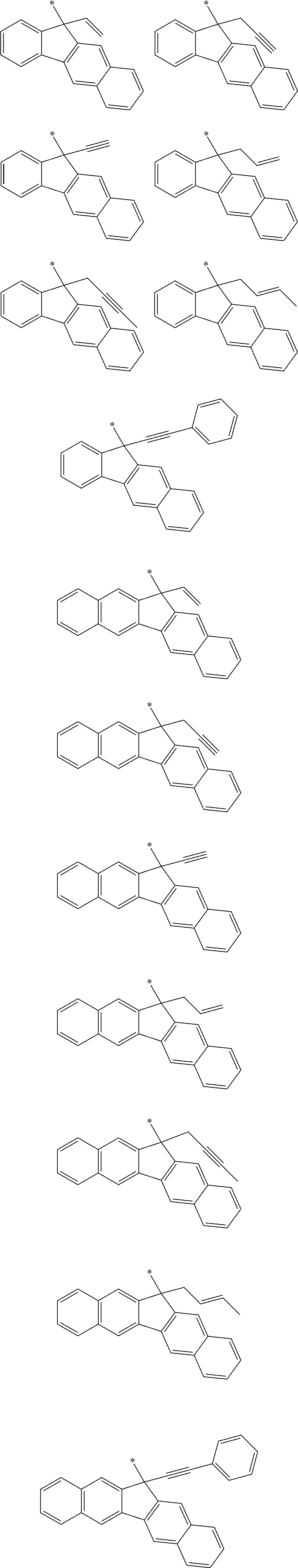

It should be noted that the specific examples shown above that do not contain bonds from aromatic rings may be specific examples of a polymer terminal.

### <Side Chain of Novolac Resin>

The novolac resin having a repeating composite unit structure A-B of Formula (AB) shown above further has a structure of the following Formula (D) in its side chain.

—O—Ar² Formula (D)
wherein Ar² is an aromatic ring. For the “aromatic ring”, refer to the above section <Definitions of terms>.
Ar² in Formula (D) is preferably an aromatic ring having an aromatic hydrocarbon ring and/or an aromatic heterocycle. For the “aromatic hydrocarbon ring” and the “aromatic heterocycle”, refer to the above section <Definitions of terms>.

The aromatic hydrocarbon ring is preferably an aromatic hydrocarbon ring including a benzene structure, a naphthalene structure, an anthracene structure, a pyrene structure, a phenanthrene structure, a fluorene structure, a benzofluorene structure, or a dibenzofluorene structure, more preferably benzene, naphthalene, anthracene, pyrene, phenanthrene, fluorene, benzofluorene, or dibenzofluorene, and the aromatic heterocycle is an aromatic heterocycle that may contain nitrogen and may be an aromatic heterocycle including an indole structure, a phenylindole structure, a carbazole structure, an indolocarbazole structure, a furan structure, a thiophene structure, a pyrrole structure, or a phenothiazine structure.

Examples of the aromatic heterocycle that may contain nitrogen include pyrrole, indole, isoindole, phenylindole, imidazole, pyrazole, pyridine, quinoline, isoquinoline, pyrazine, quinoxaline, acridine, pyrimidine, carbazole, indolocarbazole, furan, thiophene, and phenothiazine, and preferred are indole, phenylindole, carbazole, indolocarbazole, furan, thiophene, pyrrole, and phenothiazine.

Ar² is more preferably an aromatic ring having an aromatic hydrocarbon ring and/or an aromatic heterocycle substituted with —CH₂—OR¹² wherein R¹² is a hydrogen atom or a linear, branched, or cyclic alkyl group that has a carbon atom number of 1 to 20 and that may have a heteroatom such as a nitrogen atom, an oxygen atom, or a sulfur atom.
R¹² is preferably a hydrogen atom or a methyl group.

The side chain having a structure of Formula (D) may directly bind to the main chain of the unit structure B or may bind to an aromatic ring as a side chain of the unit structure B. Even more preferably, the aromatic ring is an aromatic ring having an aromatic hydrocarbon ring and/or an aromatic heterocycle that may be substituted with a halogeno group, a hydroxy group, a methylol group, a linear or branched alkyl group having a carbon atom number of 1 to 6, or a linear or branched ether group having a carbon atom number of 1 to 6.

For the definitions of the “aromatic ring”, the “aromatic hydrocarbon ring”, and the “aromatic heterocycle”, refer to their respective descriptions in the above section <Definitions of terms>.

The structure of Formula (D) can partially have a methylol ether structure. Therefore, in the following description, the structure of Formula (D) is sometimes simply referred to as a methylol ether structure, which, however, does not mean that the structure of Formula (D) is a methylol ether structure as a whole.

### <Examples of Unit Structure of Novolac Resin>

Examples of a unit structure of the novolac resin according to the present invention having a structure of Formula (D) are as shown below. An asterisk (*) denotes a bond that links to the main chain of the novolac resin.

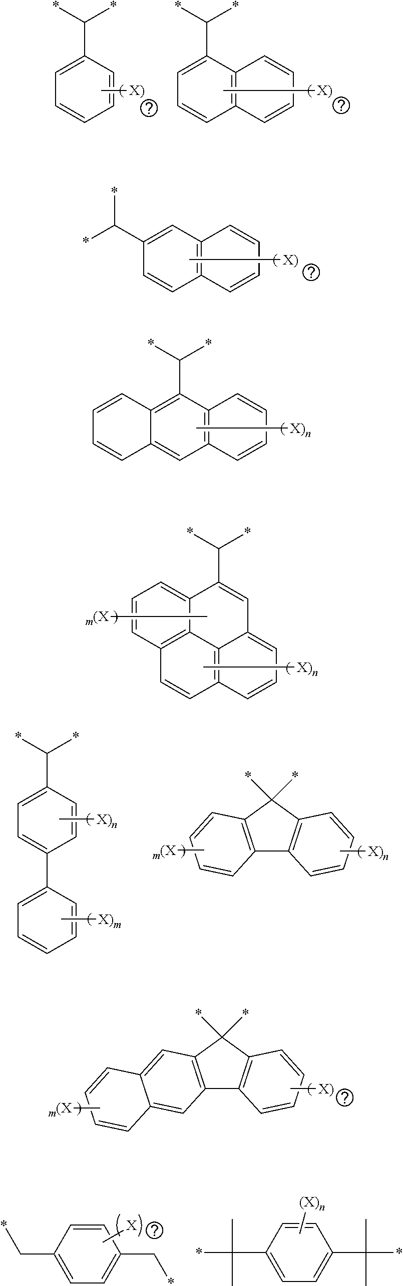

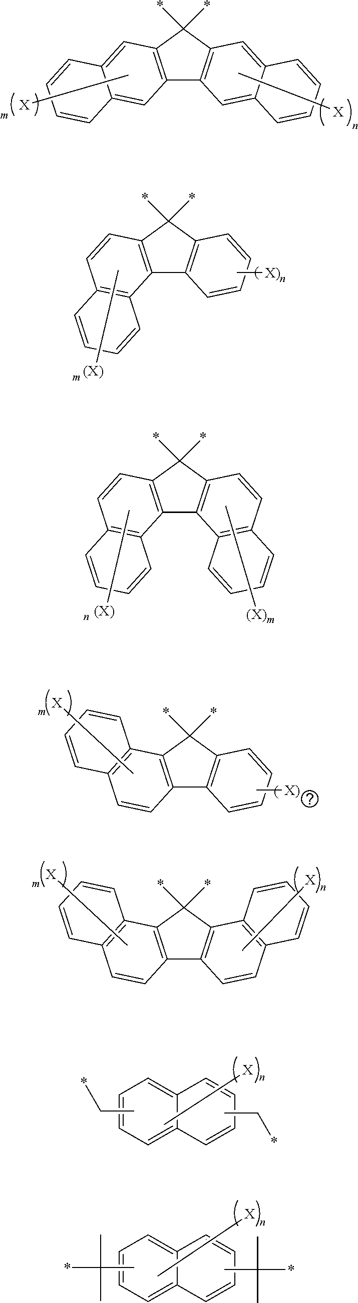

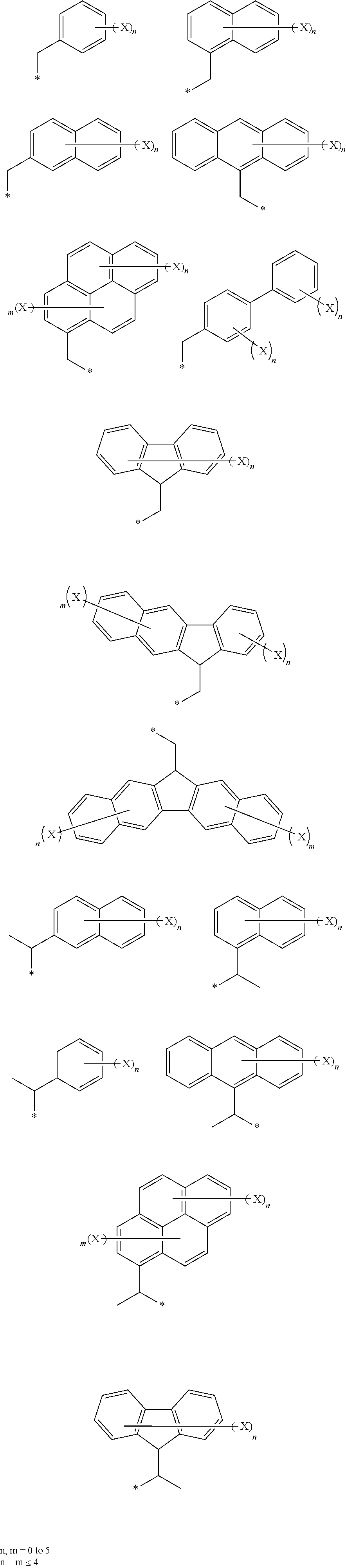

In the examples shown above, X has any one of structures shown below. X shown across two or more aromatic rings and the like means that X is substituted for a hydrogen atom that binds to any one of carbon atoms of the aromatic rings across which X is shown. A wavy line in Y denotes a bond that directly binds to an aromatic series.

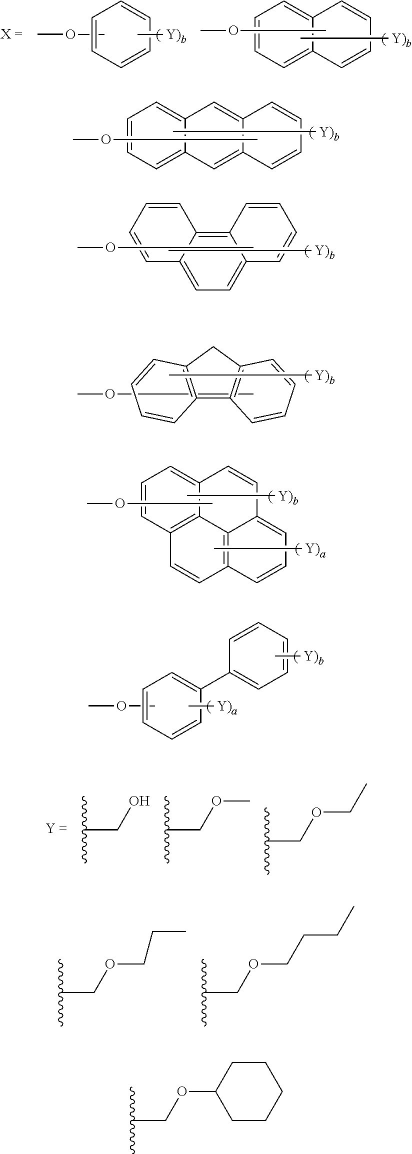

Examples of a unit structure of the main chain of the novolac resin having a side chain having a structure of Formula (D) are as shown below. An asterisk (*) denotes a bond that links to the unit structure of main chain of the novolac resin.

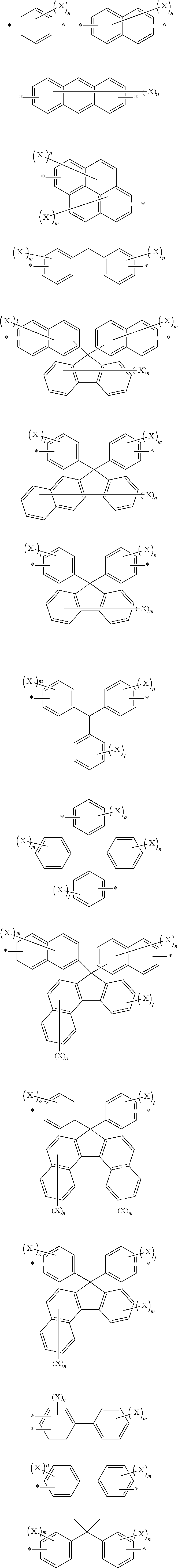

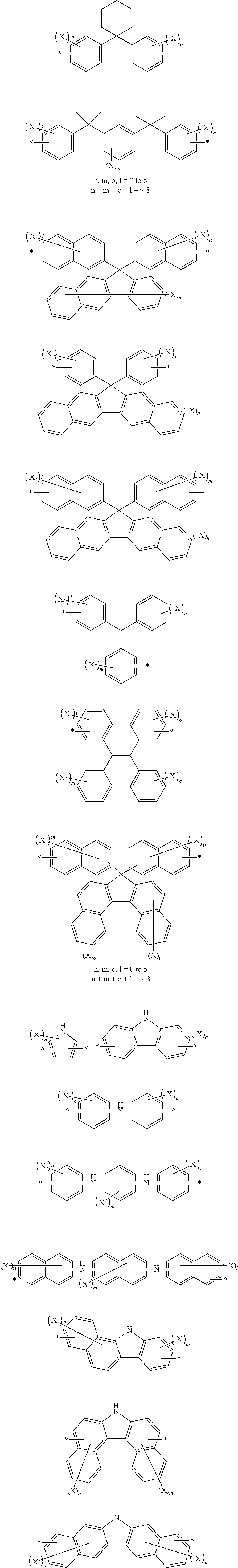

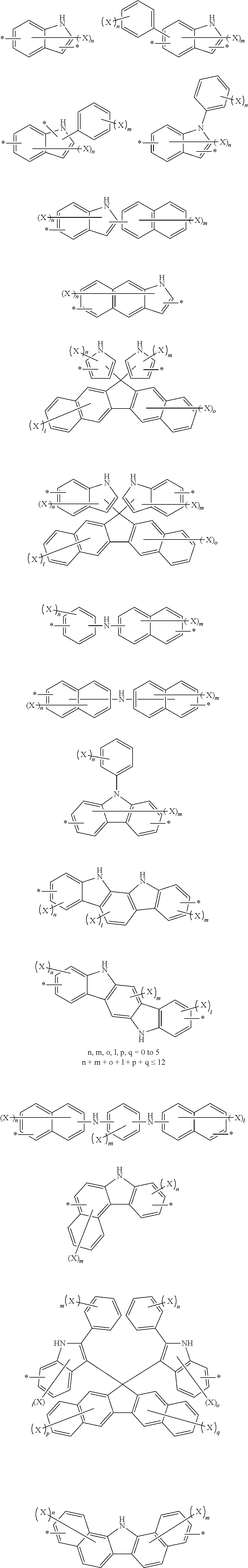

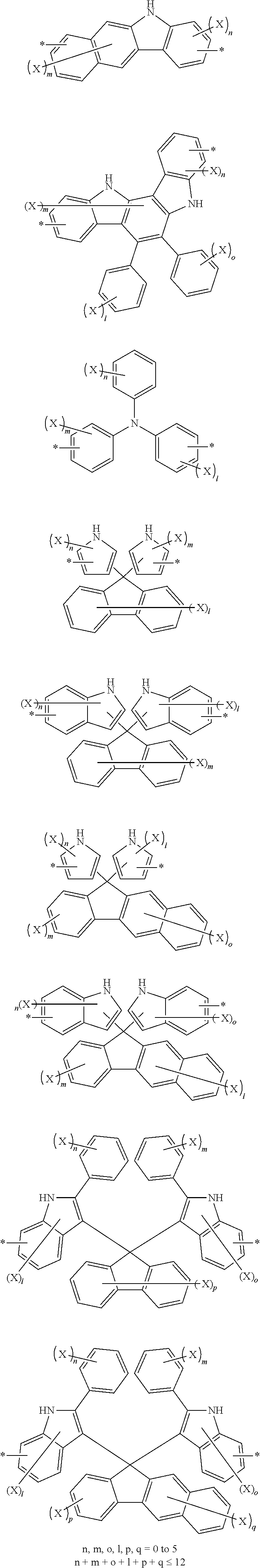

In the examples shown above, X has any one of structures shown below. X shown across two or more aromatic rings and the like means that X is substituted for a hydrogen atom that binds to any one of carbon atoms of the aromatic rings across which X is shown. A wavy line in Y denotes a bond that directly binds to an aromatic series.

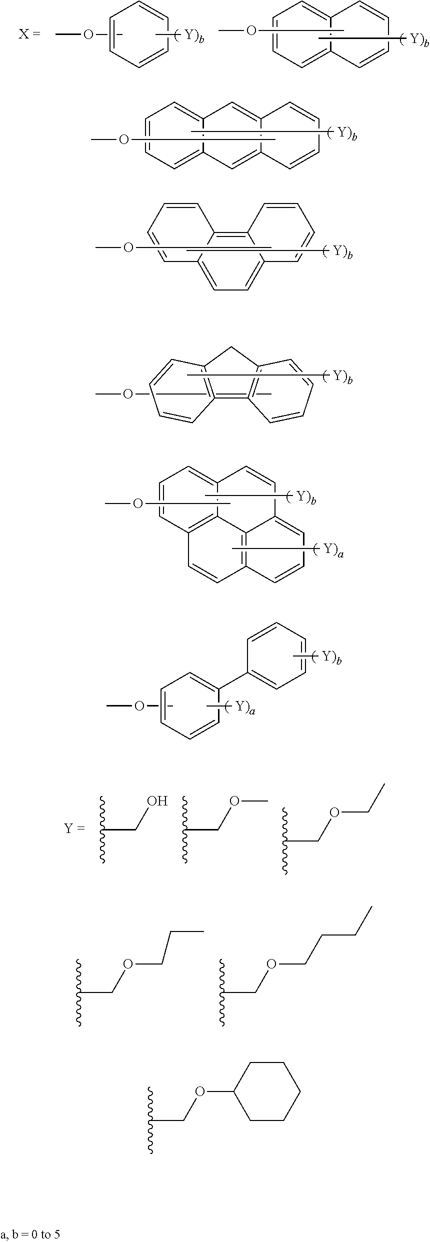

### <Production of Novolac Resin>

The novolac resin having a structure of Formula (AB) can be prepared by a publicly-known method. For example, the novolac resin can be prepared by condensation between a ring-containing compound represented by H-A-H and an oxygen-containing compound represented by OHC—B, O═C—B, RO—B—OR, RO—CH₂—B—CH₂—OR, or the like. In these formulas, A and B are the same as those defined above and R is a hydrogen atom, a halogen atom, or an alkyl group having a carbon atom number of about 1 to 3.

A methylol ether structure can also be introduced by adding a methylol agent to the novolac resin.

As an example of a generation method, condensation between the novolac resin and an —OH monomer containing a halogen atom and having a side chain having a methylol ether structure makes it possible to generate a novolac resin having a methylol ether structure in its side chain. However, when one of the novolac resin and the methylol agent has a halogen atom and the other has a hydroxyl group, a novolac resin having a methylol ether structure in its side chain can be generated.

It should be noted that during this reaction, a side reaction in which the methylol agent binds to a nitrogen atom may occur to the extent that the effects of the present invention are not impaired, but the novolac resin according to the present invention may include a partial structure generated by such a side reaction.

Particularly preferred examples of the methylol agent include, but are not limited to, structures shown below. It should be noted that F as a halogen atom in the structures shown below may be replaced with Cl, Br, or I, and when the side chain has a structure represented by —O—Ar²—CH₂—OH due to substitution with —CH₂—OH, the H atom of OH may be substituted by a linear, branched, or cyclic alkyl group that has a carbon atom number of 1 to 20 and that may contain a heteroatom such as a nitrogen atom, an oxygen atom, or a sulfur atom.

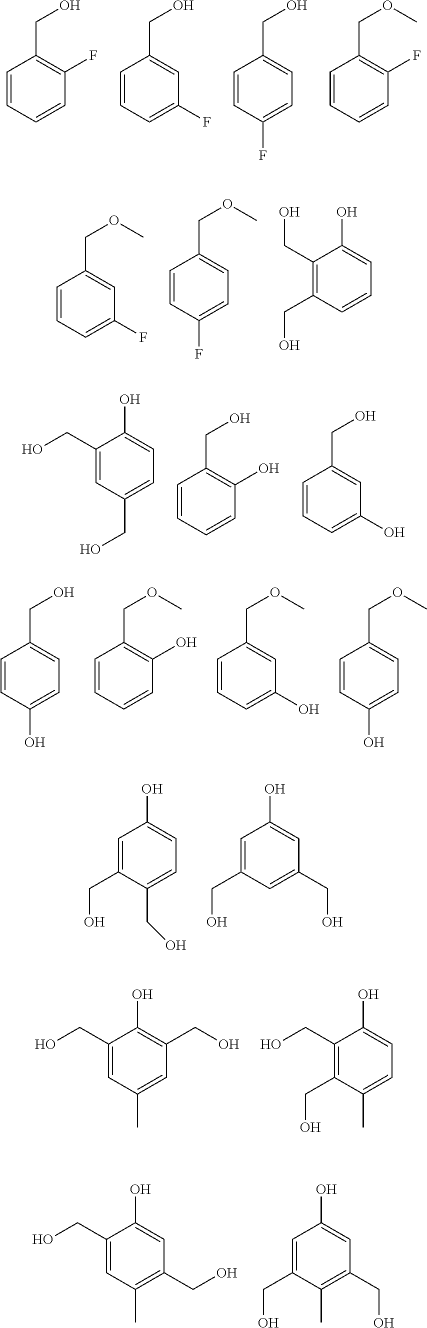

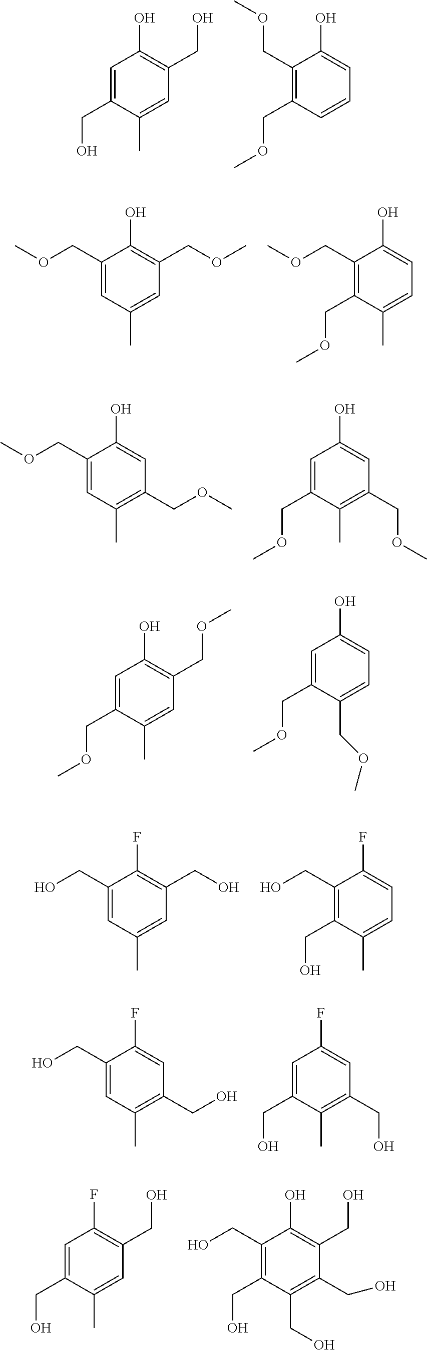

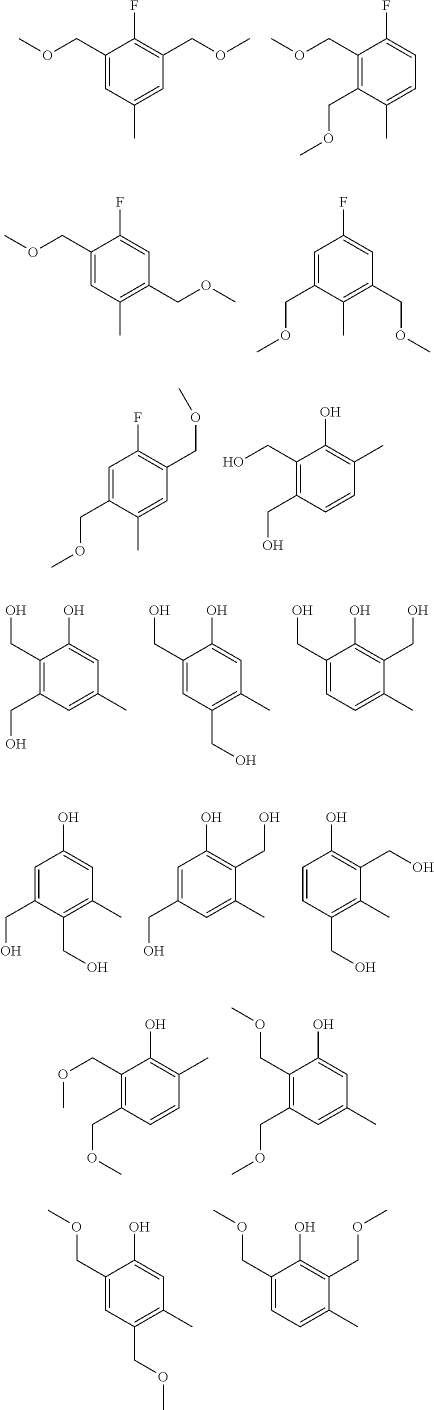

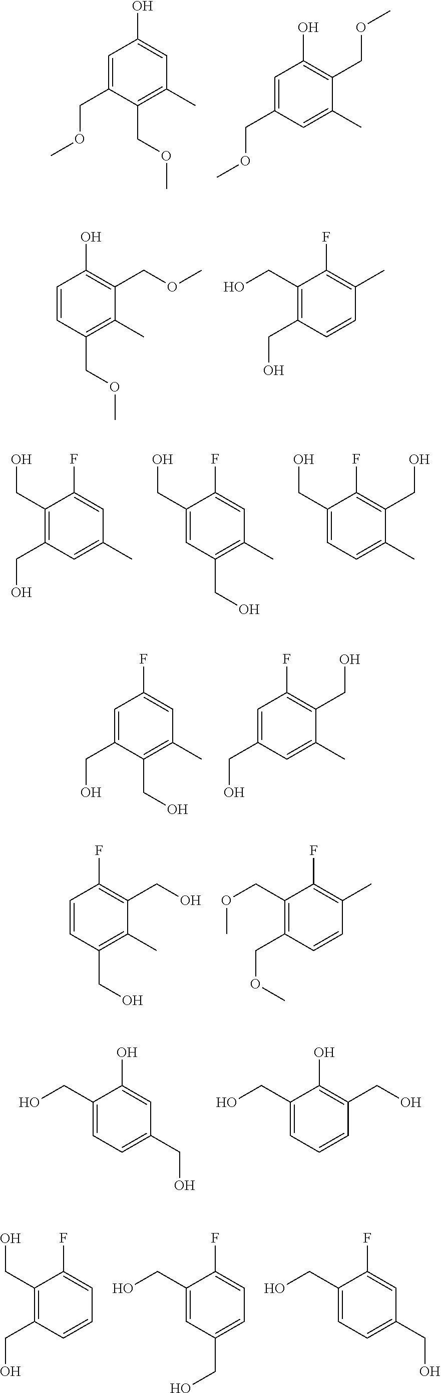

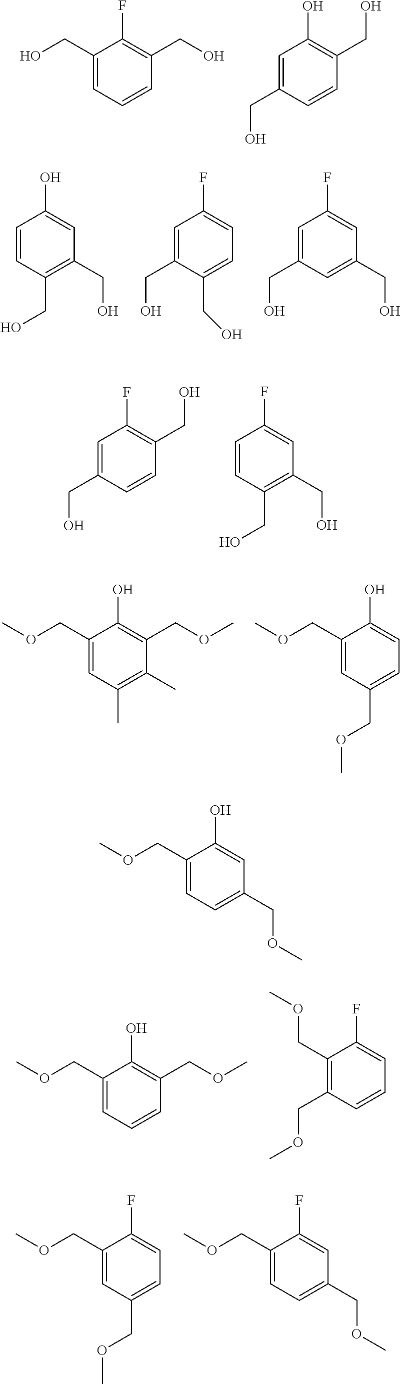

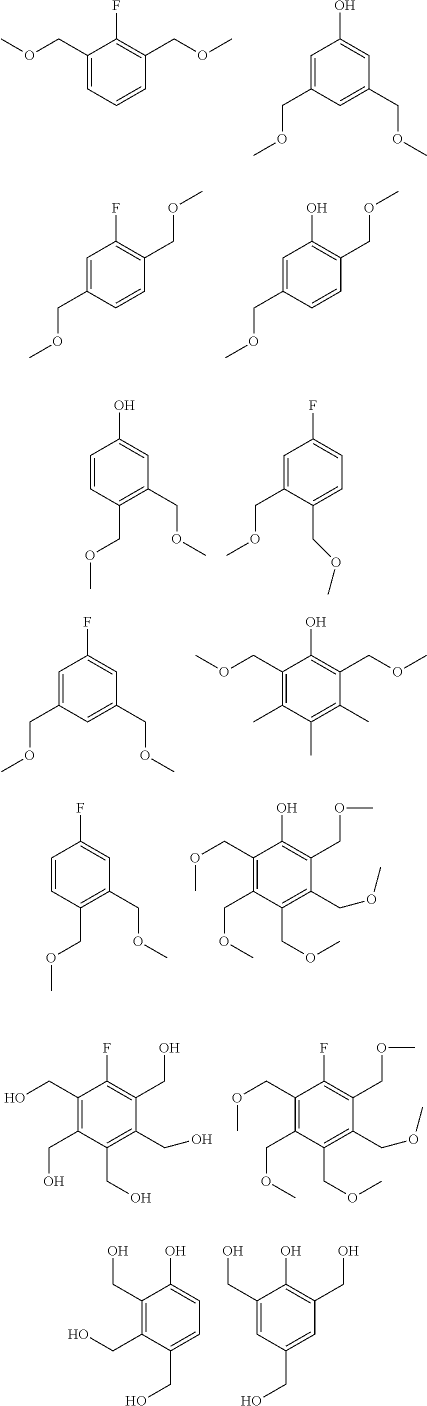

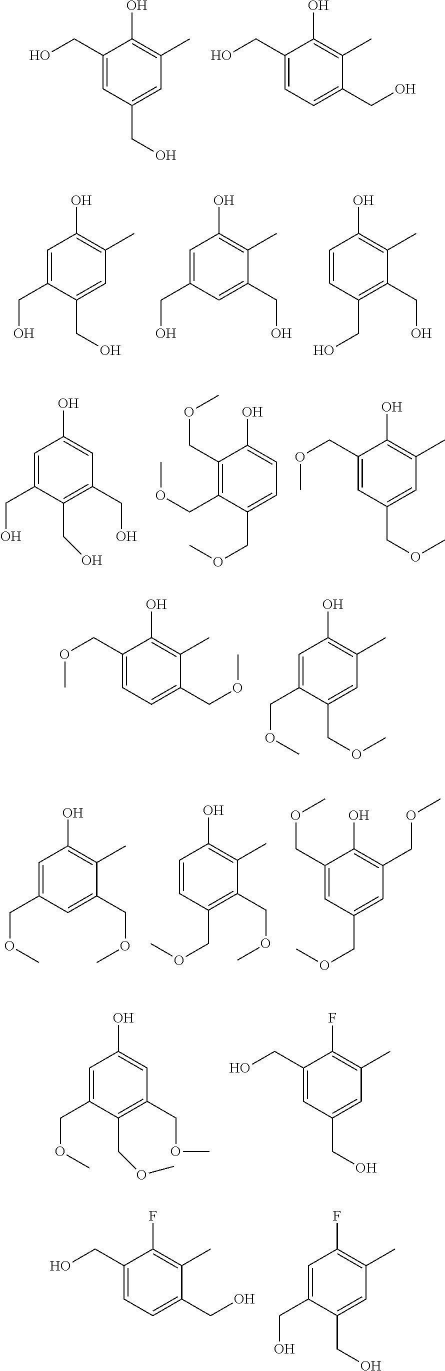

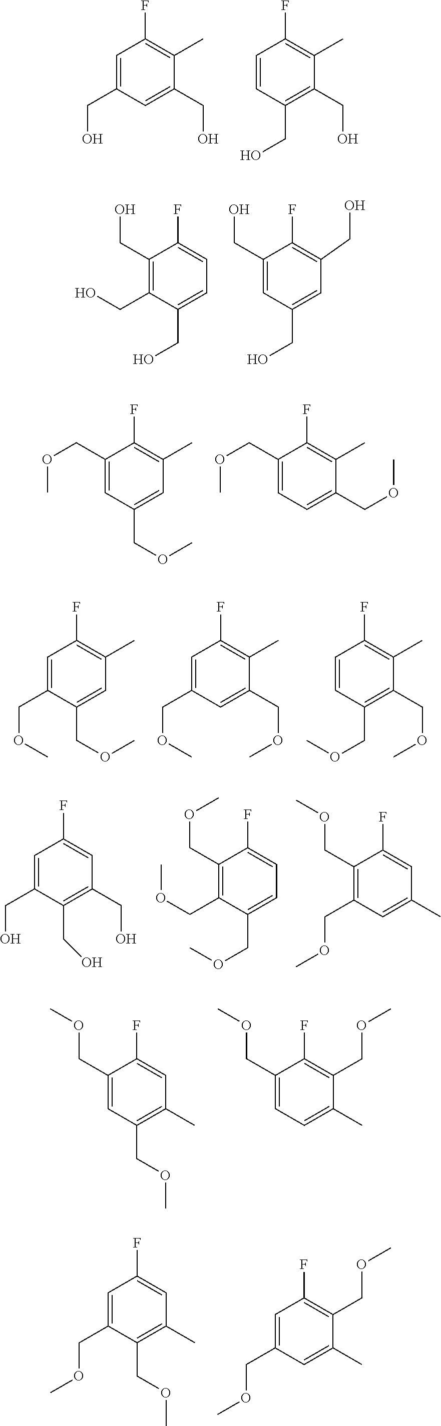

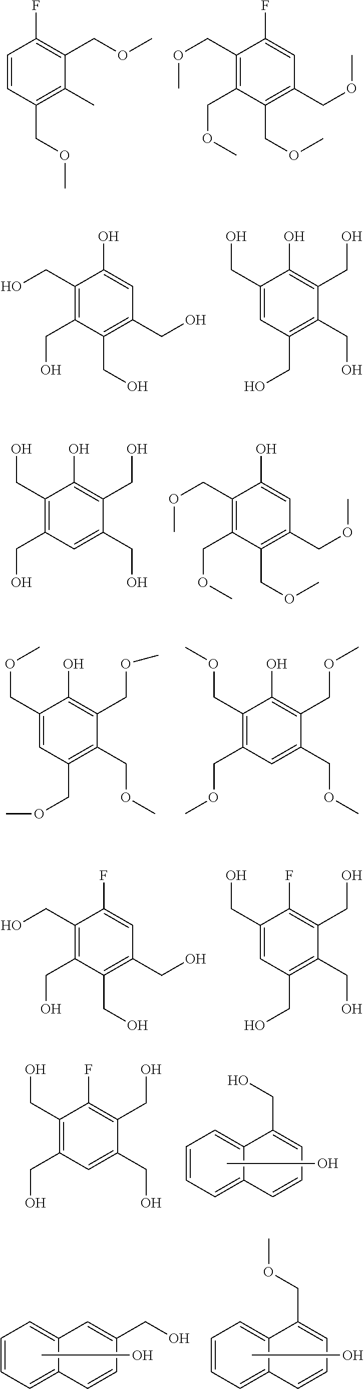

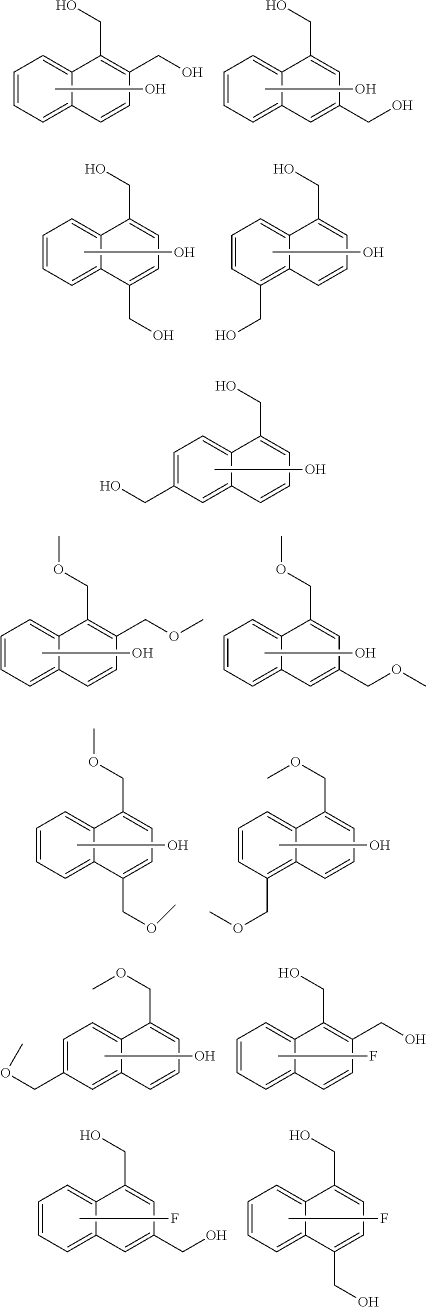

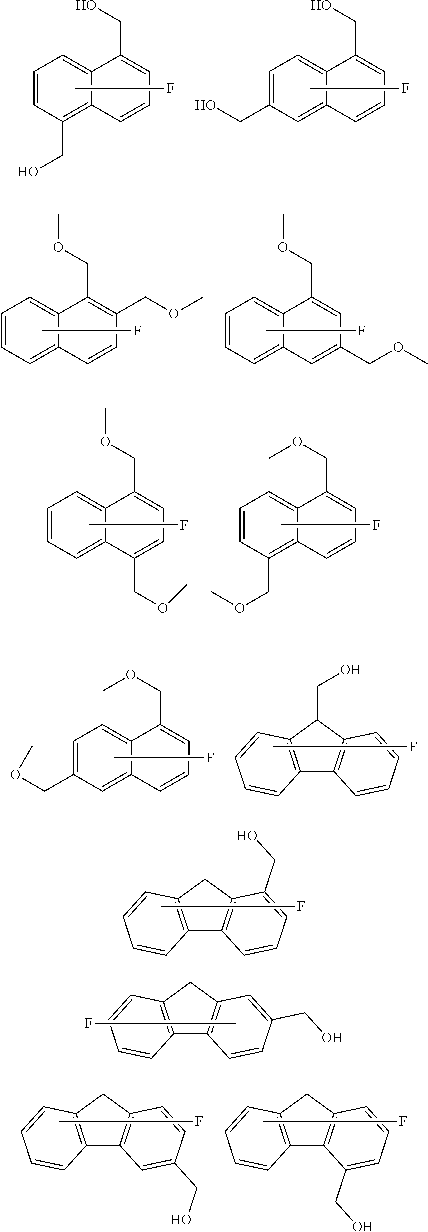

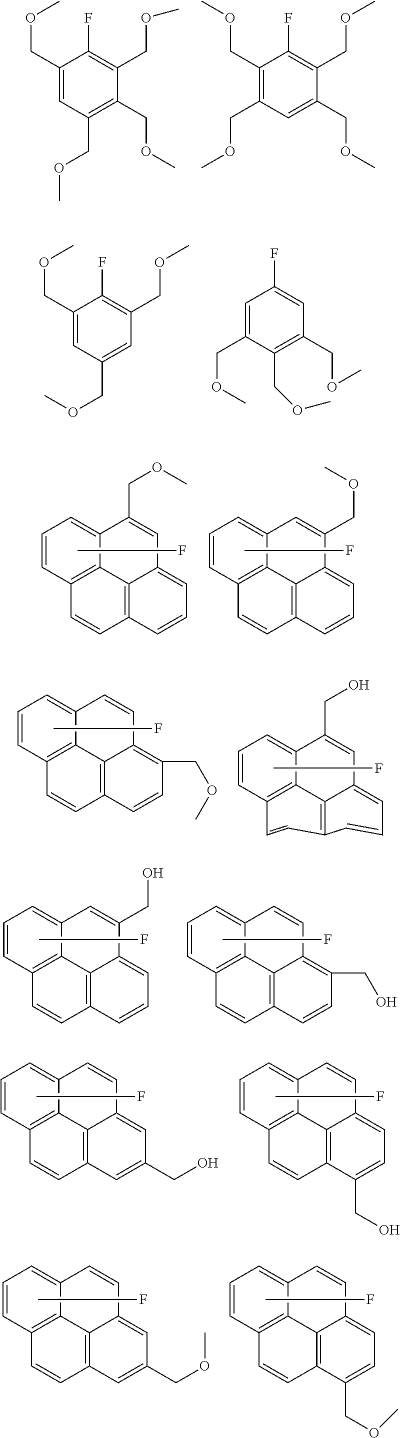

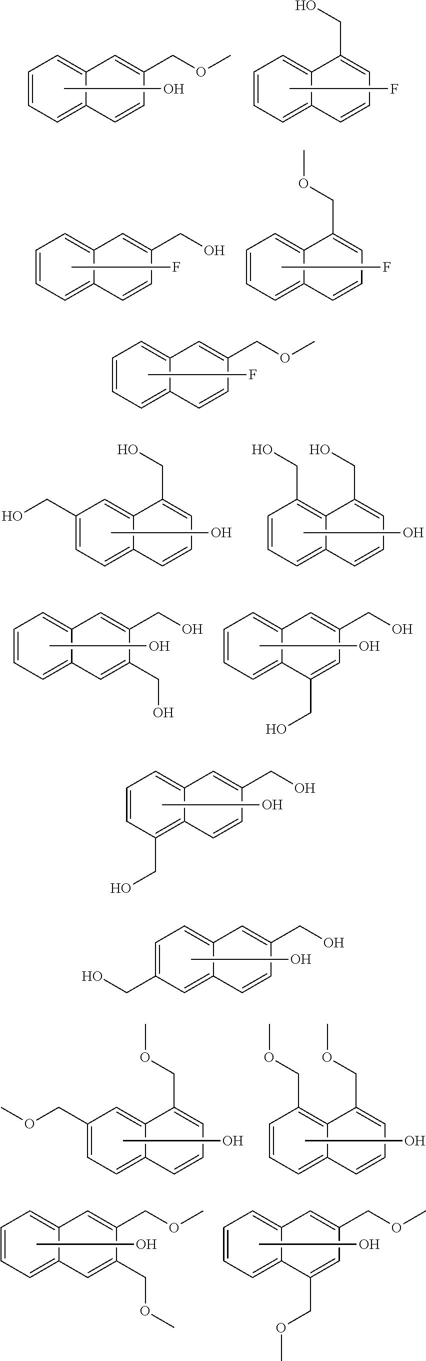

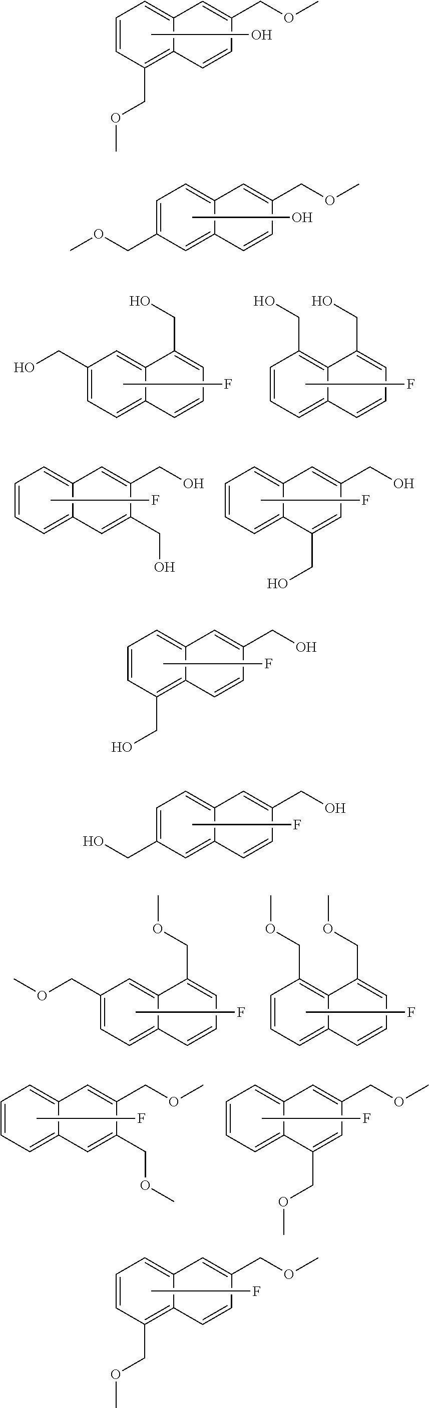

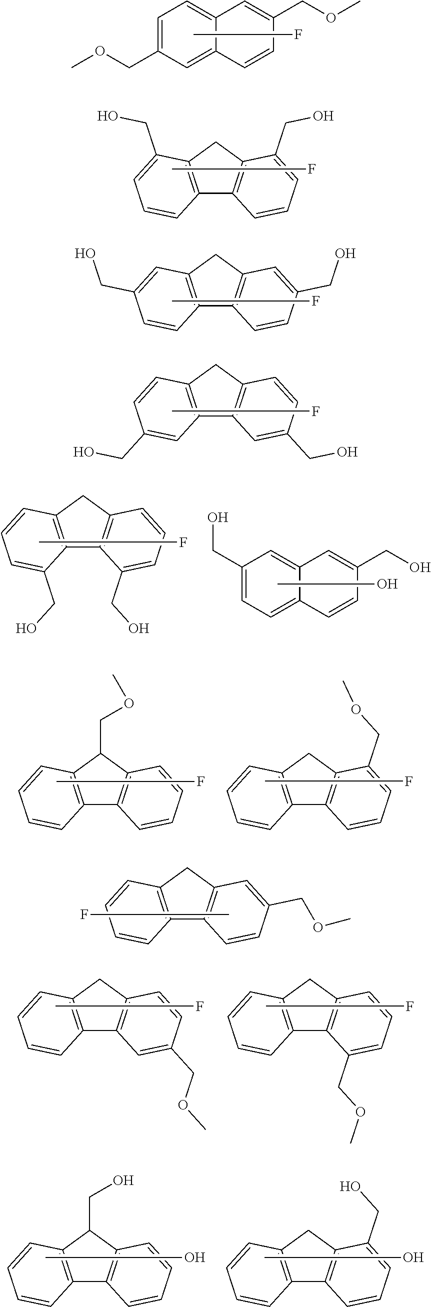

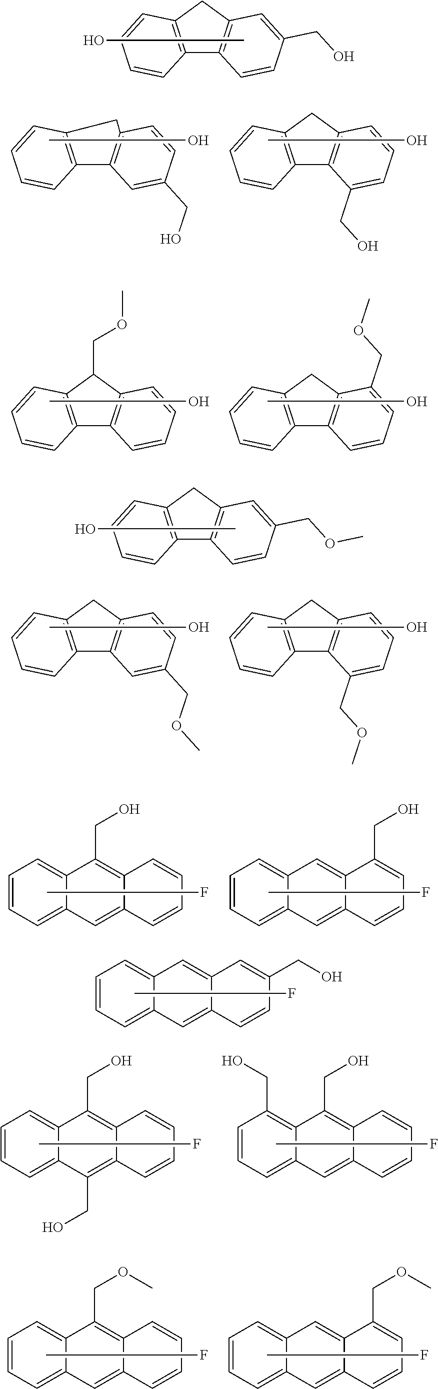

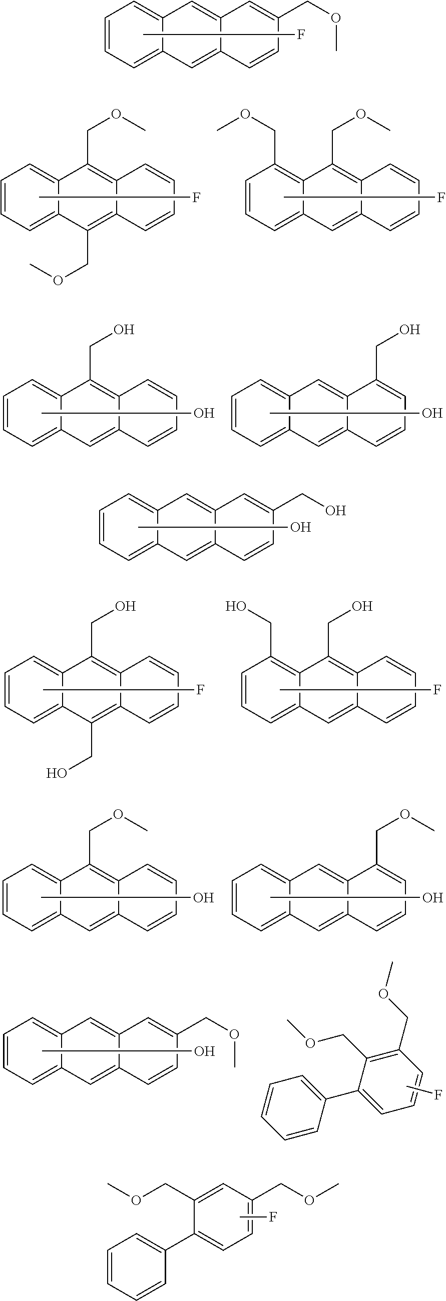

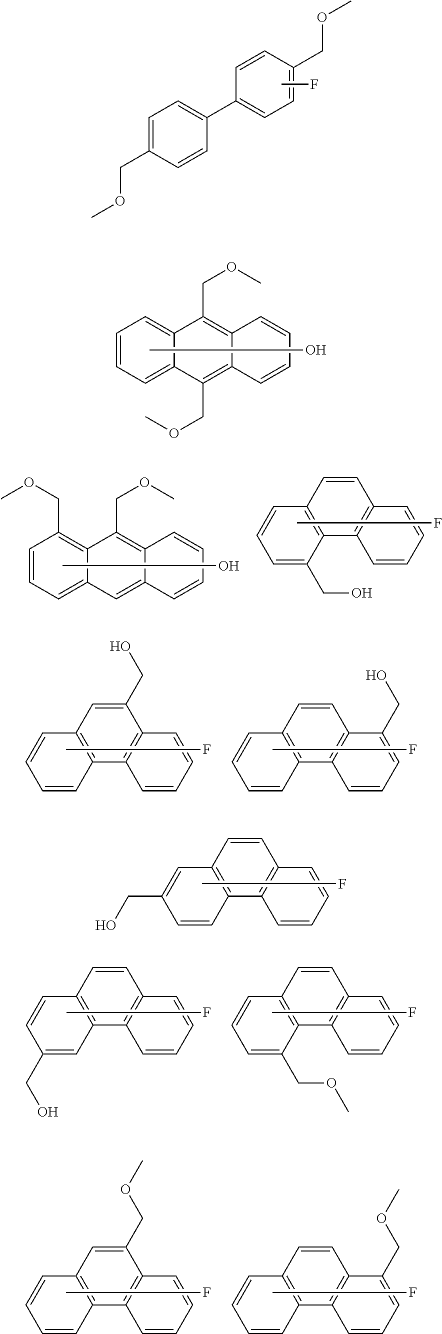

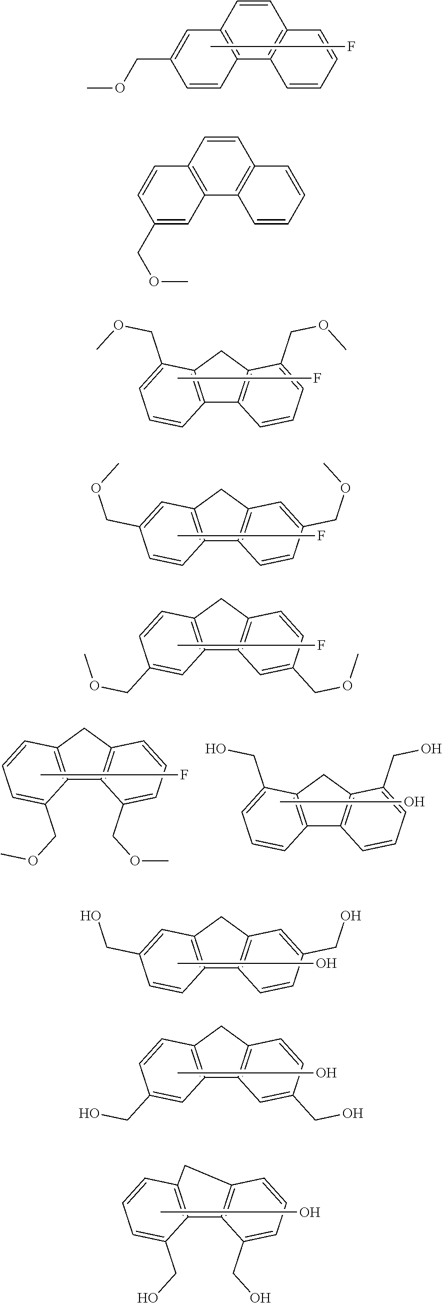

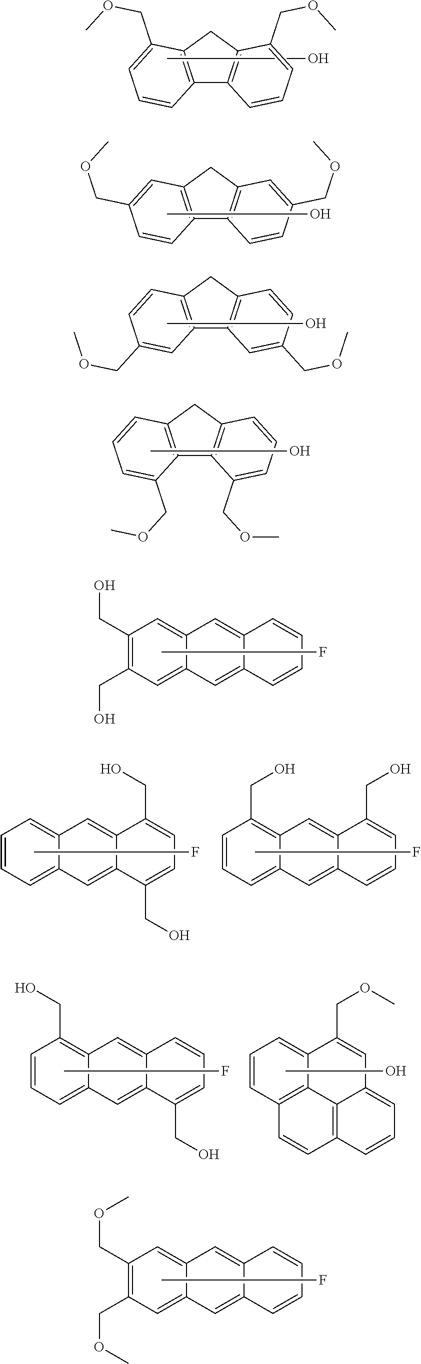

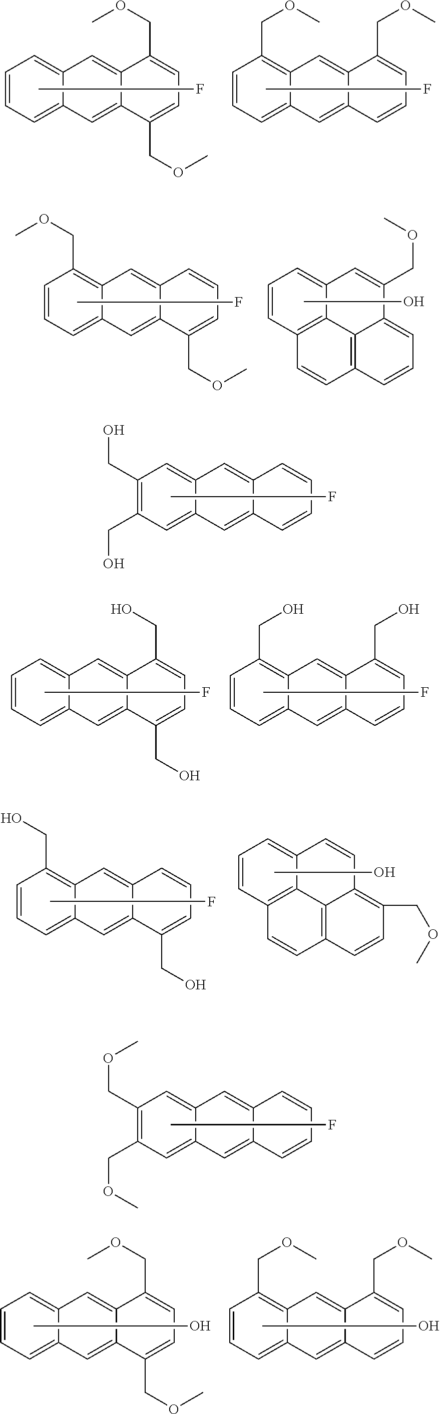

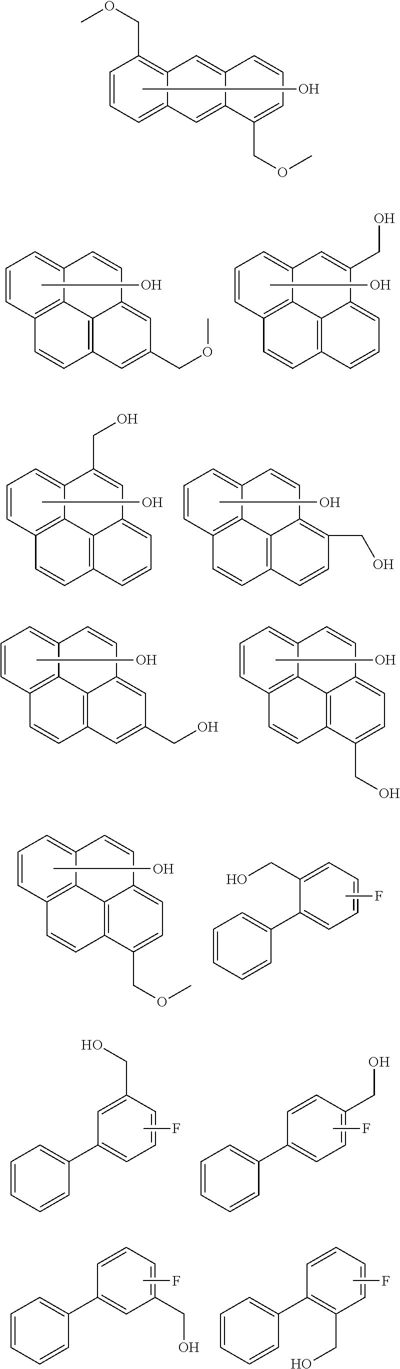

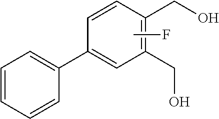

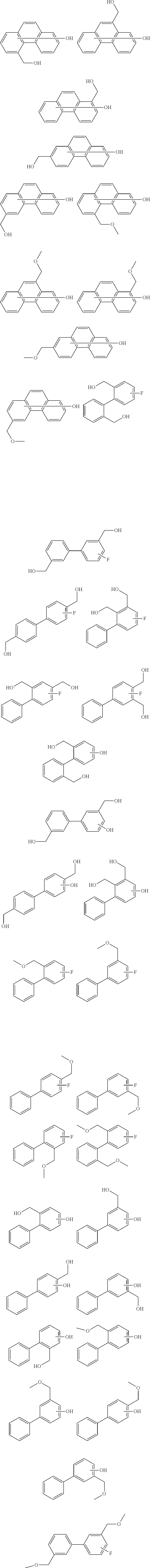

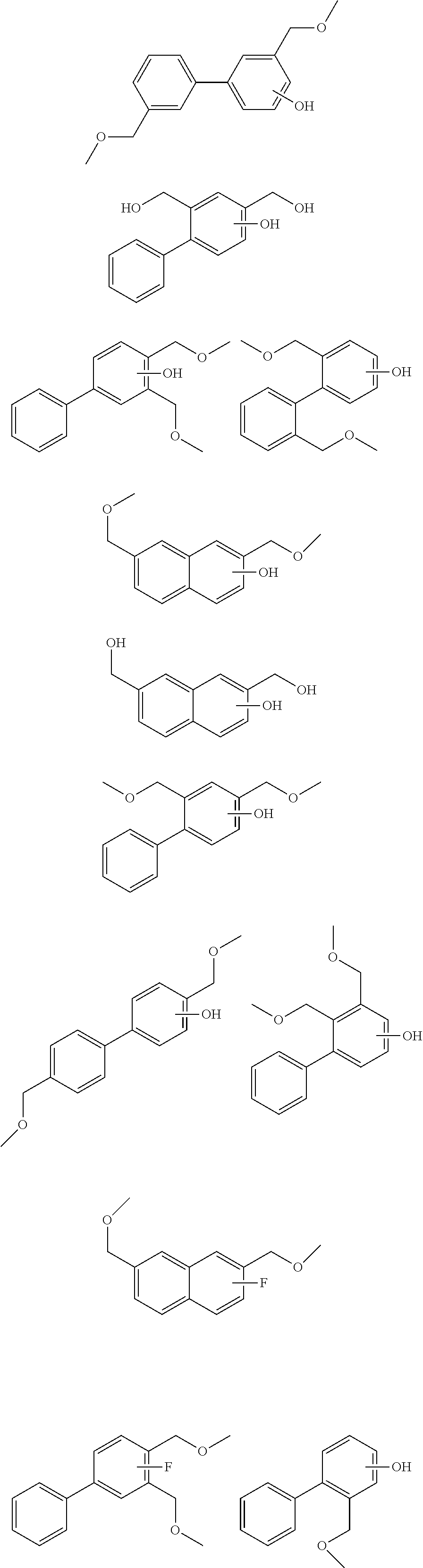

Each of the ring-containing compound and the oxygen-containing compound may be one kind of compound or a combination of two or more kinds of compounds. In this condensation reaction, the oxygen-containing compound can be used in an amount of 0.1 to 10 mol, preferably 0.1 to 2 mol per mol of the ring-containing compound.

Examples of a catalyst that can be used in the condensation reaction include: mineral acids such as sulfuric acid, phosphoric acid, and perchloric acid; organic sulfonic acids such as p-toluenesulfonic acid, p-toluenesulfonic acid monohydrate, methanesulfonic acid, and trifluoromethanesulfonic acid; and carboxylic acids such as formic acid and oxalic acid. The amount of the catalyst to be used depends on the type of catalyst to be used, but is usually 0.001 to 10,000 parts by mass, preferably 0.01 to 1,000 parts by mass, more preferably 0.05 to 100 parts by mass per 100 parts by mass of the ring-containing compound (or the total amount of two or more kinds of ring-containing compounds when they are used in combination).

The condensation reaction may be performed without using a solvent, but is usually performed using a solvent. The solvent is not limited as long as it can dissolve reactive substrates and does not inhibit the reaction. Examples of such a solvent include 1,2-dimethoxyethane, diethylene glycol dimethyl ether, propylene glycol monomethyl ether, propylene glycol monomethyl ether acetate, tetrahydrofuran, dioxane, 1,2-dichloromethane, 1,2-dichloroethane, toluene, N-methylpyrrolidone, and dimethylformamide. The temperature of the condensation reaction is usually 40° C. to 200° C., preferably 100° C. to 180° C. A reaction time depends on the reaction temperature, but is usually 5 minutes to 50 hours, preferably 5 minutes to 24 hours.

The weight-average molecular weight of the novolac resin according to one aspect of the present invention is usually 500 to 100,000, preferably 600 to 50,000, 700 to 10,000, or 800 to 8,000.

### <Solvent>

The resist underlayer film-forming composition according to one aspect of the present invention includes a solvent.

The solvent is not limited as long as it can dissolve the specific novolac resin and other optional components added if necessary.

Examples of such a solvent include methyl cellosolve acetate, ethyl cellosolve acetate, propylene glycol, propylene glycol monomethyl ether, propylene glycol monoethyl ether, propylene glycol monopropyl ether, methyl isobutyl carbinol, propylene glycol monobutyl ether, propylene glycol monomethyl ether acetate, propylene glycol monoethyl ether acetate, propylene glycol monopropyl ether acetate, propylene glycol monobutyl ether acetate, toluene, xylene, methyl ethyl ketone, cyclopentanone, cyclohexanone, ethyl 2-hydroxypropionate, ethyl 2-hydroxy-2-methylpropionate, ethyl ethoxyacetate, ethyl hydroxyacetate, methyl 2-hydroxy-3-methylbutanoate, methyl 3-methoxypropionate, ethyl 3-methoxypropionate, ethyl 3-ethoxypropionate, methyl 3-ethoxypropionate, methyl pyruvate, ethyl pyruvate, ethylene glycol monomethyl ether, ethylene glycol monoethyl ether, ethylene glycol monopropyl ether, ethylene glycol monobutyl ether, ethylene glycol monomethyl ether acetate, ethylene glycol monoethyl ether acetate, ethylene glycol monopropyl ether acetate, ethylene glycol monobutyl ether acetate, diethylene glycol monomethyl ether, diethylene glycol monoethyl ether, diethylene glycol dimethyl ether, diethylene glycol diethyl ether, diethylene glycol dipropyl ether, diethylene glycol dibutyl ether, propylene glycol monomethyl ether, propylene glycol dimethyl ether, propylene glycol diethyl ether, propylene glycol dipropyl ether, propylene glycol dibutyl ether, ethyl lactate, propyl lactate, isopropyl lactate, butyl lactate, isobutyl lactate, methyl formate, ethyl formate, propyl formate, isopropyl formate, butyl formate, isobutyl formate, amyl formate, isoamyl formate, methyl acetate, ethyl acetate, amyl acetate, isoamyl acetate, hexyl acetate, methyl propionate, ethyl propionate, propyl propionate, isopropyl propionate, butyl propionate, isobutyl propionate, methyl butyrate, ethyl butyrate, propyl butyrate, isopropyl butyrate, butyl butyrate, isobutyl butyrate, ethyl hydroxyacetate, methyl 2-hydroxy-2-methylpropionate, ethyl 2-hydroxy-2-methylpropionate, methyl 3-methoxy-2-methylpropionate, methyl 2-hydroxy-3-methylbutyrate, ethyl methoxyacetate, ethyl ethoxyacetate, methyl 3-methoxypropionate, ethyl 3-ethoxypropionate, ethyl 3-methoxypropionate, 3-methoxybutyl acetate, 3-methoxypropyl acetate, 3-methyl-3-methoxybutyl acetate, 3-methyl-3-methoxybutyl propionate, 3-methyl-3-methoxybutyl butyrate, methyl acetoacetate, toluene, xylene, methyl ethyl ketone, methyl propyl ketone, methyl butyl ketone, 2-heptanone, 3-heptanone, 4-heptanone, N,N-dimethylformamide, N-methylacetamide, N,N-dimethylacetamide, N-methylpyrrolidone, 4-methyl-2-pentanol, and γ-butyrolactone. These solvents may be used singly or in combination of two or more of them.

The solvent may be a combination of a solvent having a boiling point of 160° C., or more and a solvent having a boiling point of less than 160° C. As such a high-boiling solvent, for example, a compound described in WO2018/131562 (A1) is preferably used which is shown below.

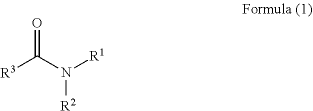

[in Formula (i), R¹, R², and R³ are each a hydrogen atom or a C₁₋₂₀ alkyl group that may be interrupted by an oxygen atom, a sulfur atom, or an amide bond, may be the same or different from each other, and may bind to each other to form a ring structure].

Alternatively, 1,6-diacetoxyhexane (boiling point 260° C.) or tripropylene glycol monomethyl ether (boiling point 242° C.) described in JP 2021-84974 A or any one of various other high-boiling solvents disclosed in paragraph [0082] in JP 2021-84974 A is preferably used.

Alternatively, dipropylene glycol monomethyl ether acetate (boiling point 213° C.), diethylene glycol monoethyl ether acetate (boiling point 217° C.), diethylene glycol monobutyl ether acetate (boiling point 247° C.), dipropylene glycol dimethyl ether (boiling point 171° C.), dipropylene glycol monomethyl ether (boiling point 187° C.), dipropylene 20 glycol monobutyl ether (boiling point 231° C.), tripropylene glycol monomethyl ether (boiling point 242° C.), γ-butyrolactone (boiling point 204° C.), benzyl alcohol (boiling point 205° C.), propylene carbonate (boiling point 242° C.), tetraethylene glycol dimethyl ether (boiling point 275° C.), 1,6-diacetoxyhexane (boiling point 260° C.), dipropylene glycol (boiling point 230° C.), or 1,3-butylene glycol diacetate (boiling point 232° C.) described in JP 2019-20701 A or any one of various other high-boiling solvents described in paragraphs [0023] to [0031] in JP 2019-20701 A is preferably used.

<Acid and/or Salt Thereof and/or Acid Generator>

The resist underlayer film-forming composition according to one aspect of the present invention may include an acid and/or a salt thereof and/or an acid generator.

Examples of the acid include p-toluenesulfonic acid, trifluoromethanesulfonic acid, salicylic acid, 5-sulfosalicylic acid, 4-phenolsulfonic acid, camphorsulfonic acid, 4-chlorobenzenesulfonic acid, benzenedisulfonic acid, 1-naphthalenesulfonic acid, citric acid, benzoic acid, hydroxybenzoic acid, and naphthalenecarboxylic acid.

The salt may be a salt of the acid described above. The salt is not limited, but an ammonia derivative salt such as a trimethylamine salt or a triethylamine salt, a pyridine derivative salt, a morpholine derivative salt, or the like can suitably be used.

These acids and/or salts thereof may be used singly or in combination of two or more of them. The amount of the acid and/or the salt thereof to be added is usually 0.0001 to 20% by mass, preferably 0.0005 to 10% by mass, more preferably 0.01 to 5% by mass relative to a total solid content.

The acid generator may be a thermal acid generator or a photo acid generator.

Examples of the thermal acid generator include 2,4,4,6-tetrabromocyclohexadienone, benzointosylate, 2-nitrobenzyltosylate, K-PURE (R) CXC-1612, K-PURE (R) CXC-1614, K-PURE (R) TAG-2172, K-PURE (R) TAG-2179, K-PURE (R) TAG-2678, K-PURE (R) TAG-2689, and K-PURE (R) TAG-2700 (manufactured by King Industries), SI-45, SI-60, SI-80, SI-100, SI-110, and SI-150 (manufactured by SANSHIN CHEMICAL INDUSTRY CO., LTD.), and other organic sulfonic acid alkyl esters.

The photo acid generator generates acid during exposure of a resist to light. This makes it possible to adjust the acidity of a underlayer film. This is one of methods for adjusting the acidity of an underlayer film to that of a resist as an upper layer. Further, adjusting the acidity of an underlayer film makes it possible to adjust the pattern shape of a resist formed as an upper layer.

Examples of the photo acid generator contained in the resist underlayer film-forming composition according to the present invention include an onium salt compound, a sulfonimide compound, and a disulfonyldiazomethane compound.

Examples of the onium salt compound include: iodonium salt compounds such as diphenyliodonium hexafluorophosphate, diphenyliodonium trifluoromethanesulfonate, diphenyliodonium nonafluoro-n-butanesulfonate, diphenyliodonium perfluoro-n-octanesulfonate, diphenyliodonium camphorsulfonate, bis(4-tert-butylphenyl)iodonium camphorsulfonate, and bis(4-tert-butylphenyl)iodonium trifluoromethanesulfonate; and sulfonium salt compounds such as triphenylsulfonium hexafluoroantimonate, triphenylsulfonium nonafluoro-n-butanesulfonate, triphenylsulfonium camphorsulfonate, and triphenylsulfonium trifluoromethanesulfonate.

Examples of the sulfonimide compound include N-(trifluoromethanesulfonyloxy)succinimide, N-(nonafluoro-n-butanesulfonyloxy)succinimide, N-(camphorsulfonyloxy)succinimide, and N-(trifluoromethanesulfonyloxy)naphthalimide.

Examples of the disulfonyldiazomethane compound include bis(trifluoromethylsulfonyl)diazomethane, bis(cyclohexylsulfonyl)diazomethane, bis(phenylsulfonyl)diazomethane, bis(p-toluenesulfonyl)diazomethane, bis(2,4-dimethylbenzenesulfonyl)diazomethane, and methylsulfonyl-p-toluenesulfonyldiazomethane.

These acid generators may be used singly or in combination of two or more of them.

When the acid generator is used, the amount of the acid generator is 0.01 to 10 parts by mass, 0.1 to 8 parts by mass, or 0.5 to 5 parts by mass per 100 parts by mass of the solid content of the resist underlayer film-forming composition.

### <Other Optional Components>

If necessary, the resist underlayer film-forming composition according to one aspect of the present invention may include a component other than the above components, such as a crosslinking agent, a surfactant, a light absorber, a rheology adjuster, an adhesive aid, or a curing catalyst.

### <Crosslinking Agent>

Examples of a typical crosslinking agent include an aminoplast crosslinking agent and a phenoplast crosslinking agent.

As the crosslinking agent, a crosslinking agent having high heat resistance can be used. As such a crosslinking agent having high heat resistance, a compound is preferably used which contains, in its molecule, a crosslink-forming substituent having an aromatic ring (e.g., a benzene ring or a naphthalene ring).

Examples of the aminoplast crosslinking agent include highly alkylated, alkoxylated, or alkoxyalkylated melamine, benzoguanamine, glycoluril, and urea and polymers thereof. Preferred is a crosslinking agent having at least two crosslink-forming substituents, and examples thereof include compounds such as methoxymethylated glycoluril, butoxymethylated glycoluril, methoxymethylated melamine, butoxymethylated melamine, methoxymethylated benzoguanamine, butoxymethylated benzoguanamine, methoxymethylated urea, butoxymethylated urea, methoxymethylated thiourea, and methoxymethylated thiourea. Condensation products of these compounds may also be used.

Preferred is at least one selected from the group consisting of tetramethoxymethylglycoluril and hexamethoxymethylmelamine.

Some specific examples are as shown below.

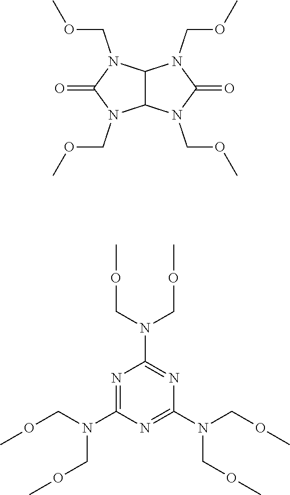

Examples of the phenoplast crosslinking agent include highly-alkylated, alkoxylated, or alkoxyalkylated aromatic series and polymers thereof. Preferred is a crosslinking agent having at least two crosslink-forming substituents in one molecule thereof, and examples thereof include compounds such as 2,6-dihydroxymethyl-4-methylphenol, 2,4-dihydroxymethyl-6-methylphenol, bis(2-hydroxy-3-hydroxymethyl-5-methylphenyl)methane, bis(4-hydroxy-3-hydroxymethyl-5-methylphenyl)methane, 2,2-bis(4-hydroxy-3,5-dihydroxymethylphenyl)propane, bis(3-formyl-4-hydroxyphenyl)methane, bis(4-hydroxy-2,5-dimethylphenyl)formylmethane, and α,α-bis(4-hydroxy-2,5-dimethylphenyl)-4-formyltoluene. Condensation products of these compounds may also be used.

Examples of such a compound other than the above compounds include a compound having a partial structure of the following Formula (4) and a polymer or oligomer having a repeating unit of the following Formula (5).

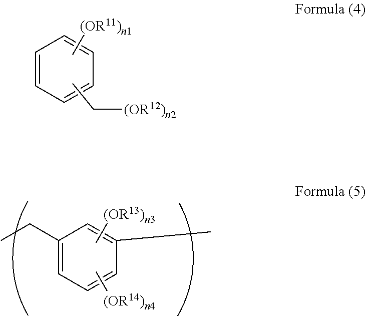

R¹¹, R¹², R¹³, and R¹⁴ are each a hydrogen atom or a C₁₋₁₀ alkyl group, and examples of the alkyl group may be those exemplified above. n1 is an integer of 1 to 4, n2 is an integer of 1 to (5−n1), (n1+n2) is an integer of 2 to 5, n3 is an integer of 1 to 4, n4 is 0 to (4-n3), and (n3+n4) is an integer of 1 to 4. The oligomer or polymer having a number of repeating unit structures of 2 to 100 or 2 to 50 can be used.

Some specific examples are as shown below.

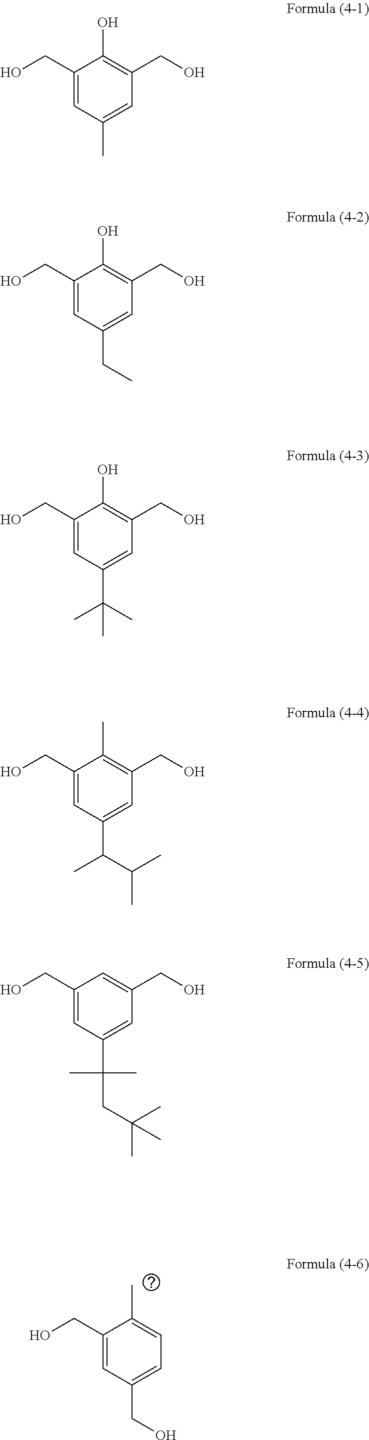 [SMILES: Cc1cc(CO)c(O)c(CO)c1 ; CCc1cc(CO)c(O)c(CO)c1 ; CC(C)(C)c1cc(CO)c(O)c(CO)c1 ; Cc1c(CO)cc(C(C)C(C)C)cc1CO ; CC(C)(C)CC(C)(C)c1cc(CO)cc(CO)c1 ; Cc1ccc(CO)cc1CO]

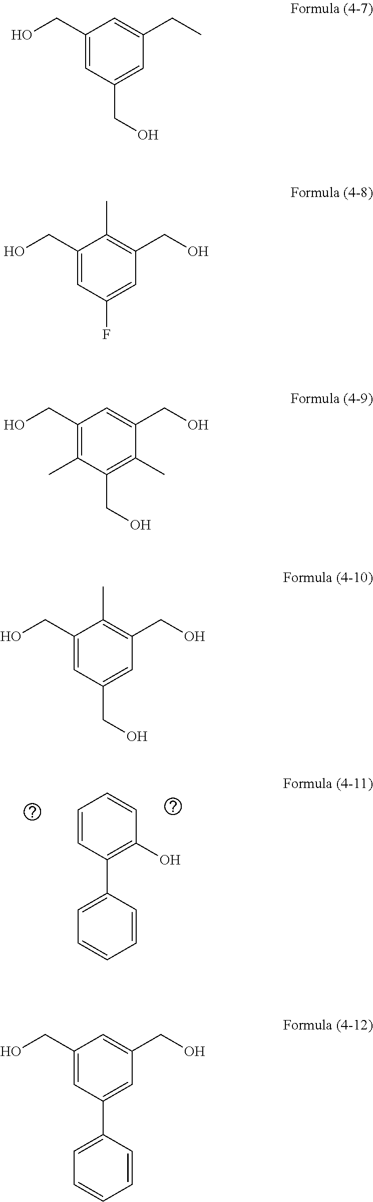 [SMILES: CCc1cc(CO)cc(CO)c1 ; Cc1c(CO)cc(F)cc1CO ; Cc1c(CO)cc(CO)c(C)c1CO ; Cc1c(CO)cc(CO)cc1CO ; Oc1ccccc1-c1ccccc1 ; OCc1cc(CO)cc(-c2ccccc2)c1]

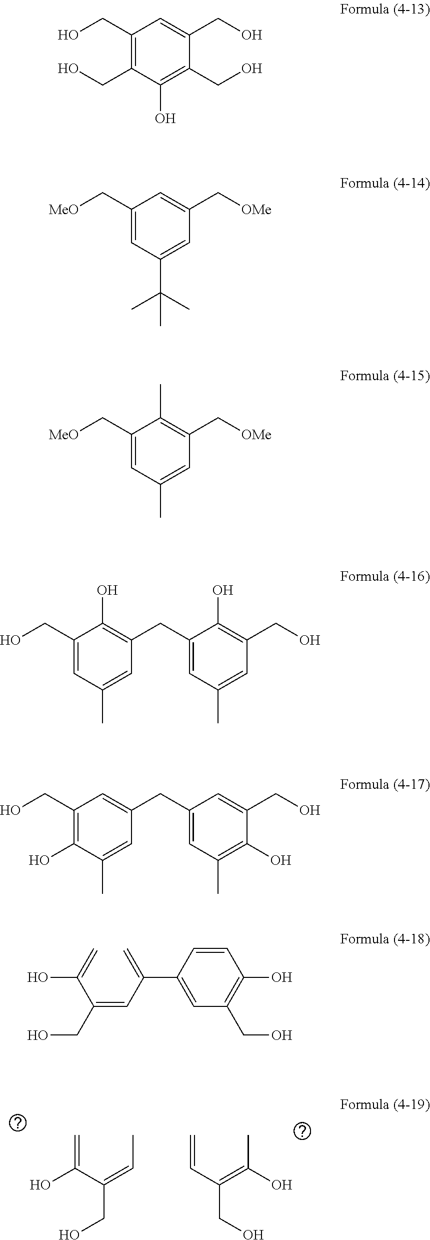

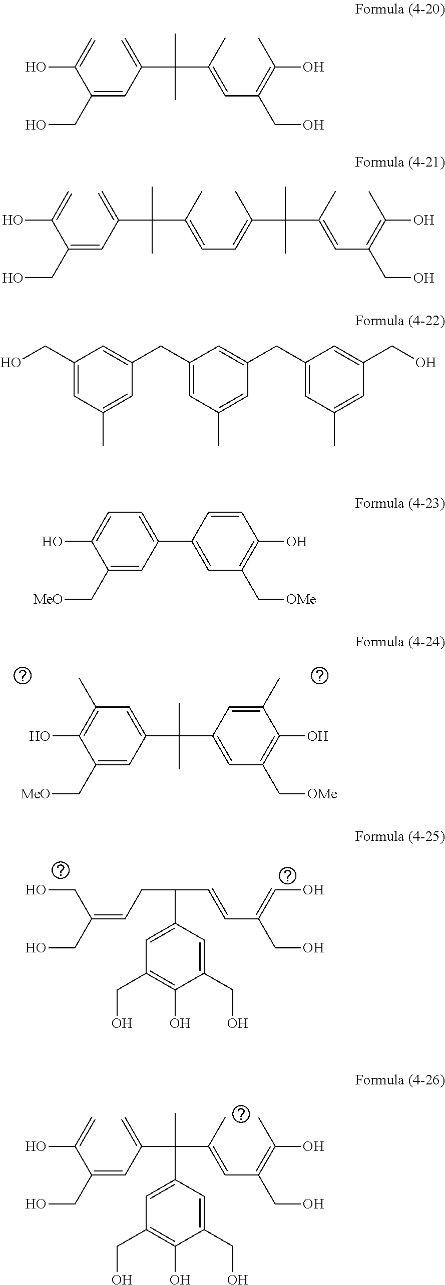

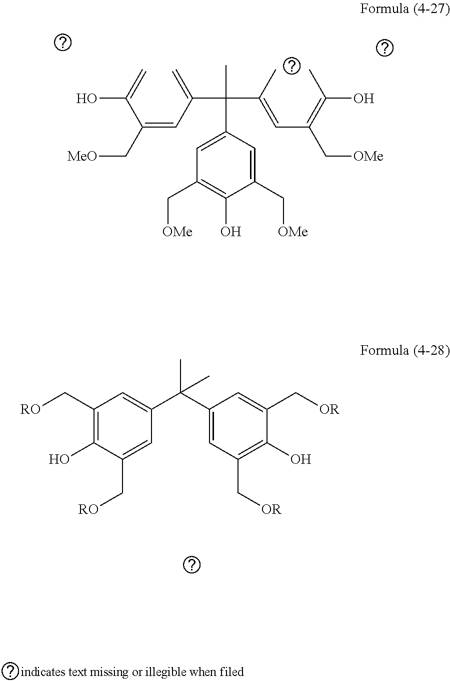

These crosslinking agents such as the aminoplast crosslinking agents and the phenoplast crosslinking agents may be used singly or in combination of two or more of them. The aminoplast crosslinking agent can be produced by a method known per se or a method analogous thereto. Alternatively, a commercially-available product may be used.

The amount of the crosslinking agents such as the aminoplast crosslinking agents or the phenoplast crosslinking agent to be used varies depending on, for example, the type of coating solvent to be used, the type of base substrate to be used, the viscosity of a solution required, or the shape of a film required, but is 0.001% by mass or more, 0.01% by mass or more, 0.05% by mass or more, 0.5% by mass or more, or 1.0% by mass or more and 80% by mass or less, 50% by mass or less, 40% by mass or less, 20% by mass or less, or 10% by mass or less relative to the total solid content of the resist underlayer film-forming composition according to the present invention.

### <Surfactant>

The resist underlayer film-forming composition according to the present invention may include a surfactant to further improve applicability against surface irregularities without generating pinholes, striation, and the like.

Examples of the surfactant include:
nonionic surfactants such as polyoxyethylene alkyl ethers such as polyoxyethylene lauryl ether, polyoxyethylene stearyl ether, polyoxyethylene cetyl ether, and polyoxyethylene oleyl ether, polyoxyethylene alkylaryl ethers such as polyoxyethylene octylphenol ether and polyoxyethylene nonylphenol ether, polyoxyethylene-polyoxypropylene block copolymers, sorbitan fatty acid esters such as sorbitan monolaurate, sorbitan monopalmitate, sorbitan monostearate, sorbitan monooleate, sorbitan trioleate, and sorbitan tristearate, and polyoxyethylene sorbitan fatty acid esters such as polyoxyethylene sorbitan monolaurate, polyoxyethylene sorbitan monopalmitate, polyoxyethylene sorbitan monostearate, polyoxyethylene sorbitan trioleate, and polyoxyethylene sorbitan tristearate;
fluorine-based surfactants such as FETOP EF301, EF303, and EF352 (trade names, manufactured by Tohkem Products Corporation), MEGAFACE F171, F173, R-30, and R-40 (trade names, manufactured by DIC Corporation), Fluorad FC430 and FC431 (trade names, Sumitomo 3M Limited), AsahiGuard AG710 and Surflon S-382, SC101, SC102, SC103, SC104, SC105, and SC106 (trade names, manufactured by Asahi Glass Co., Ltd.; and
organosiloxane polymer KP341 (manufactured by Shin-Etsu Chemical Co., Ltd.).

The amount of the surfactant to be added is usually 2.0% by mass or less, preferably 1.0% by mass or less relative to the total solid content of the resist underlayer film-forming composition according to the present invention. These surfactants may be added singly or in combination of two or more of them.

### <Other Additives>

Examples of the light absorber that can suitably be used include commercially-available light absorbers described in “Technology and Market of Industrial Dyes” (CMC Publishing Co., Ltd.) and “Dye Handbook” (edited by The Society of Synthetic Organic Chemistry, Japan) such as C.I. Disperse Yellow 1, 3, 4, 5, 7, 8, 13, 23, 31, 49, 50, 51, 54, 60, 64, 66, 68, 79, 82, 88, 90, 93, 102, 114, and 124; C.I. Disperse Orange 1,5,13,25,29,30,31,44,57,72, and 73; C.I. Disperse Red 1,5,7,13,17,19,43, 50, 54, 58, 65, 72, 73, 88, 117, 137, 143, 199, and 210; C.I. Disperse Violet 43; C.I. Disperse Blue 96; C.I. Fluorescent Brightening Agent 112, 135, and 163; C.I. Solvent Orange 2 and 45; C.I. Solvent Red 1, 3, 8, 23, 24, 25, 27, and 49; C.I. Pigment Green 10; and C.I. Pigment Brown 2. The amount of the light absorber to be added is usually 10% by mass or less, preferably 5% by mass or less relative to the total solid content of the resist underlayer film-forming composition according to the present invention.

The rheology adjuster is added for the main purpose of improving the fluidity of the resist underlayer film-forming composition, particularly for the purpose of improving the film thickness uniformity of a resist underlayer film or enhancing the fillability of the resist underlayer film-forming composition into holes in a baking process. Specific examples of the rheology adjuster include phthalic acid derivatives such as dimethyl phthalate, diethyl phthalate, diisobutyl phthalate, dihexyl phthalate, and butyl isodecyl phthalate, adipic acid derivatives such as di-normal butyl adipate, diisobutyl adipate, diisooctyl adipate, and octyldecyl adipate, maleic acid derivatives such as di(n-butyl) maleate, diethyl maleate, and dinonyl maleate, oleic acid derivatives such as methyl oleate, butyl oleate, and tetrahydrofurfuryl maleate, and stearic acid derivatives such as n-butyl stearate and glyceryl stearate. The amount of the rheology adjuster to be added is usually less than 30% by mass relative to the total solid content of the resist underlayer film-forming composition according to the present invention.

The adhesion aid is added for the main purpose of improving adhesiveness between a substrate or a resist and the resist underlayer film-forming composition, particularly for the purpose of preventing peeling-off of the resist during development. Specific examples of the adhesion aid include chlorosilanes such as trimethylchlorosilane, dimethylvinylchlorosilane, methyldiphenylchlorosilane, and chloromethyldimethylchlorosilane, alkoxysilanes such as trimethylmethoxysilane, dimethyldiethoxysilane, methyldimethoxysilane, dimethylvinylethoxysilane, diphenyldimethoxysilane, and phenyltriethoxysilane, silazanes such as hexamethyldisilazane, N,N′-bis(trimethylsilyl)urea, and dimethyltrimethylsilylamine, trimethylsilylimidazole, silanes such as vinyltrichlorosilane, γ-chloropropyltrimethoxysilane, γ-aminopropyltriethoxysilane, and γ-glycidoxypropyltrimethoxysilane, heterocyclic compounds such as benzotriazole, benzimidazole, indazole, imidazole, 2-mercaptobenzimidazole, 2-mercaptobenzothiazole, 2-mercaptobenzoxazole, urazole, thiourasil, mercaptoimidazole, and mercaptopyrimidine, ureas such as 1,1-dimethylurea and 1,3-dimethylurea, and thiourea compounds. The amount of the adhesion aid to be added is usually less than 5% by mass, preferably less than 2% by mass relative to the total solid content of the resist underlayer film-forming composition according to the present invention.

The curing catalyst is effective at curing a film. Specific examples of the curing catalyst include, but are not limited to, sulfonium salt compounds such as triphenylsulfonium nitrate, triphenylsulfonium maleate, triphenylsulfonium trifluoroacetate, triphenylsulfonium hydrochloride, and triphenylsulfonium acetate.

The solid content of the resist underlayer film-forming composition according to the present invention is 0.1 to 70% by mass or 0.1 to 60% by mass. The solid content refers to the content of all the components of the resist underlayer film-forming composition excluding the solvent. The percentage of a crosslinkable resin contained in solid matter may be 1 to 99.9% by mass, 50 to 99.9% by mass, 50 to 95% by mass, or 50 to 90% by mass.

### <Resist Underlayer Film>

A resist underlayer film can be formed, for example, in the following manner using the resist underlayer film-forming composition according to the present invention.

The resist underlayer film-forming composition according to one aspect of the present invention is applied onto a substrate used for producing a semiconductor device (e.g., a silicon wafer substrate, a silicon dioxide-coated substrate (SiO₂ substrate), a silicon nitride substrate (SiN substrate), a silicon oxynitride substrate (SiON substrate), a titanium nitride substrate (TiN substrate), a tungsten substrate (W substrate), a glass substrate, an ITO substrate, a polyimide substrate, or a low-dielectric material (low-k material)-coated substrate) by an appropriate coating method using a spinner, a coater, or the like and is then baked using a heating means such as a hot plate to form a resist underlayer film. Conditions for baking are appropriately selected from a baking temperature of 80° C. to 800° C. and a baking time of 0.3 to 60 minutes. Preferably, the baking temperature is 150° C. to 400° C. and the baking time is 0.5 to 2 minutes. An atmosphere gas used for baking may be air or an inert gas such as nitrogen or argon. According to one aspect, the concentration of oxygen is particularly preferably 1% or less. The film thickness of the underlayer film formed here is, for example, 10 to 1000 nm, 20 to 500 nm, 30 to 400 nm, or 50 to 300 nm. When a quartz substrate is used as a substrate, a replica (mold replica) of a quartz imprint mold can be produced.

A adhesion layer and/or a silicon-containing layer containing 99% by mass or less or 50% by mass or less of Si may be formed by coating or vapor deposition on the resist underlayer film according to one aspect of the present invention. For example, an adhesion layer described in JP 2013-202982 A or Japanese Patent No. 5827180 may be formed, a silicon-containing resist underlayer film (inorganic resist underlayer film)-forming composition disclosed in WO 2009/104552 (A1) may be applied by spin coating, or a Si-based inorganic material film may be formed by CVD.

The resist underlayer film-forming composition according to one aspect of the present invention may be applied onto a semiconductor substrate having a stepped portion and a step-free portion (a so-called stepped substrate) and baked to reduce a level difference between the stepped portion and the step-free portion.

### <Method for Producing Semiconductor Device>

(i)

A method for producing a semiconductor device according to one aspect of the present invention comprises the steps of:
forming a resist underlayer film on a semiconductor substrate with use of the resist underlayer film-forming composition according to one aspect of the present invention;
forming a resist film on the resist underlayer film;
forming a resist pattern in the resist film by light or electron beam irradiation and development;
patterning the resist underlayer film by etching using the resist pattern; and
subjecting the semiconductor substrate to processing using the patterned resist underlayer film.
   (ii)

A method for producing a semiconductor device according to one aspect of the present invention comprises the steps of:
forming a resist underlayer film on a semiconductor substrate with use of the resist underlayer film-forming composition according to one aspect of the present invention;
forming a hard mask on the resist underlayer film;
further forming a resist film on the hard mask;
forming a resist pattern in the resist film by light or electron beam irradiation and development;
patterning the hard mask by etching using the resist pattern;
patterning the resist underlayer film by etching using the patterned hard mask; and
subjecting the semiconductor substrate to processing using the patterned resist underlayer film.
   (iii)

A method for producing a semiconductor device according to one aspect of the present invention comprises the steps of:
forming a resist underlayer film on a semiconductor substrate with use of the resist underlayer film-forming composition according to one aspect of the present invention;
forming a hard mask on the resist underlayer film;
further forming a resist film on the hard mask;
forming a resist pattern in the resist film by light or electron beam irradiation and development;
patterning the hard mask by etching using the resist pattern;
patterning the resist underlayer film by etching using the patterned hard mask;
removing the hard mask; and
subjecting the semiconductor substrate to processing using the patterned resist underlayer film.
   (iv)

A method for producing a semiconductor device according to one aspect of the present invention comprises the steps of.
forming a resist underlayer film on a semiconductor substrate with use of the resist underlayer film-forming composition according to one aspect of the present invention;
forming a hard mask on the resist underlayer film;
further forming a resist film on the hard mask;
forming a resist pattern in the resist film by light or electron beam irradiation and development;
patterning the hard mask by etching using the resist pattern;
patterning the resist underlayer film by etching using the etched hard mask;
removing the hard mask;
forming a vapor-deposited film (spacer) on the resist underlayer film after removing the hard mask;
processing the vapor-deposited film (spacer) by etching;
removing the patterned resist underlayer film so that the patterned vapor-deposited film (spacer) remains; and
subjecting the semiconductor substrate to processing using the patterned vapor-deposited film (spacer).

A semiconductor substrate can be processed by any one of the above production methods (i) to (iv).

The step of forming a resist underlayer film with use of the resist underlayer film-forming composition according to one aspect of the present invention is as described above with reference to the above section <Resist underlayer film>.

On the resist underlayer film formed in the above-described step, a hard mask such as a silicon-containing film may be formed as a second resist underlayer film, which is followed by forming a resist pattern thereon [the above (ii) to (iv)].

The hard mask may be a coating film of an inorganic material-containing composition or the like or a vapor-deposited film of an inorganic material or the like formed by vapor deposition such as CVD or PVD, and examples thereof include a SiON film, a SiN film, and a SiO₂ film.

On the hard mask, an anti-reflective coating (Bottom Anti-Reflective Coating, BARC) or a resist shape-correcting film having no antireflection ability may further be formed.

In the step of forming a resist pattern, exposure is performed through a mask (reticle) for forming a predetermined pattern or by direct writing. Examples of a usable exposure source include g ray, i ray, KrF excimer laser, ArF excimer layer, EUV, and electron beam. After exposure, post-exposure bake is performed, if necessary. Then, development is performed using a developer (e.g., an aqueous 2.38% by mass tetramethylammonium hydroxide solution) and washing with a rinse solution or pure water is further performed to remove the developer used. Then, post bake is performed to dry the resist pattern and enhance adhesiveness with the substrate.

The etching step performed after forming the resist pattern is performed by dry etching.

Patterning of the resist film may be performed by nanoimprinting or a self-assembled film method.

In nanoimprinting, a resist composition is molded using a patterned mold transparent to irradiation light. In a self-assembled film method, a pattern is formed using a self-assembled film of a diblock polymer (e.g., polystyrene-polymethyl methacrylate) or the like that has a naturally-formed regular structure on the order of nanometers.

In nanoimprinting, before applying a curable composition for forming a resist film, a silicon-containing layer (hard mask layer) may optionally be formed on the resist underlayer film by coating or vapor deposition. Further, an adhesion layer may be formed on the resist underlayer film or the silicon-containing layer by coating or vapor deposition, which is followed by applying a curable composition for forming a resist layer on the adhesion layer.

It should be noted that various gases i.e., CF₄, CHF₃, CH₂F₂, CH₃F, C₄F₆, C₄F8, O₂, N₂O, NO₂, He, and H₂ can be used for processing the hard mask (silicon-containing layer), the resist underlayer film, and the substrate. These gases may be used singly or in combination of two or more of them. Further, these gases may be used in combination with argon, nitrogen, carbon dioxide, carbonyl sulfide, sulfur dioxide, neon, or nitrogen trifluoride.

It should be noted that for the purpose of simplifying the steps of processing or reducing damage to a substrate to be processed, wet etching may be performed. This leads to suppressing variation of processing dimensions or reducing pattern roughness, thereby making it possible to process substrates at high yield. Therefore, in the above (ii) to (iv), removal of the hard mask may be performed either by etching or using an alkali chemical solution. Particularly, when an alkali chemical solution is used, its components are not limited, but an alkali component described below is preferably contained.

Examples of the alkali component include tetramethylammonium hydroxide, tetraethylammonium hydroxide, tetrapropylammonium hydroxide, tetrabutylammonium hydroxide, methyltripropylammonium hydroxide, methyltributylammonium hydroxide, ethyltrimethylammonium hydroxide, dimethyldiethylammonium hydroxide, benzyltrimethylammonium hydroxide, hexadecyltrimethylammonium hydroxide, (2-hydroxyethyl)trimethylammonium hydroxide, monoethanolamine, diethanolamine, triethanolamine, 2-(2-aminoethoxy)ethanol, N,N-dimethylethanolamine, N,N-diethylethanolamine, N,N-dibutylethanolamine, N-methylethanolamine, N-ethylethanolamine, N-butylethanolamine, N-methyldiethanolamine, monoisopropanolamine, diisopropanolamine, triisopropanolamine, tetrahydrofurfurylamine, N-(2-aminoethyl)piperazine, 1,8-diazabicyclo[5.4.0]undec-7-ene, 1,4-diazabicyclo[2.2.2]octane, hydroxyethylpiperazine, piperazine, 2-methylpiperazine, trans-2,5-dimethylpiperazine, cis-2,6-dimethylpiperazine, 2-piperidinemethanol, cyclohexylamine, and 1,5-diazabicyclo[4,3,0]non-5-ene. From the viewpoint of handling, tetramethylammonium hydroxide and tetraethylammonium hydroxide are particularly preferred, and an inorganic base may be used in combination with a quaternary ammonium hydroxide. The inorganic base is preferably a hydroxide of an alkali metal such as potassium hydroxide, sodium hydroxide, or rubidium hydroxide, more preferably potassium hydroxide.

### EXAMPLES

### (1) Synthesis of Polymers

Polymers of structural formulas (S1) to (S20) as comparative examples and polymers of structural formulas (S′1) to (S′25) used for resist underlayer films were synthesized using a compound group A, a compound group B, a compound group C, a catalyst group D, a solvent group E, and a reprecipitation solvent group F described below.

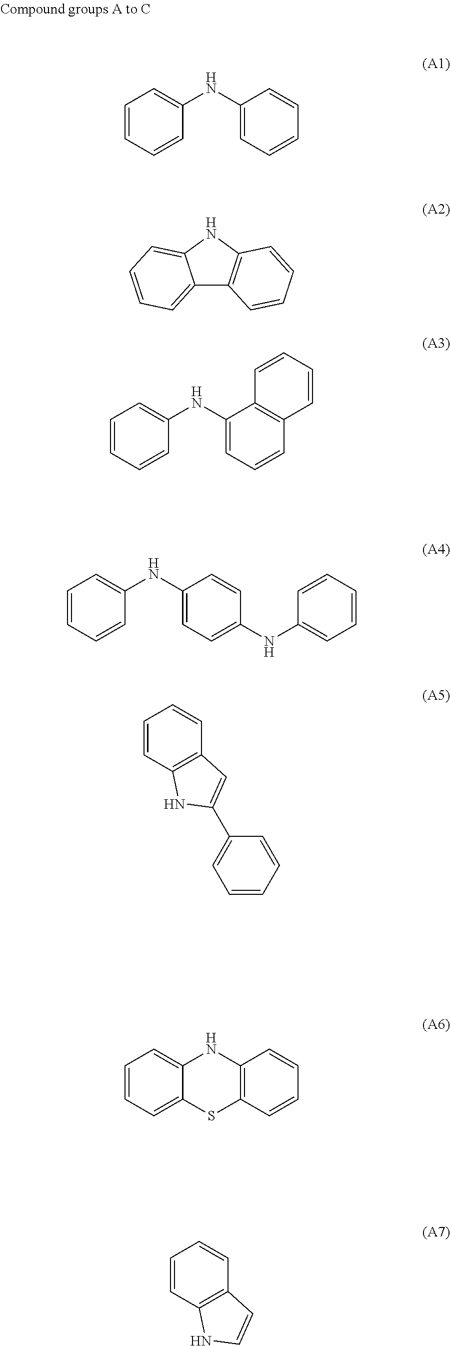

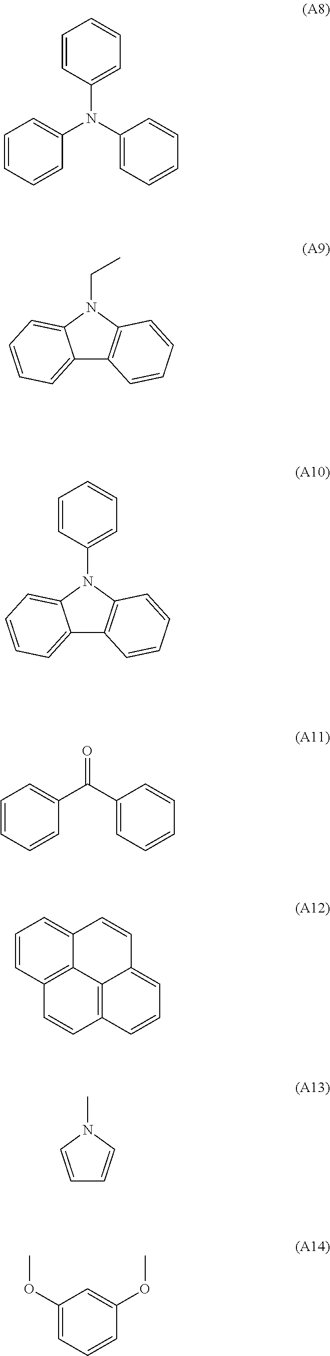

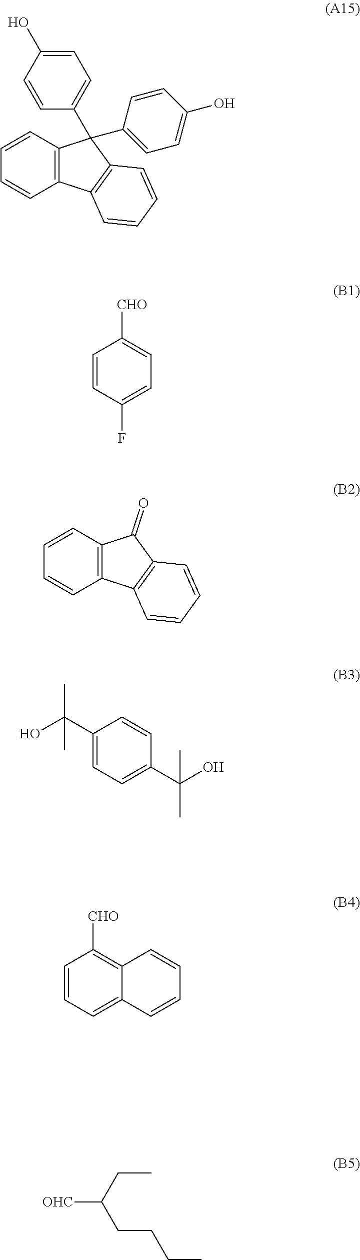

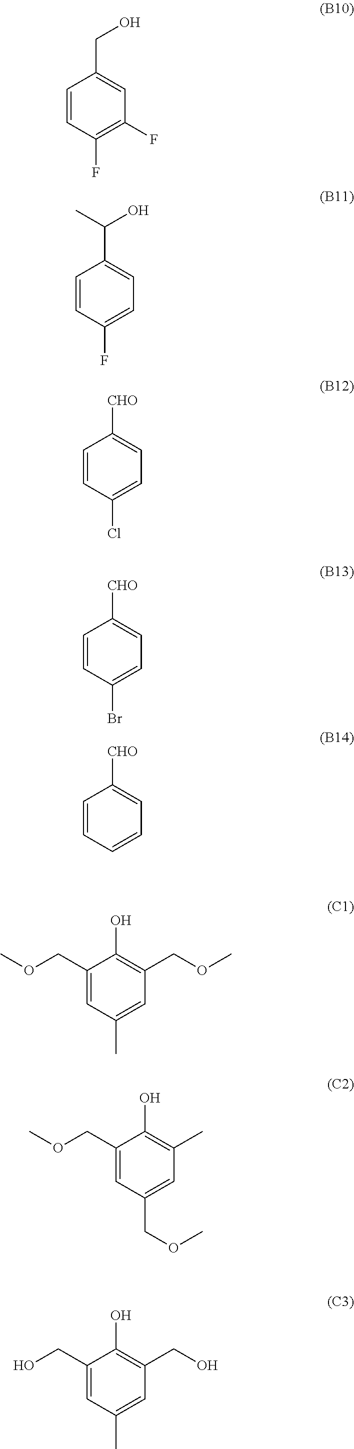

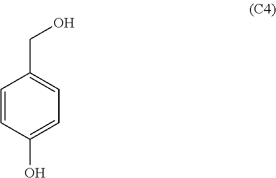

Catalyst group D, Solvent group E, Reprecipitation solvent group F, and Separating solvent group G
Methanesulfonic acid: D1
Potassium carbonate: D2
Propylene glycol monomethyl ether acetate (=PGMEA): E1
N-methylpyrrolidone: E2
Methanol: F1
Methanol/water: F2

### Synthesis Example 1

In a flask, 100.0 g of diphenylamine (A1), 73.4 g of 4-fluorobenzaldehyde (B1), 2.8 g of methanesulfonic acid, and 749.9 g of PGMEA were placed. Then, a resultant was heated to reflux in an atmosphere of nitrogen for reaction for about 4 hours. After the termination of the reaction, a resin was isolated by reprecipitation using methanol/water. The resin was dried to obtain a resin (Si). The weight-average molecular weight Mw of the resin (Si) as measured by GPC using polystyrene standards was about 4,200. The obtained resin was dissolved in PGMEA and subjected to ion-exchange using a cation exchange resin and an anion exchange resin for 4 hours to obtain a target compound solution.

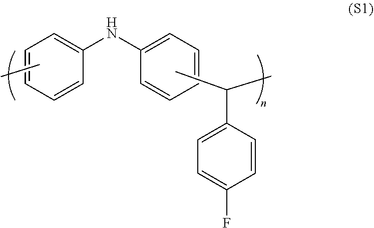

### Synthesis Example 21

In a flask, 10.0 g of the resin (S1) after reprecipitation treatment, 3.27 g of 2,6-dihydroxymethyl-4-methylphenol (C1), 2.4 g of potassium carbonate, and 36.6 g of N-methylpyrrolidone were placed. Then, a resultant was heated to 120° C. in an atmosphere of nitrogen for reaction for about 14 hours. After the termination of the reaction, the potassium carbonate was removed by filtration, and a resin was isolated by neutralization using a 1 N—HCl NMP solution and reprecipitation using methanol/water. The resin was dried to obtain a resin (S′1). The weight-average molecular weight Mw of the resin (S′1) as measured by GPC using polystyrene standards was about 5,600. The obtained resin was dissolved in PGMEA and subjected to ion-exchange using a cation exchange resin and an anion exchange resin for 4 hours to obtain a target compound solution.

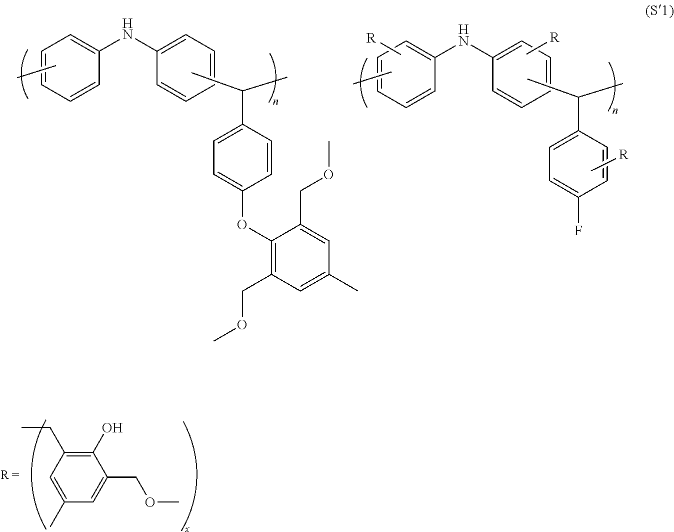

TABLE 1

| Synthesis | Structural | | | | Temperature/ | |
|---|---|---|---|---|---|---|
| Example | formula | Compound | Catalyst | Solvent | Time | Reprecipitation |
| 1 | S1 | A1/B1 | D1 | E1 | Reflux/ | F2 |
| | | 50.0 g/46.9 g | 12.5 g | 109.1 g | 16 hours | |
| 2 | S2 | A2/B1 | D1 | E1 | Reflux/ | F2 |
| | | 75.0 g/55.7 g | 4.3 g | 315.1 g | 3 hours | |
| 3 | S3 | A3/B1 | D1 | E1 | Reflux/ | F1 |
| | | 100.0 g/56.6 g | 6.6 g | 489.5 g | 3 hours | |
| 4 | S4 | A4/B1 | D1 | E1 | Reflux/ | F2 |
| | | 100.0 g/47.7 g | 5.5 g | 459.7 g | 4.5 hours | |
| 5 | S5 | A5/B1 | D1 | E1 | Reflux/ | F2 |
| | | 100.0 g/64.2 g | 10.0 g | 261.25 g | 4.5 hours | |
| 6 | S6 | A1/B1/B2 | D1 | E1 | Reflux/ | F1 |
| | | 100.0 g/66.1 g/10.7 g | 2.8 g | 675.6 g | 4 hours | |
| 7 | S7 | A1/B1/B3 | D1 | E1 | Reflux/ | F1 |
| | | 100.0 g/66.1 g/11.5 g | 2.8 g | 675.6 g | 4 hours | |
| 8 | S8 | A1/B1/B4/B5 | D1 | E1 | Reflux/ | F1 |
| | | 100.0 g/66.1 g/9.2 g/7.6 g | 2.8 g | 675.6 g | 4 hours | |
| 9 | S9 | A1/A6/A11/B1 | D1 | E1 | Reflux/ | F1 |
| | | 60.0 g/10.1 g/22.1 g/62.9 g | 2.4 g | 630.2 g | 4 hours | |
| 10 | S10 | A1/A7/A12/B1 | D1 | E1 | Reflux/ | F1 |
| | | 70.0 g/13.9 g/12.0 g/73.4 g | 2.8 g | 688.4 g | 4 hours | |
| 11 | S11 | A1/A13/A14/B1 | D1 | E1 | Reflux/ | F1 |
| | | 70.0 g/4.2 g/7.1 g/64.2 g | 2.5 g | 592.2 g | 4 hours | |
| 12 | S12 | A1/B1/B6/B7 | D1 | E1 | Reflux/ | F1 |
| | | 70.0 g/41.1 g/8.6 g/5.3 g | 2.5 g | 592.2 g | 5 hours | |
| 13 | S13 | A1/B1/B8/B9 | D1 | E1 | Reflux/ | F2 |
| | | 80.0 g/41.1 g/13.4 g/6.0 g | 1.8 g | 491.7 g | 4 hours | |
| 14 | S14 | A1/B1/B10/B11 | D1 | E1 | Reflux/ | F2 |
| | | 80.0 g/41.1 g/13.6 g/6.6 g | 2.1 g | 492.6 g | 4 hours | |
| 15 | S15 | A1/B12 | D1 | E1 | Reflux/ | F1 |
| | | 100.0 g/82.8 g | 2.8 g | 742.55 | 2.5 hours | |
| 16 | S16 | A1/B13 | D1 | E1 | Reflux/ | F1 |
| | | 25.0 g/27.2 g | 0.7 g | 211.6 g | 3 hours | |
| 17 | S17 | A1/A3/A8/B1 | D1 | E1 | Reflux/ | F1 |
| | | 70.0 g/25.9 g/14.5 g/73.4 g | 2.8 g | 746.6 g | 3 hours | |
| 18 | S18 | A1/A2/A9/B1 | D1 | E1 | Reflux/ | F1 |
| | | 70.0 g/8.7 g/10.1 g/64.2 g | 2.5 g | 621.9 g | 4 hours | |
| 19 | S19 | A2/A9/A10/B1 | D1 | E1 | 120° C./ | F1 |
| | | 60.0 g/20.0 g/12.5 g/63.7 g | 4.9 g | 375.9 g | 6 hours | |
| 20 | S20 | A15/B14 | D1 | E1 | Reflux/ | F2 |
| | | 150.0 g/45.5 g | 8.2 g | 248.9 g | 4 hours | |
| 21 | S′1 | S1/C1 | D2 | E2 | 120° C. | F2 |
| | | 10.0 g/3.3 g | 2.4 g | 36.6 g | 14 hours | |
| 22 | S′2 | S1/C2 | D2 | E2 | 120° C./ | F2 |
| | | 10.0 g/3.3 g | 2.4 g | 36.6 g | 14 hours | |
| 23 | S′3 | S2/C2 | D2 | E2 | 80° C. | F2 |
| | | 10.0 g/2.9 g | 2.2 g | 35.3 g | 14 hours | |
| 24 | S′4 | S3/C2 | D2 | E2 | 120° C./ | F2 |
| | | 10.0 g/2.9 g | 2.2 g | 35.3 g | 14.5 hours | |
| 25 | S′5 | S4/C1 | D2 | E2 | 120° C./ | F2 |
| | | 10.0 g/2.9 g | 2.2 g | 35.3 g | 14 hours | |
| 26 | S′6 | S5/C1 | D2 | E2 | 120° C./ | F2 |
| | | 10.0 g/2.9 g | 2.2 g | 35.3 g | 14 hours | |
| 27 | S′7 | S6/C1 | D2 | E2 | 120° C./ | F2 |
| | | 10.0 g/2.9 g | 2.2 g | 35.3 g | 15 hours | |
| 28 | S′8 | S7/C1 | D2 | E2 | 120° C./ | F2 |
| | | 10.0 g/2.9 g | 2.2 g | 35.3 g | 15 hours | |
| 29 | S′9 | S8/C1 | D2 | E2 | 120° C./ | F2 |
| | | 10.0 g/2.9 g | 2.2 g | 35.3 g | 14 hours | |
| 30 | S′10 | S9/C1 | D2 | E2 | 120° C./ | F2 |
| | | 10.0 g/2.9 g | 2.2 g | 35.3 g | 14 hours | |
| 31 | S′11 | S10/C1 | D2 | E2 | 120° C./ | F2 |
| | | 10.0 g/2.9 g | 2.2 g | 35.3 g | 14 hours | |
| 32 | S′12 | S11/C1 | D2 | E2 | 120° C./ | F2 |
| | | 10.0 g/2.9 g | 2.2 g | 35.3 g | 14 hours | |
| 33 | S′13 | S12/C1 | D2 | E2 | 120° C./ | F2 |
| | | 10.0 g/2.9 g | 2.2 g | 35.3 g | 14 hours | |
| 34 | S′14 | S13/C2 | D2 | E2 | 120° C./ | F2 |
| | | 10.0 g/2.9 g | 2.2 g | 35.3 g | 14 hours | |
| 35 | S′15 | S14/C1 | D2 | E2 | 120° C./ | F2 |
| | | 10.0 g/2.9 g | 2.2 g | 35.3 g | 14 hours | |
| 36 | S′16 | S15/C2 | D2 | E2 | 120° C./ | F2 |
| | | 10.0 g/2.9 g | 2.2 g | 35.3 g | 14 hours | |
| 37 | S′17 | S16/C2 | D2 | E2 | 120° C./ | F2 |
| | | 10.0 g/2.9 g | 2.2 g | 35.3 g | 14 hours | |
| 38 | S′18 | S17/C2 | D2 | E2 | 120° C./ | F2 |
| | | 10.0 g/2.9 g | 2.2 g | 35.3 g | 14 hours | |
| 39 | S′19 | S18/C2 | D2 | E2 | 120° C./ | F2 |
| | | 10.0 g/2.9 g | 2.2 g | 35.3 g | 14 hours | |
| 40 | S′20 | S19/C2 | D2 | E2 | 90° C./ | F2 |
| | | 10.0 g/2.9 g | 2.2 g | 35.3 g | 14 hours | |
| 41 | S′21 | S3/C3 | D2 | E2 | 120° C./ | F2 |
| | | 10.0 g/5.1 g | 4.3 g | 45.2 g | 16 hours | |
| 42 | S′22 | S4/C3 | D2 | E2 | 100° C./ | F2 |
| | | 10.0 g/5.1 g | 4.3 g | 45.2 g | 14 hours | |
| 43 | S′23 | S5/C3 | D2 | E2 | Reflux/ | F2 |
| | | 10.0 g/5.1 g | 4.3 g | 45.2 g | 14 hours | |
| 44 | S′24 | S4/C4 | D2 | E2 | 120° C./ | F2 |
| | | 10.0 g/3.7 g | 4.3 g | 42.1 g | 13 hours | |
| 45 | S′25 | S20/B 9 | D2 | E2 | Reflux/ | F2 |
| | | 10.0 g/3.8 g | 4.3 g | 42.3 g | 14 hours | |

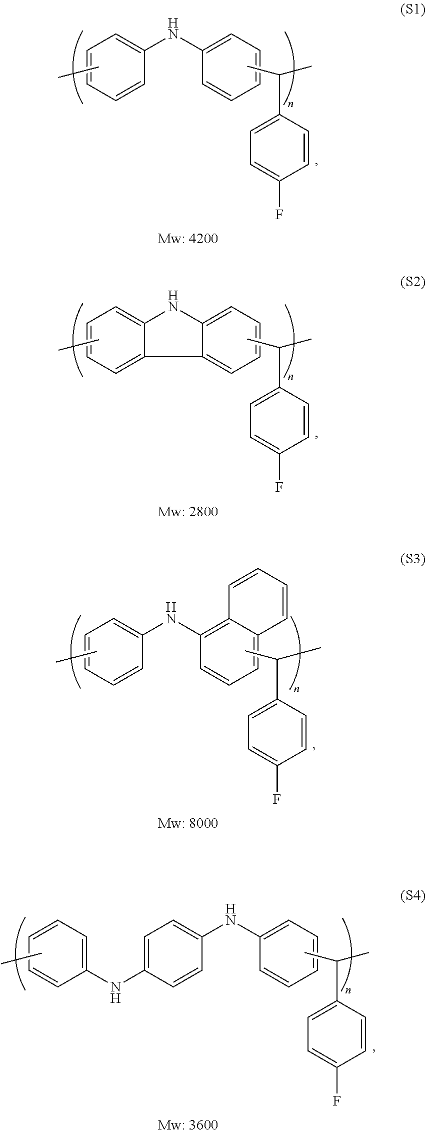

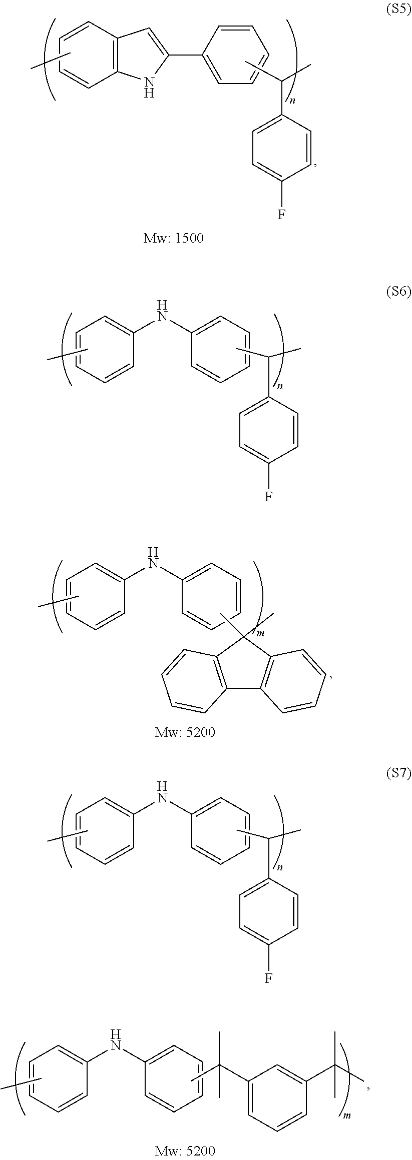

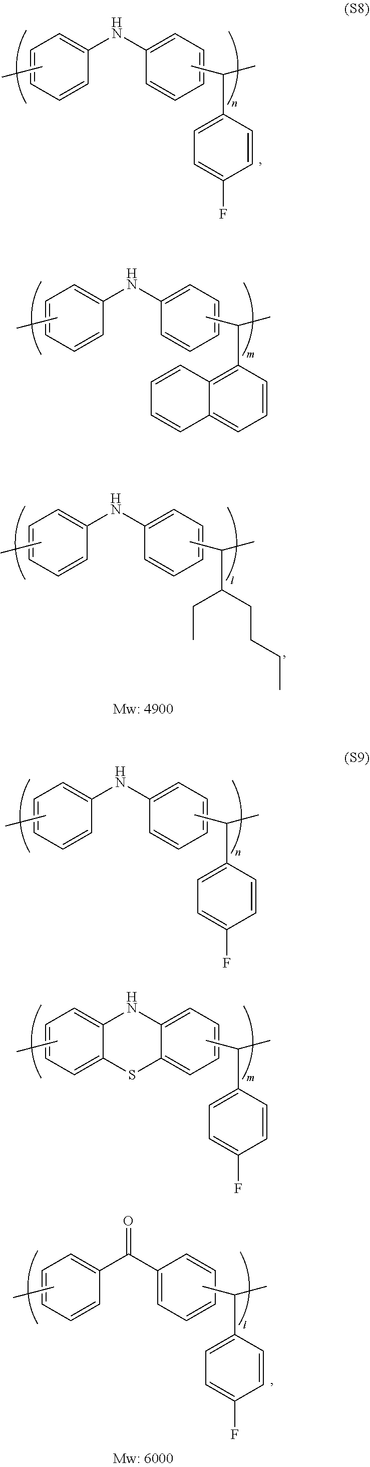

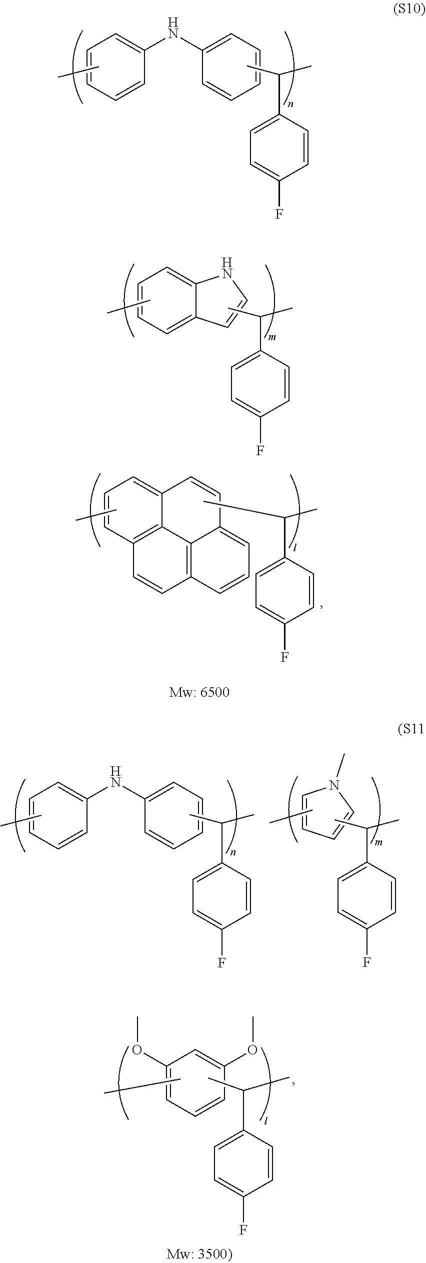

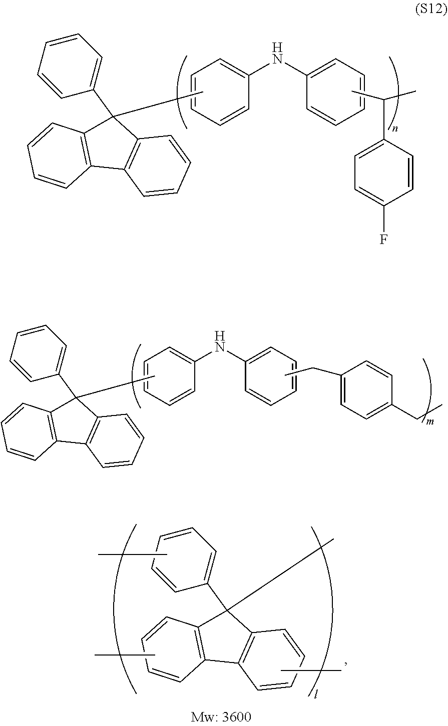

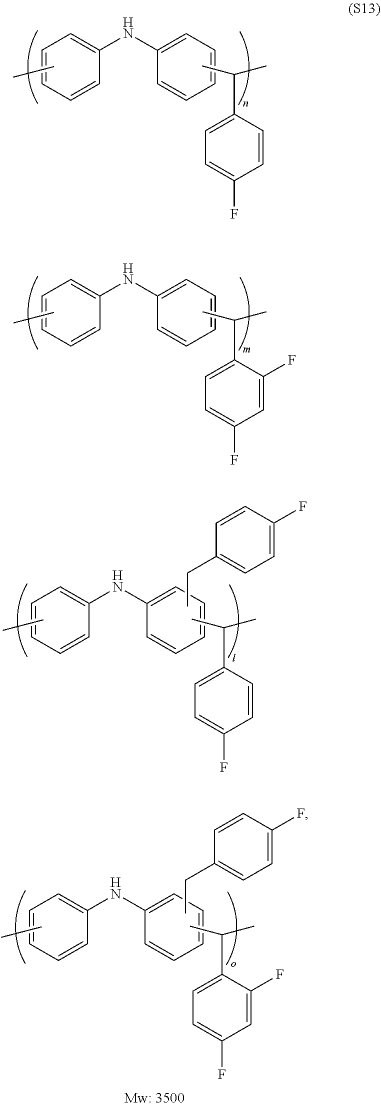

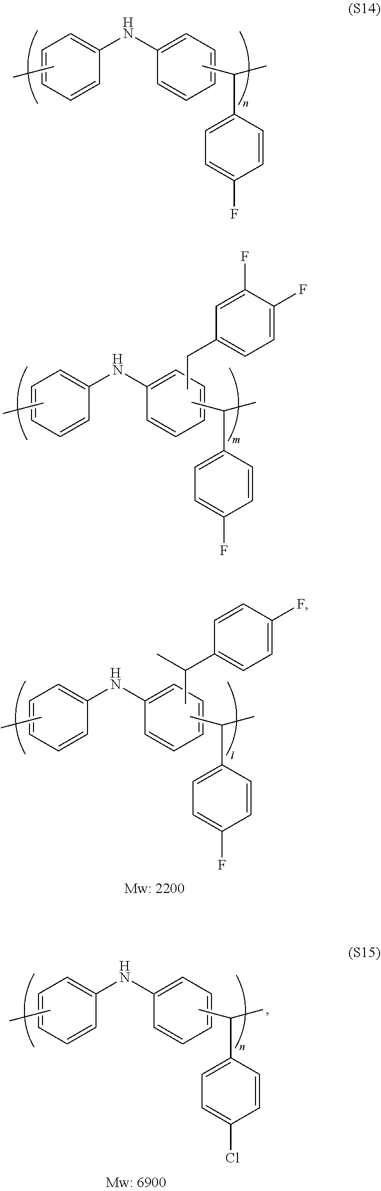

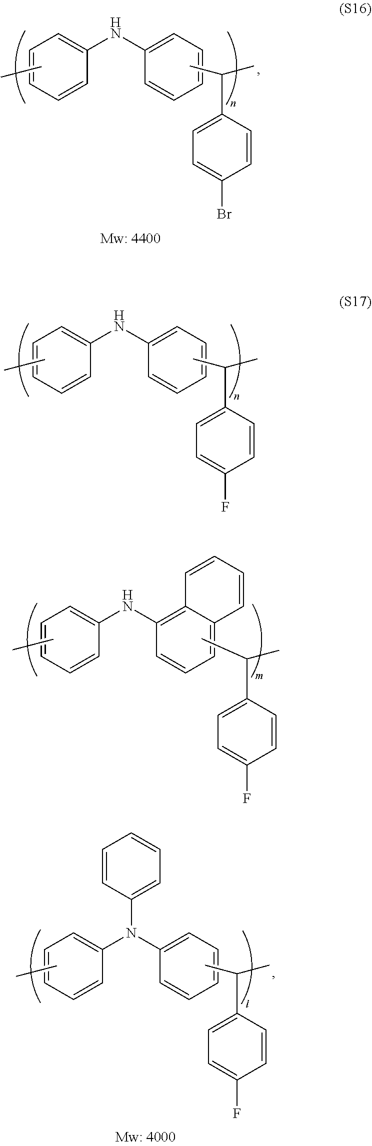

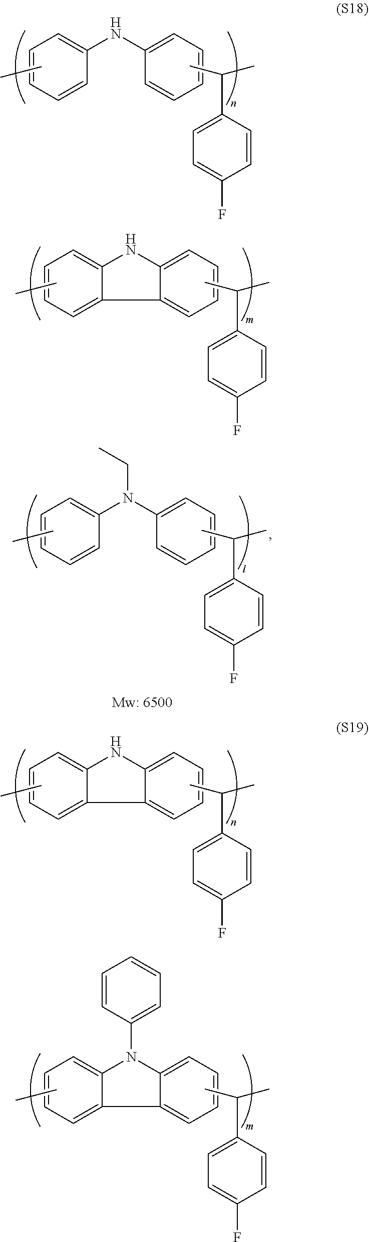

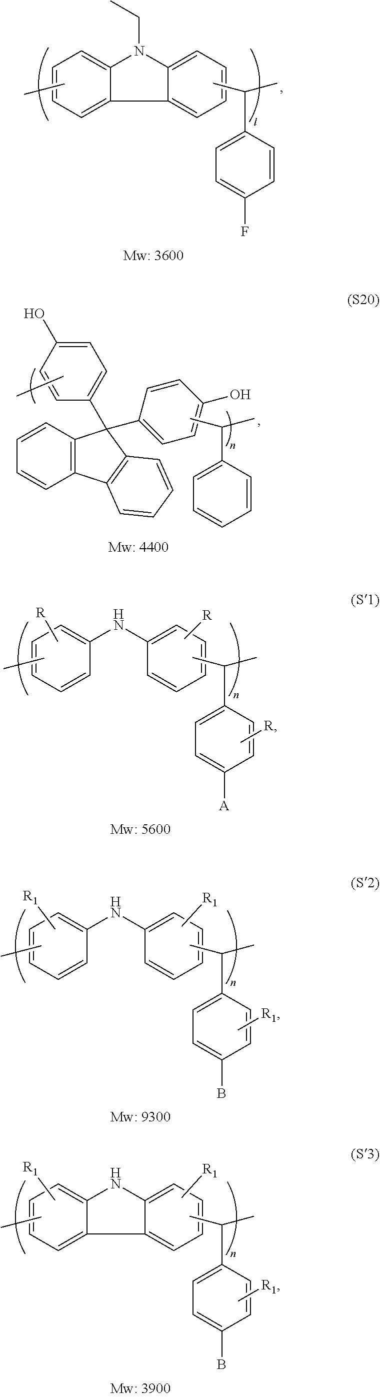

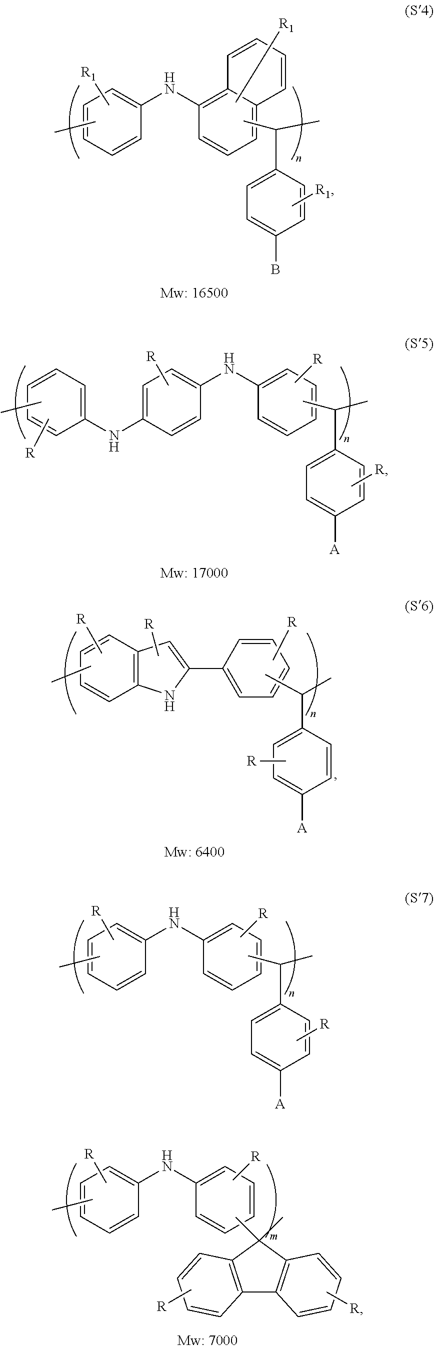

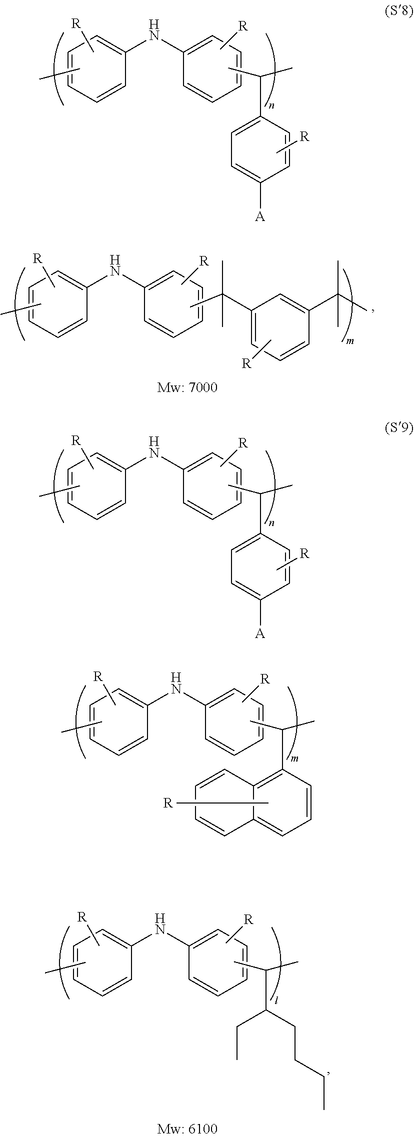

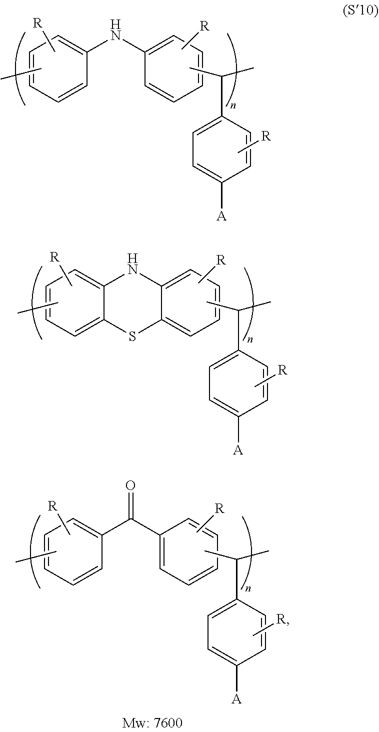

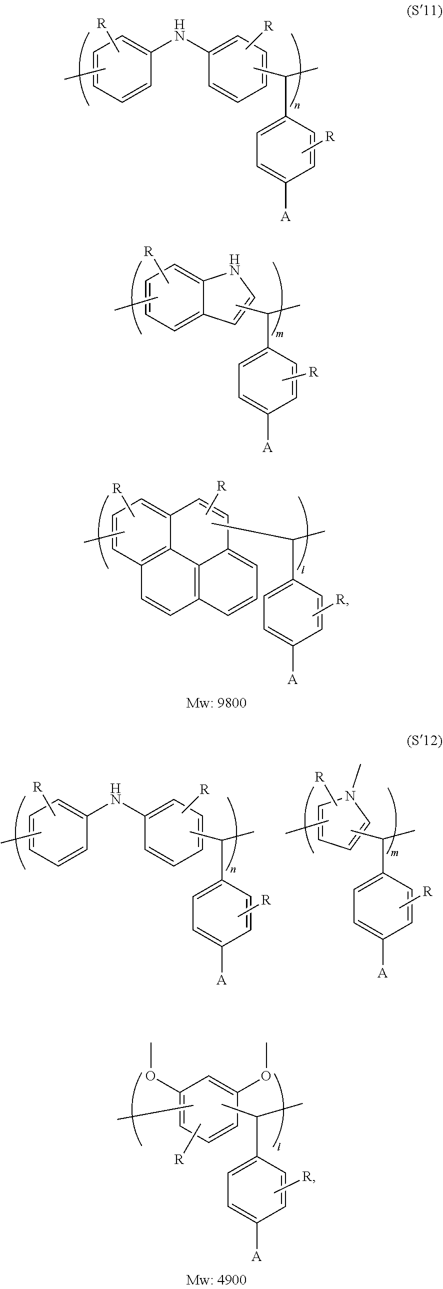

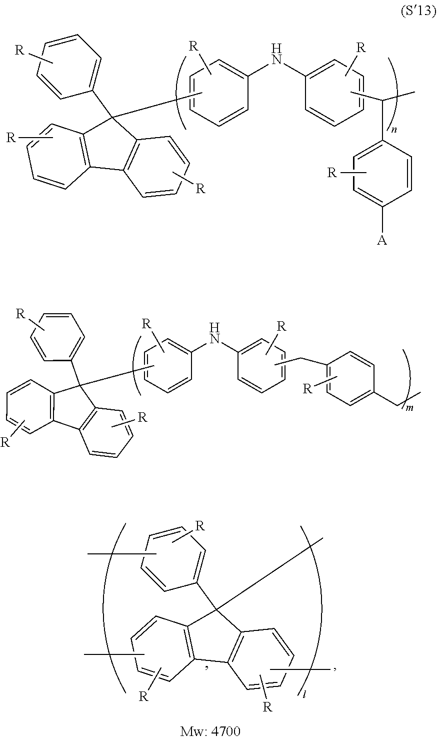

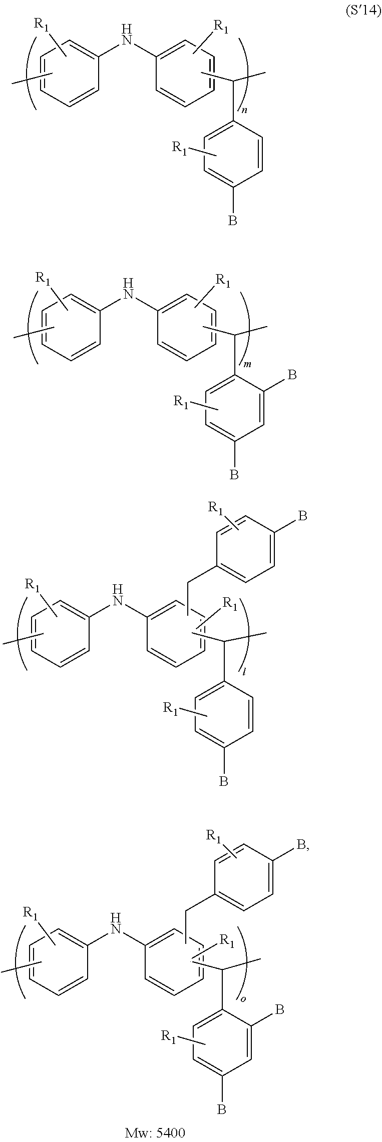

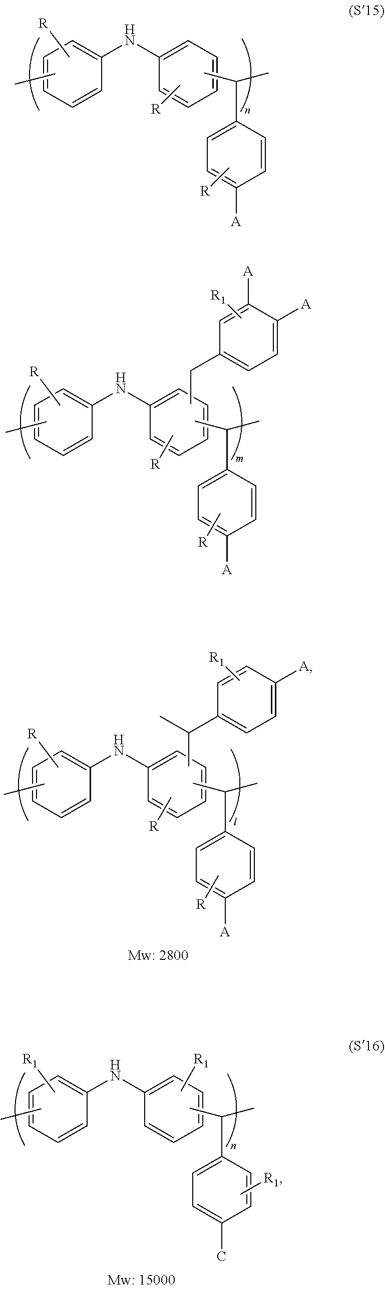

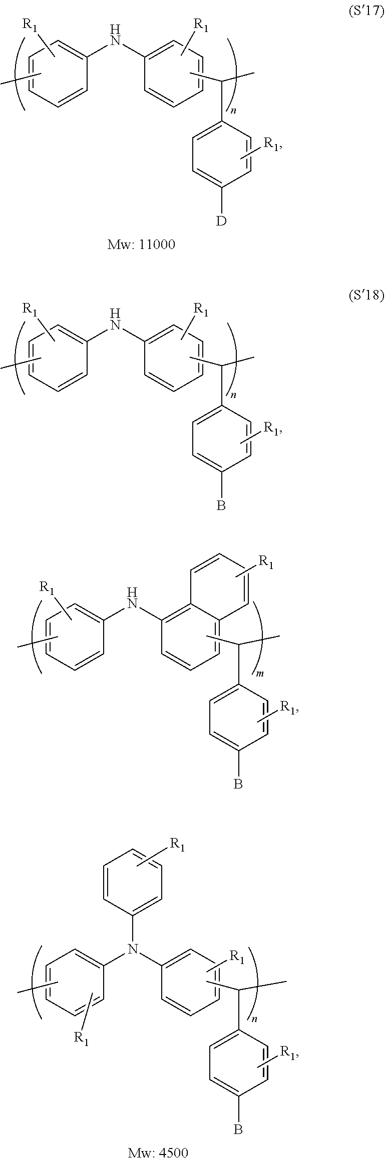

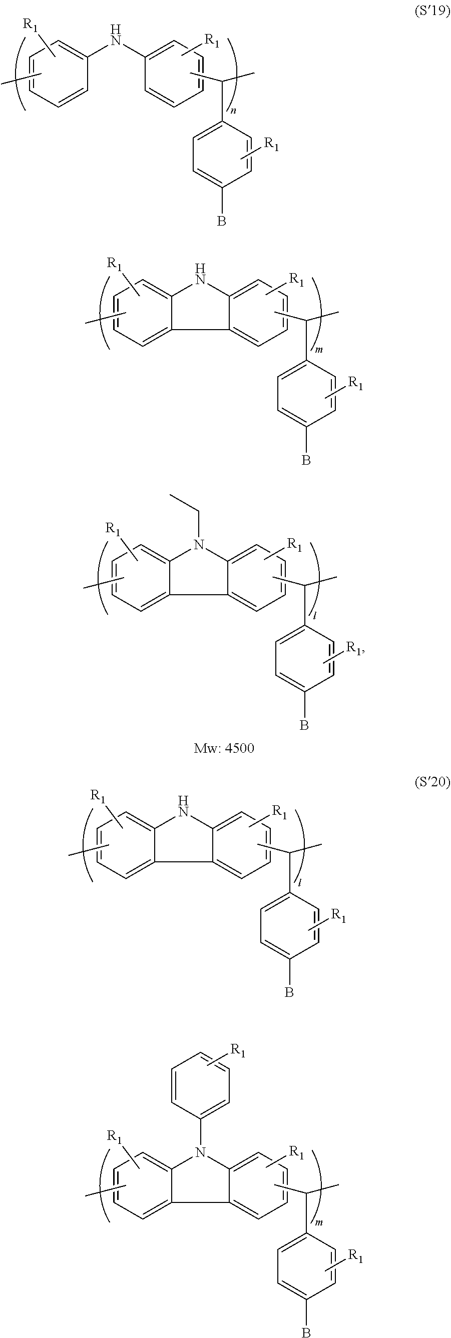

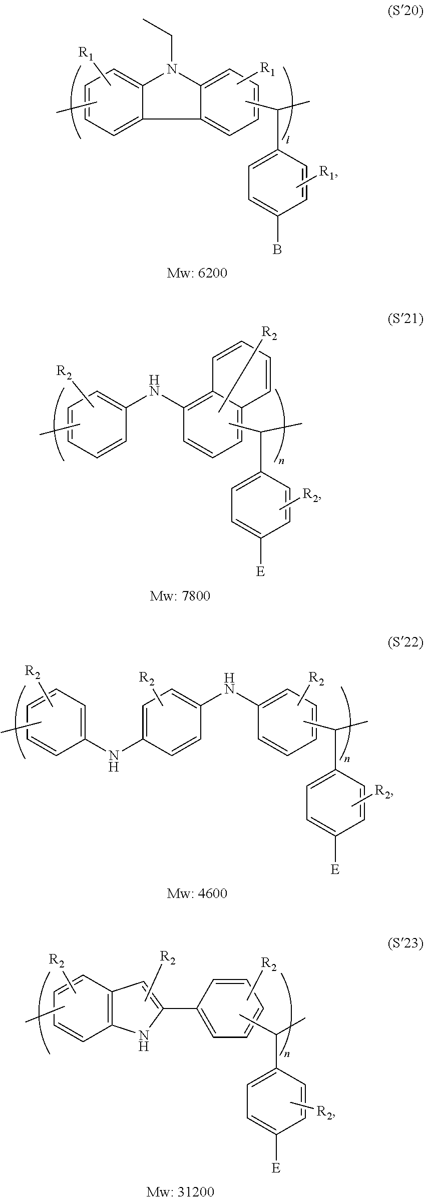

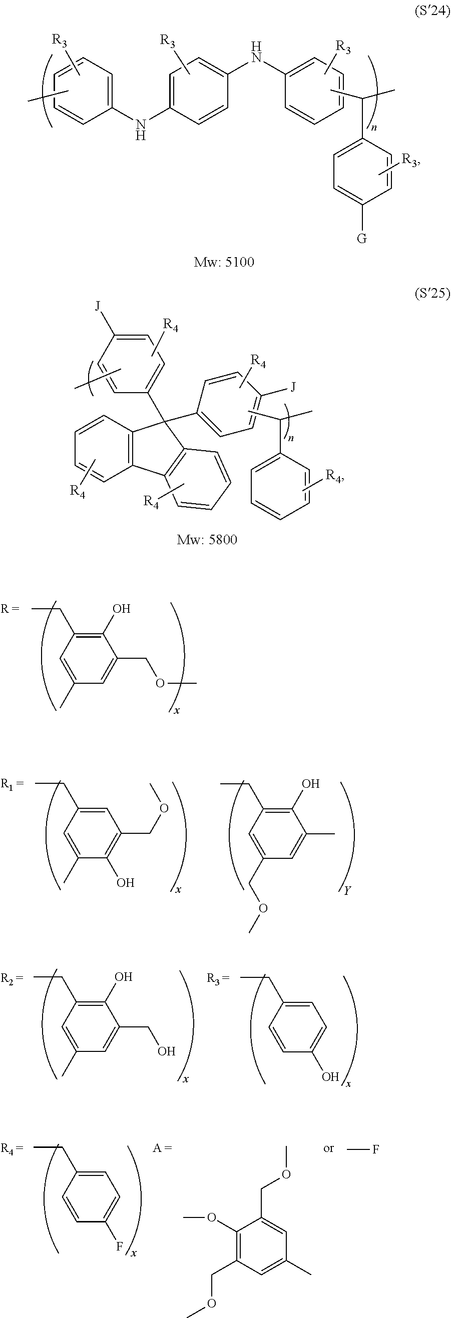

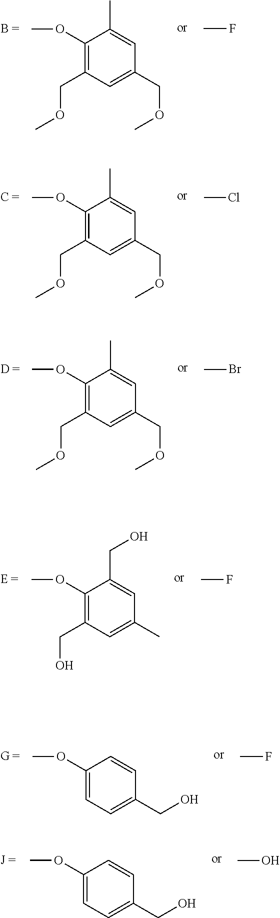

### Preparation of Resist Underlayer Films

The polymers (S1) to (S20) and (S′1) to (S′25), a crosslinking agent (CL1 to CL2), an acid generator (Ad1 to Ad2), a solvent (propylene glycol monomethyl ether acetate (PGMEA), propylene glycol monomethyl ether (PGMG), cyclohexanone (CYH)), and MEGAFACE R-40 (manufactured by DIC Corporation, PM) as a surfactant were mixed according to formulations shown below in a table, and resultants were filtered through a 0.1 m microfilter made of polytetrafluoroethylene to prepare resist underlayer film materials (M to M26, Comparative M to Comparative M21).

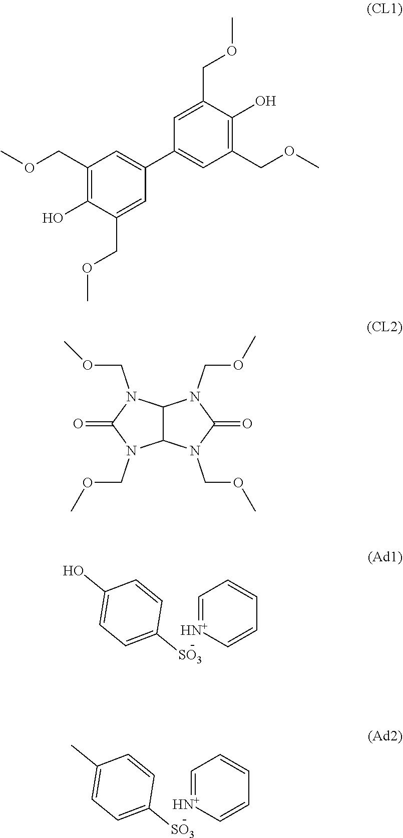

TABLE 2

| | | Crosslinking | Acid | | | | |
|---|---|---|---|---|---|---|---|
| Composition | Polymer | agent | generator | Surfactant | Solvent (Total 100) | | |
| Comparative | Synthesis | — | — | G1 | PGMEA | PGME | CYH |
| M1 | Example 1 | | | | | | |
| | 100 | — | — | 0.1 | 70 | 30 | 0 |
| Comparative | Synthesis | — | — | G1 | PGMEA | PGME | CYH |
| M2 | Example 2 | | | | | | |
| | 100 | — | — | 0.1 | 70 | 30 | 0 |
| Comparative | Synthesis | — | — | G1 | PGMEA | PGME | CYH |
| M3 | Example 3 | | | | | | |
| | 100 | — | — | 0.1 | 70 | 30 | 0 |
| Comparative | Synthesis | — | — | G1 | PGMEA | PGME | CYH |
| M4 | Example 4 | | | | | | |
| | 100 | — | — | 0.1 | 70 | 30 | 0 |
| Comparative | Synthesis | — | — | G1 | PGMEA | PGME | CYH |
| M5 | Example 5 | | | | | | |
| | 100 | — | — | 0.1 | 70 | 30 | 0 |
| Comparative | Synthesis | — | — | G1 | PGMEA | PGME | CYH |
| M6 | Example 6 | | | | | | |
| | 100 | — | — | 0.1 | 70 | 30 | 0 |
| Comparative | Synthesis | — | — | G1 | PGMEA | PGME | CYH |
| M7 | Example 7 | | | | | | |
| | 100 | — | — | 0.1 | 70 | 30 | 0 |
| Comparative | Synthesis | — | — | G1 | PGMEA | PGME | CYH |
| M8 | Example 8 | | | | | | |
| | 100 | — | — | 0.1 | 70 | 30 | 0 |
| Comparative | Synthesis | — | — | G1 | PGMEA | PGME | CYH |
| M9 | Example 9 | | | | | | |
| | 100 | — | — | 0.1 | 70 | 30 | 0 |
| Comparative | Synthesis | — | — | G1 | PGMEA | PGME | CYH |
| M10 | Example 10 | | | | | | |
| | 100 | — | — | 0.1 | 70 | 30 | 0 |
| Comparative | Synthesis | — | — | G1 | PGMEA | PGME | CYH |
| M11 | Example 11 | | | | | | |
| | 100 | — | — | 0.1 | 70 | 30 | 0 |
| Comparative | Synthesis | — | — | G1 | PGMEA | PGME | CYH |
| M12 | Example 12 | | | | | | |
| | 100 | — | — | 0.1 | 70 | 30 | 0 |
| Comparative | Synthesis | — | — | G1 | PGMEA | PGME | CYH |
| M13 | Example 13 | | | | | | |
| | 100 | — | — | 0.1 | 70 | 30 | 0 |
| Comparative | Synthesis | — | — | G1 | PGMEA | PGME | CYH |
| M14 | Example 14 | | | | | | |
| | 100 | — | — | 0.1 | 70 | 30 | 0 |
| Comparative | Synthesis | — | — | G1 | PGMEA | PGME | CYH |
| M15 | Example 15 | | | | | | |
| | 100 | — | — | 0.1 | 70 | 30 | 0 |
| Comparative | Synthesis | — | — | G1 | PGMEA | PGME | CYH |
| M16 | Example 16 | | | | | | |
| | 100 | — | — | 0.1 | 70 | 30 | 0 |
| Comparative | Synthesis | — | — | G1 | PGMEA | PGME | CYH |
| M17 | Example 17 | | | | | | |
| | 100 | — | — | 0.1 | 70 | 30 | 0 |
| Comparative | Synthesis | — | — | G1 | PGMEA | PGME | CYH |
| M18 | Example 18 | | | | | | |
| | 100 | — | — | 0.1 | 70 | 30 | 0 |
| Comparative | Synthesis | — | — | G1 | PGMEA | PGME | CYH |
| M19 | Example 19 | | | | | | |
| | 100 | — | — | 0.1 | 70 | 30 | 0 |
| Comparative | Synthesis | — | — | G1 | PGMEA | PGME | CYH |
| M20 | Example 20 | | | | | | |
| | 100 | — | — | 0.1 | 70 | 30 | 0 |
| Comparative | Synthesis | CL2 | Ad2 | G1 | PGMEA | PGME | CYH |
| M21 | Example 4 | | | | | | |
| | 100 | 30 | 3.0 | 0.1 | 70 | 30 | 0 |
| M1 | Synthesis | — | — | G1 | PGMEA | PGME | CYH |
| | Example 21 | | | | | | |
| | 100 | — | — | 0.1 | 70 | 30 | 0 |
| M2 | Synthesis | — | — | G1 | PGMEA | PGME | CYH |
| | Example 22 | | | | | | |
| | 100 | — | — | 0.1 | 70 | 30 | 0 |
| M3 | Synthesis | — | — | G1 | PGMEA | PGME | CYH |
| | Example 23 | | | | | | |
| | 100 | — | — | 0.1 | 70 | 30 | 0 |
| M4 | Synthesis | — | — | G1 | PGMEA | PGME | CYH |
| | Example 24 | | | | | | |
| | 100 | — | — | 0.1 | 70 | 30 | 0 |
| M5 | Synthesis | — | — | G1 | PGMEA | PGME | CYH |
| | Example 25 | | | | | | |
| | 100 | — | — | 0.1 | 70 | 30 | 0 |
| M6 | Synthesis | — | — | G1 | PGMEA | PGME | CYH |
| | Example 26 | | | | | | |
| | 100 | — | — | 0.1 | 70 | 30 | 0 |
| M7 | Synthesis | — | — | G1 | PGMEA | PGME | CYH |
| | Example 27 | | | | | | |
| | 100 | — | — | 0.1 | 70 | 30 | 0 |
| M8 | Synthesis | — | — | G1 | PGMEA | PGME | CYH |
| | Example 28 | | | | | | |
| | 100 | — | — | 0.1 | 70 | 30 | 0 |
| M9 | Synthesis | — | — | G1 | PGMEA | PGME | CYH |
| | Example 29 | | | | | | |
| | 100 | — | — | 0.1 | 70 | 30 | 0 |
| M10 | Synthesis | — | — | G1 | PGMEA | PGME | CYH |
| | Example 30 | | | | | | |
| | 100 | — | — | 0.1 | 70 | 30 | 0 |
| M11 | Synthesis | — | — | G1 | PGMEA | PGME | CYH |
| | Example 31 | | | | | | |
| | 100 | — | — | 0.1 | 70 | 30 | 0 |
| M12 | Synthesis | — | — | G1 | PGMEA | PGME | CYH |
| | Example 32 | | | | | | |
| | 100 | — | — | 0.1 | 70 | 30 | 0 |
| M13 | Synthesis | — | — | G1 | PGMEA | PGME | CYH |
| | Example 33 | | | | | | |
| | 100 | — | — | 0.1 | 70 | 30 | 0 |
| M14 | Synthesis | — | — | G1 | PGMEA | PGME | CYH |
| | Example 34 | | | | | | |
| | 100 | — | — | 0.1 | 70 | 30 | 0 |
| M15 | Synthesis | — | — | G1 | PGMEA | PGME | CYH |
| | Example 35 | | | | | | |
| | 100 | — | — | 0.1 | 70 | 30 | 0 |
| M16 | Synthesis | — | — | G1 | PGMEA | PGME | CYH |
| | Example 36 | | | | | | |
| | 100 | — | — | 0.1 | 70 | 30 | 0 |
| M17 | Synthesis | — | — | G1 | PGMEA | PGME | CYH |
| | Example 37 | | | | | | |
| | 100 | — | — | 0.1 | 70 | 30 | 0 |
| M18 | Synthesis | — | — | G1 | PGMEA | PGME | CYH |
| | Example 38 | | | | | | |
| | 100 | — | — | 0.1 | 70 | 30 | 0 |
| M19 | Synthesis | — | — | G1 | PGMEA | PGME | CYH |
| | Example 39 | | | | | | |
| | 100 | — | — | 0.1 | 70 | 30 | 0 |
| M20 | Synthesis | — | — | G1 | PGMEA | PGME | CYH |
| | Example 40 | | | | | | |
| | 100 | — | — | 0.1 | 70 | 30 | 0 |
| M21 | Synthesis | — | — | G1 | PGMEA | PGME | CYH |
| | Example 41 | | | | | | |
| | 100 | — | — | 0.1 | 70 | 30 | 0 |
| M22 | Synthesis | — | — | G1 | PGMEA | PGME | CYH |
| | Example 42 | | | | | | |
| | 100 | — | — | 0.1 | 70 | 30 | 0 |
| M23 | Synthesis | — | — | G1 | PGMEA | PGME | CYH |
| | Example 43 | | | | | | |
| | 100 | — | — | 0.1 | 70 | 30 | 0 |
| M24 | Synthesis | — | — | G1 | PGMEA | PGME | CYH |
| | Example 44 | | | | | | |
| | 100 | — | — | 0.1 | 70 | 30 | 0 |
| M25 | Synthesis | — | — | G1 | PGMEA | PGME | CYH |
| | Example 45 | | | | | | |
| | 100 | — | — | 0.1 | 70 | 30 | 0 |
| M26 | Synthesis | CL1 | Ad1 | G1 | PGMEA | PGME | CYH |
| | Example 24 | | | | | | |
| | 100 | 30 | 3.0 | 0.1 | 70 | 20 | 10 |

[Test of Elution into Resist Solvent]

Each of the resist underlayer film materials of Comparative Examples 1 to 20 and Examples 1 to 26 was applied onto a silicon wafer using a spin coater and baked in an atmosphere of air at a predetermined temperature for a predetermined time to form a resist underlayer film having a film thickness of about 150 nm. The predetermined temperature and the predetermined time are shown in a table. The formed resist underlayer film was immersed in a versatile thinner, PGME/PGMIEA=7/3 for 60 seconds to determine solvent resistance. The solvent resistance was judged as O when the rate of film thickness reduction before and after immersion in thinner was 1% or less (Table 1). Further, each of the resist underlayer film materials was applied onto a silicon wafer using ACT-8 manufactured by Tokyo Electron Ltd. and baked in an atmosphere of nitrogen at a predetermined temperature for a predetermined time to form a 75 nm resist underlayer film. The predetermined temperature and the predetermined time are shown in the table. Similarly to the above, the resist underlayer film was immersed in PGME/PGMEA=7/3 for 60 seconds to determine solvent resistance. The solvent resistance was judged as ◯ when the rate of film thickness reduction before and after immersion in thinner was smaller than that of a comparative example (Table 1). A value within parentheses is the rate of film thickness reduction. It should be noted that the samples (Comparative Examples 1 to 20) formed by baking in an atmosphere of air in which baking is generally performed significantly elute into the resist solvent and therefore cannot be used as resist underlayer films. Therefore, they were excluded from comparative examples in evaluations described below. As an alternative comparative example, a general resist underlayer film containing a crosslinking agent and a curing catalyst (Comparative Example 21) was formed and used as a comparative example in evaluations described below.

TABLE 1

| | | | Solvent | | Solvent |
|---|---|---|---|---|---|
| | | | resistance | | resistance |
| Example/ | | | under | | under |
| Comparative | | Baking | atmosphere | Baking | atmosphere |
| Example | Composition | temperature | of air | temperature | of nitrogen |
| Example 1 | M1 | 300° C./60 seconds | ◯ | 300° C./60 seconds | ◯ |
| Example 2 | M2 | 300° C./60 seconds | ◯ | 300° C./60 seconds | ◯ |
| Example 3 | M3 | 300° C./60 seconds | ◯ | 300° C./60 seconds | ◯ |
| Example 4 | M4 | 300° C./60 seconds | ◯ | 300° C./60 seconds | ◯ |
| Example 5 | M5 | 300° C./60 seconds | ◯ | 300° C./60 seconds | ◯ |
| Example 6 | M6 | 300° C./60 seconds | ◯ | 300° C./60 seconds | ◯ |
| Example 7 | M7 | 300° C./60 seconds | ◯ | 300° C./60 seconds | ◯ |
| Example 8 | M8 | 300° C./60 seconds | ◯ | 300° C./60 seconds | ◯ |
| Example 9 | M9 | 300° C./60 seconds | ◯ | 300° C./60 seconds | ◯ |
| Example 10 | M10 | 300° C./60 seconds | ◯ | 300° C./60 seconds | ◯ |
| Example 11 | M11 | 300° C./60 seconds | ◯ | 300° C./60 seconds | ◯ |
| Example 12 | M12 | 300° C./60 seconds | ◯ | 300° C./60 seconds | ◯ |
| Example 13 | M13 | 300° C./60 seconds | ◯ | 300° C./60 seconds | ◯ |
| | | 400° C./60 seconds | ◯ | 400° C./60 seconds | ◯ |
| Example 14 | M14 | 300° C./60 seconds | ◯ | 300° C./60 seconds | ◯ |
| Example 15 | M15 | 300° C./60 seconds | ◯ | 300° C./60 seconds | ◯ |
| Example 16 | M16 | 300° C./60 seconds | ◯ | 300° C./60 seconds | ◯ |
| Example 17 | M17 | 300° C./60 seconds | ◯ | 300° C./60 seconds | ◯ |
| Example 18 | M18 | 300° C./60 seconds | ◯ | 300° C./60 seconds | ◯ |
| Example 19 | M19 | 300° C./60 seconds | ◯ | 300° C./60 seconds | ◯ |
| Example 20 | M20 | 300° C./60 seconds | ◯ | 300° C./60 seconds | ◯ |
| Example 21 | M21 | 300° C./60 seconds | ◯ | 300° C./60 seconds | ◯ |
| Example 22 | M22 | 300° C./60 seconds | ◯ | 300° C./60 seconds | ◯ |
| Example 23 | M23 | 300° C./60 seconds | ◯ | 300° C./60 seconds | ◯ |
| Example 24 | M24 | 300° C./60 seconds | ◯ | 400° C./60 seconds | ◯ |
| Example 25 | M25 | 300° C./60 seconds | ◯ | 400° C./60 seconds | ◯ |
| Example 26 | M26 | 300° C./60 seconds | ◯ | 300° C./60 seconds | ◯ |
| Comparative | Comparative | 300° C./60 seconds | X | 300° C./60 seconds | X(100%) |
| Example 1 | M1 | | | | |
| Comparative | Comparative | 300° C./60 seconds | X | 300° C./60 seconds | X(100%) |
| Example 2 | M2 | | | | |
| Comparative | Comparative | 300° C./60 seconds | X | 300° C./60 seconds | X(100%) |
| Example 3 | M3 | | | | |
| Comparative | Comparative | 300° C./60 seconds | X | 300° C./60 seconds | X(100%) |
| Example 4 | M4 | | | | |
| Comparative | Comparative | 300° C./60 seconds | X | 300° C./60 seconds | X(100%) |
| Example 5 | M5 | | | | |
| Comparative | Comparative | 300° C./60 seconds | X | 300° C./60 seconds | X(100%) |
| Example 6 | M6 | | | | |
| Comparative | Comparative | 300° C./60 seconds | X | 300° C./60 seconds | X(100%) |
| Example 7 | M7 | | | | |
| Comparative | Comparative | 300° C./60 seconds | X | 300° C./60 seconds | X(100%) |
| Example 8 | M8 | | | | |
| Comparative | Comparative | 300° C./60 seconds | X | 300° C./60 seconds | X(100%) |
| Example 9 | M9 | | | | |
| Comparative | Comparative | 300° C./60 seconds | X | 300° C./60 seconds | X(100%) |
| Example 10 | M10 | | | | |
| Comparative | Comparative | 300° C./60 seconds | X | 300° C./60 seconds | X(100%) |
| Example 11 | M11 | | | | |
| Comparative | Comparative | 300° C./60 seconds | X | 300° C./60 seconds | X(100%) |
| Example 12 | M12 | | | | |
| Comparative | Comparative | 300° C./60 seconds | X | 300° C./60 seconds | X(100%) |
| Example 13 | M13 | | | | |
| Comparative | Comparative | 300° C./60 seconds | X | 300° C./60 seconds | X(100%) |
| Example 14 | M14 | | | | |
| Comparative | Comparative | 300° C./60 seconds | X | 300° C./60 seconds | X(100%) |
| Example 15 | M15 | | | | |
| Comparative | Comparative | 300° C./60 seconds | X | 300° C./60 seconds | X(100%) |
| Example 16 | M16 | | | | |
| Comparative | Comparative | 300° C./60 seconds | X | 300° C./60 seconds | X(100%) |
| Example 17 | M17 | | | | |
| Comparative | Comparative | 300° C./60 seconds | X | 300° C./60 seconds | X(100%) |
| Example 18 | M18 | | | | |
| Comparative | Comparative | 300° C./60 seconds | X | 300° C./60 seconds | X(100%) |
| Example 19 | M19 | | | | |
| Comparative | Comparative | 300° C./60 seconds | X | 300° C./60 seconds | X(100%) |
| Example 20 | M20 | | | | |

### [Measurement of Etching Rate]

Each of the resist underlayer film materials of Comparative Example 21 and Examples 1 to 26 was applied onto a silicon wafer using a spin coater and baked on a hot plate at a predetermined temperature for a predetermined time to form a 75 nm resist underlayer film. The predetermined temperature and the predetermined time are shown in a table. A dry etching rate was measured using O₂/N₂ gas or CF₄ gas as an etching gas (Table 2). A value within parentheses is a dry etching rate ratio of (resist underlayer film)/(phenol novolac resin film). When the etching rate was lower than that of the comparative example, etching resistance was judged as 0, and when the etching rate was higher than that of the comparative example, etching resistance was judged as X.

An etcher and etching gases used for measuring an etching rate are as shown below.
RIE-200NL (manufactured by Samco Inc): CF₄ 50 sccm
RIE-200NL (manufactured by Samco Inc.): O₂/N₂ 10 sccm/200 sccm

### [Measurement of Optical Constant]

Each of the resist underlayer film-forming composition solutions prepared in Comparative Examples 21 and Examples 1 to 26 was applied onto a silicon wafer using a spin coater and baked on a hot plate at a predetermined temperature for a predetermined time to form a 50 nm resist underlayer film. The predetermined temperature and the predetermined time are shown in a table. The refractive index (n value) and optical absorption coefficient (k value, also referred to as extinction coefficient) of the resist underlayer film were measured at a wavelength of 193 nm using a spectroscopic ellipsometer (Table 2).

### [Evaluation of Applicability]

Each of the resist underlayer film materials of Comparative Example 21 and Examples 1 to 26 was applied onto a silicon wafer using ACT-8 manufactured by Tokyo Electron Ltd. and baked in an atmosphere of air at a predetermined temperature for a predetermined time to form a 75 nm resist underlayer film. The predetermined temperature and the predetermined time are shown in a table. Then, the film surface (wafer center and edge) was observed using an optical microscope to determine whether or not there was a problem with applicability. The “problem” herein means a case where cissing or pinhole formation is observed on the film surface or a case where the film has surface irregularities that are not usually observed (Table 2). The applicability was judged as O when there was not a problem with applicability.

TABLE 2

| Example/ | | | | | | | |
|---|---|---|---|---|---|---|---|
| Comparative | | Baking | Etching resistance | | Optical constant | Applicability | |
| Example | Composition | temperature | CF4 | O2/N2 | n/k @ 193 nm | Center | Edge |
| Example 1 | M1 | 300° C./60 seconds | ∘ | ∘ | 1.56/0.72 | ∘ | ∘ |
| Example 2 | M2 | 300° C./60 seconds | ∘ | ∘ | 1.56/0.70 | ∘ | ∘ |
| Example 3 | M3 | 300° C./60 seconds | ∘ | ∘ | 1.55/0.61 | ∘ | ∘ |
| Example 4 | M4 | 300° C./60 seconds | ∘ | ∘ | 1.50/0.60 | ∘ | ∘ |
| Example 5 | M5 | 300° C./60 seconds | ∘ | ∘ | 1.55/0.65 | ∘ | ∘ |
| Example 6 | M6 | 300° C./60 seconds | ∘ | ∘ | 1.62/0.72 | ∘ | ∘ |
| Example 7 | M7 | 300° C./60 seconds | ∘ | ∘ | 1.57/0.72 | ∘ | ∘ |
| Example 8 | M8 | 300° C./60 seconds | ∘ | ∘ | 1.57/0.72 | ∘ | ∘ |
| Example 9 | M9 | 300° C./60 seconds | ∘ | ∘ | 1.55/0.70 | ∘ | ∘ |
| Example 10 | M10 | 300° C./60 seconds | ∘ | ∘ | 1.57/0.71 | ∘ | ∘ |
| Example 11 | M11 | 300° C./60 seconds | ∘ | ∘ | 1.57/0.71 | ∘ | ∘ |
| Example 12 | M12 | 300° C./60 seconds | ∘ | ∘ | 1.59/0.70 | ∘ | ∘ |
| Example 13 | M13 | 300° C./60 seconds | ∘ | ∘ | 1.55/0.73 | ∘ | ∘ |
| | | 400° C./60 seconds | | | 1.49/0.63 | ∘ | ∘ |
| Example 14 | M14 | 300° C./60 seconds | ∘ | ∘ | 1.55/0.72 | ∘ | ∘ |
| Example 15 | M15 | 300° C./60 seconds | ∘ | ∘ | 1.55/0.72 | ∘ | ∘ |
| Example 16 | M16 | 300° C./60 seconds | ∘ | ∘ | 1.48/0.69 | ∘ | ∘ |
| Example 17 | M17 | 300° C./60 seconds | ∘ | ∘ | 1.47/0.73 | ∘ | ∘ |
| Example 18 | M18 | 300° C./60 seconds | ∘ | ∘ | 1.54/0.70 | ∘ | ∘ |
| Example 19 | M19 | 300° C./60 seconds | ∘ | ∘ | 1.54/0.70 | ∘ | ∘ |
| Example 20 | M20 | 300° C./60 seconds | ∘ | ∘ | 1.55/0.73 | ∘ | ∘ |
| Example 21 | M21 | 300° C./60 seconds | ∘ | ∘ | 1.51/0.61 | ∘ | ∘ |
| Example 22 | M22 | 300° C./60 seconds | ∘ | ∘ | 1.56/0.66 | ∘ | ∘ |
| Example 23 | M23 | 300° C./60 seconds | ∘ | ∘ | 1.59/0.69 | ∘ | ∘ |
| Example 24 | M24 | 300° C./60 seconds | ∘ | ∘ | 1.57/0.67 | ∘ | ∘ |
| Example 25 | M25 | 300° C./60 seconds | ∘ | ∘ | 1.47/0.71 | ∘ | ∘ |
| Example 26 | M26 | 300° C./60 seconds | ∘ | ∘ | 1.48/0.62 | ∘ | ∘ |
| Comparative | Comparative | 300° C./60 seconds | x | x | 1.56/0.68 | ∘ | ∘ |
| Example 21 | M21 | | (1.07) | (1.00) | | | |

[Test of Applicability/Coatability onto/on Stepped Substrate]

The test of applicability/coatability onto/on a stepped substrate was performed using 200 nm-thick SiO₂, SiN, and TiN substrates. Each of the resist underlayer film-forming compositions prepared in Comparative Example 21 and Examples 1 to 26 was applied onto the substrate and baked at a predetermined temperature for a predetermined time to form a resist underlayer film having a film thickness of about 150 nm. The predetermined temperature and the predetermined time are shown in a table. In the case of a stepped substrate, applicability of the resist underlayer film may vary or deteriorate depending on the type of substrate to be used. Therefore, whether or not the resist underlayer film-forming composition could evenly be applied onto stepped substrates different in vapor-deposited film formed thereon was visually observed. When the resist underlayer film-forming composition could evenly be applied, the applicability was judged as O.

Further, comparison of the thickness of a coating film was performed between a dense area and an area having no pattern (open area) using the same device. Flattenability was evaluated by measuring the difference in film thickness between the trench area (patterned area) and the open area (pattern-free area) (which is a coating level difference between the trench area and the open area and referred to as a bias) of a stepped substrate. The flattenability herein means that the difference in the film thickness of a coating material (Iso-dense bias) is small between an area having a pattern (trench area (patterned area)) on which the coating material is applied and an area having no pattern (open area (pattern-free area) on which the coating material is applied. The flattenability was judged as O when the bias was improved as compared to that of the comparative example (Table 3).

TABLE 3

| Example/ | | | | | | |
|---|---|---|---|---|---|---|
| Comparative | | Film | | Type of | | |
| Example | Composition | thickness | Baking temperature | substrate | Applicability | Flattenability |
| Example 1 | M1 | 150 nm | 300° C./60 seconds | SiO2 | ◯ | ◯ |
| Example 2 | M2 | 150 nm | 300° C./60 seconds | SiO2 | ◯ | ◯ |
| Example 3 | M3 | 150 nm | 300° C./60 seconds | SiO2 | ◯ | ◯ |
| Example 4 | M4 | 150 nm | 300° C./60 seconds | SiO2 | ◯ | ◯ |
| | | 150 nm | 300° C./60 seconds | TiN | ◯ | ◯ |
| | | 150 nm | 300° C./60 seconds | SiN | ◯ | ◯ |
| Example 5 | M5 | 150 nm | 300° C./60 seconds | SiO2 | ◯ | ◯ |
| Example 6 | M6 | 150 nm | 300° C./60 seconds | SiO2 | ◯ | ◯ |
| | | 150 nm | 300° C./60 seconds | TiN | ◯ | ◯ |
| | | 150 nm | 300° C./60 seconds | SiN | ◯ | ◯ |
| Example 7 | M7 | 150 nm | 300° C./60 seconds | SiO2 | ◯ | ◯ |
| Example 8 | M8 | 150 nm | 300° C./60 seconds | SiO2 | ◯ | ◯ |
| Example 9 | M9 | 150 nm | 300° C./60 seconds | SiO2 | ◯ | ◯ |
| Example 10 | M10 | 150 nm | 300° C./60 seconds | SiO2 | ◯ | ◯ |
| Example 11 | M11 | 150 nm | 300° C./60 seconds | SiO2 | ◯ | ◯ |
| Example 12 | M12 | 150 nm | 300° C./60 seconds | SiO2 | ◯ | ◯ |
| Example 13 | M13 | 150 nm | 300° C./60 seconds | SiO2 | ◯ | ◯ |
| | | 150 nm | 300° C./60 seconds | TiN | ◯ | ◯ |
| | | 150 nm | 300° C./60 seconds | SiN | ◯ | ◯ |
| | | 150 nm | 400° C./60 seconds | SiO2 | ◯ | ◯ |
| Example 14 | M14 | 150 nm | 300° C./60 seconds | SiO2 | ◯ | ◯ |
| Example 15 | M15 | 150 nm | 300° C./60 seconds | SiO2 | ◯ | ◯ |
| Example 16 | M16 | 150 nm | 300° C./60 seconds | SiO2 | ◯ | ◯ |
| Example 17 | M17 | 150 nm | 300° C./60 seconds | SiO2 | ◯ | ◯ |
| Example 18 | M18 | 150 nm | 300° C./60 seconds | SiO2 | ◯ | ◯ |
| | | 150 nm | 300° C./60 seconds | TiN | ◯ | ◯ |
| | | 150 nm | 300° C./60 seconds | SiN | ◯ | ◯ |
| Example 19 | M19 | 150 nm | 300° C./60 seconds | SiO2 | ◯ | ◯ |
| Example 20 | M20 | 150 nm | 300° C./60 seconds | SiO2 | ◯ | ◯ |
| Example 21 | M21 | 150 nm | 300° C./60 seconds | SiO2 | ◯ | ◯ |
| Example 22 | M22 | 150 nm | 300° C./60 seconds | SiO2 | ◯ | ◯ |
| Example 23 | M23 | 150 nm | 300° C./60 seconds | SiO2 | ◯ | ◯ |
| Example 24 | M24 | 150 nm | 300° C./60 seconds | SiO2 | ◯ | ◯ |
| Example 25 | M25 | 150 nm | 300° C./60 seconds | SiO2 | ◯ | ◯ |
| Example 26 | M26 | 150 nm | 300° C./60 seconds | SiO2 | ◯ | ◯ |
| Comparative | Comparative | 150 nm | 300° C./60 seconds | SiO2 | ◯ | ◯ |
| Example 21 | M21 | | | | | |

[Test of Embeddability into Stepped Substrate]

The test of applicability/coatability onto/on a stepped substrate was performed using 200 nm-thick SiO₂, SiN, and TiN substrates. Each of the resist underlayer film-forming compositions prepared in Comparative Example 21 and Examples shown below was applied onto the substrate and baked at a predetermined temperature for a predetermined time to form a resist underlayer film having a film thickness of about 150 nm. The predetermined temperature and the predetermined time are shown in a table.

Evaluation of embeddability was performed on a trench area (dense pattern area) present in the substrate, in which a trench width was 50 nm and a pitch was 100 nm, using a scanning electron microscope (S-4800) manufactured by Hitachi High-Technologies Corporation. The embeddability was judged as 0 when the trenches were filled with the resist underlayer film that reached the bottom of the trenches (Table 4).

TABLE 4

| Example/ | | | | | |
|---|---|---|---|---|---|
| Comparative | | Film | Baking | Type of | |
| Example | Composition | thickness | temperature | substrate | Embeddability |
| Example 1 | M1 | 150 nm | 300° C./60 seconds | SiO2 | ◯ |
| Example 2 | M2 | 150 nm | 300° C./60 seconds | SiO2 | ◯ |
| Example 3 | M3 | 150 nm | 300° C./60 seconds | SiO2 | ◯ |
| Example 4 | M4 | 150 nm | 300° C./60 seconds | SiO2 | ◯ |
| | | 150 nm | 300° C./60 seconds | TiN | ◯ |
| | | 150 nm | 300° C./60 seconds | SiN | ◯ |
| Example 5 | M5 | 150 nm | 300° C./60 seconds | SiO2 | ◯ |
| Example 7 | M7 | 150 nm | 300° C./60 seconds | SiO2 | ◯ |
| Example 8 | M8 | 150 nm | 300° C./60 seconds | SiO2 | ◯ |
| Example 9 | M9 | 150 nm | 300° C./60 seconds | SiO2 | ◯ |
| Example 10 | M10 | 150 nm | 300° C./60 seconds | SiO2 | ◯ |
| Example 11 | M11 | 150 nm | 300° C./60 seconds | SiO2 | ◯ |
| Example 12 | M12 | 150 nm | 300° C./60 seconds | SiO2 | ◯ |
| Example 13 | M13 | 150 nm | 300° C./60 seconds | SiO2 | ◯ |
| | | 150 nm | 300° C./60 seconds | TiN | ◯ |
| | | 150 nm | 300° C./60 seconds | SiN | ◯ |
| | | 150 nm | 400° C./60 seconds | SiO2 | ◯ |
| Example 14 | M14 | 150 nm | 300° C./60 seconds | SiO2 | ◯ |
| Example 15 | M15 | 150 nm | 300° C./60 seconds | SiO2 | ◯ |
| Example 16 | M16 | 150 nm | 300° C./60 seconds | SiO2 | ◯ |
| Example 17 | M17 | 150 nm | 300° C./60 seconds | SiO2 | ◯ |
| Example 18 | M18 | 150 nm | 300° C./60 seconds | SiO2 | ◯ |
| | | 150 nm | 300° C./60 seconds | TiN | ◯ |
| | | 150 nm | 300° C./60 seconds | SiN | ◯ |
| Example 19 | M19 | 150 nm | 300° C./60 seconds | SiO2 | ◯ |
| Example 20 | M20 | 150 nm | 300° C./60 seconds | SiO2 | ◯ |
| Example 21 | M21 | 150 nm | 300° C./60 seconds | SiO2 | ◯ |
| Example 22 | M22 | 150 nm | 300° C./60 seconds | SiO2 | ◯ |
| Example 24 | M24 | 150 nm | 300° C./60 seconds | SiO2 | ◯ |
| Example 25 | M25 | 150 nm | 300° C./60 seconds | SiO2 | ◯ |
| Example 26 | M26 | 150 nm | 300° C./60 seconds | SiO2 | ◯ |
| Comparative | Comparative | 150 nm | 300° C./60 seconds | SiO2 | ◯ |
| Example 21 | M21 | | | | |

As has been described above, unlike the conventional materials, the materials of Examples have curability both in an atmosphere of air and in an atmosphere of nitrogen without containing a crosslinking agent and a curing catalyst, and therefore can be judged as having self-crosslinkability. Needless to say, similarly to the conventional materials, the materials of Examples may contain a crosslinking agent and a curing catalyst. These materials have high heat resistance and therefore exhibit excellent applicability onto a silicon wafer even during a high-temperature baking. Further, the optical constant of each of the materials of Examples can freely be changed by changing the skeleton of the polymer to suppress reflection during exposure, which makes it possible to form an excellent resist pattern. In addition, the materials of Examples are superior in etching resistance to a major etching gas such as a fluorine- or oxygen-based gas to the material of the comparative example. Further, the materials of Examples exhibit excellent applicability even onto various vapor-deposited substrates having a stepped surface and also have excellent embeddability/flattenability into/on a substrate having a finely stepped surface. Therefore, the materials of Examples are expected to be widely usable in semiconductor production processes that have become diverse.

1. A resist underlayer film-forming composition characterized by comprising a novolac resin containing a side chain having a structure of the following Formula (D) and a solvent:
—O—Ar² Formula (D)
(wherein Ar² is an aromatic ring).

2. The resist underlayer film-forming composition according to claim 1, wherein Ar² is an aromatic ring having an aromatic hydrocarbon ring and/or an aromatic heterocycle.

3. The resist underlayer film-forming composition according to claim 2, wherein
the aromatic hydrocarbon ring is an aromatic hydrocarbon ring including a benzene structure, a naphthalene structure, an anthracene structure, a pyrene structure, a phenanthrene structure, a fluorene structure, a benzofluorene structure, or a dibenzofluorene structure, and
the aromatic heterocycle is an aromatic heterocycle including an indole structure, a phenylindole structure, a carbazole structure, an indolocarbazole structure, a furan structure, a thiophene structure, a pyrrole structure, or a phenothiazine structure.

4. The resist underlayer film-forming composition according to claim 2, wherein
the aromatic hydrocarbon ring is benzene, naphthalene, anthracene, pyrene, phenanthrene, fluorene, benzofluorene, or dibenzofluorene, and
the aromatic heterocycle is any one selected from among indole, phenylindole, carbazole, indolocarbazole, furan, thiophene, pyrrole, and phenothiazine.

5. The resist underlayer film-forming composition according to claim 1, wherein Ar² is an aromatic ring having an aromatic hydrocarbon ring and/or an aromatic heterocycle substituted with —CH₂—OR¹² (wherein R¹² is a hydrogen atom or a linear, branched, or cyclic alkyl group that has a carbon atom number of 1 to 20 and that arbitrarily contains a heteroatom such as a nitrogen atom, an oxygen atom, or a sulfur atom).

6. The resist underlayer film-forming composition according to claim 5, wherein R¹² is a hydrogen atom or a methyl group.

7. The resist underlayer film-forming composition according to claim 5, wherein
the aromatic hydrocarbon ring is an aromatic hydrocarbon ring including a benzene structure, a naphthalene structure, an anthracene structure, a pyrene structure, a phenanthrene structure, a fluorene structure, a benzofluorene structure, or a dibenzofluorene structure, and
the aromatic heterocycle is an aromatic heterocycle including an indole structure, a phenylindole structure, a carbazole structure, an indolocarbazole structure, a furan structure, a thiophene structure, a pyrrole structure, or a phenothiazine structure.

8. The resist underlayer film-forming composition according to claim 5, wherein
the aromatic hydrocarbon ring is benzene, naphthalene, anthracene, pyrene, phenanthrene, fluorene, benzofluorene, or dibenzofluorene, and
the aromatic heterocycle is any one selected from among indole, phenylindole, carbazole, indolocarbazole, furan, thiophene, pyrrole, and phenothiazine.

9. The resist underlayer film-forming composition according to claim 1, wherein the novolac resin is a novolac resin that has a repeating composite unit structure A-B of the following Formula (AB) and further has a side chain having a structure of Formula (D): 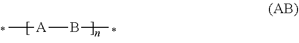
(in Formula (AB),
n is the number of composite unit structures A-B,
a unit structure A includes a phenol unit structure and/or an amine unit structure,
a unit structure B is one or two or more unit structures each including a structure of the following Formula (B1), (B2), or (B3), and
an asterisk * denotes a bond); 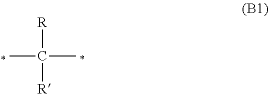
[in Formula (B1),
R and R′ are each independently a hydrogen atom, a C₆₋₃₀ aromatic ring residue that arbitrarily has a substituent, a C₃₋₃₀ heterocycle residue that arbitrarily has a substituent, or a linear, branched, or cyclic alkyl group that has a carbon atom number of 10 or less and arbitrarily has a substituent, and
an asterisk * denotes a bond];
*-J¹-Z⁰-J²-* (B2)
[in Formula (B2),
Z⁰ is a C₆₋₃₀ aromatic ring residue that arbitrarily has a substituent, an aliphatic ring residue, or an organic group in which two aromatic ring residues or aliphatic ring residues are linked by a single bond,
J¹ and J² are each independently a direct bond or a divalent organic group that arbitrarily has a substituent, and
an asterisk * denotes a bond]; 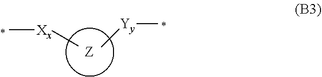
[in Formula (B3),
Z is a C₄₋₂₅ monocycle that arbitrarily has a substituent or a C₄₋₂₅ bicyclic, tricyclic, or tetracyclic condensed ring that arbitrarily has a substituent, the monocycle is a non-aromatic monocycle, at least one monocycle constituting the bicyclic, tricyclic, or tetracyclic condensed ring is a non-aromatic monocycle and a residual monocycle is an aromatic monocycle or a non-aromatic monocycle, the monocycle or the bicyclic, tricyclic, or tetracyclic condensed ring is arbitrarily further condensed with one or more aromatic rings to form a pentacyclic or higher polycyclic condensed ring,
X and Y are same or different from each other and are each a —CR¹R² group in which R¹ and R² are same or different from each other and are each a hydrogen atom or a C₁₋₆ hydrocarbon group,
x and y are respectively the number of Xs and the number of Ys and are each independently 0 or 1,
*—Xₓ
binds to any one of carbon atoms (referred to as a “carbon atom 1”) constituting the non-aromatic monocycle of Z (when x=1) or extends from the carbon atom 1 (when x=0),
Y_{y}—*
binds to any one of carbon atoms (referred to as a “carbon atom 2”) constituting the non-aromatic monocycle of Z (when y=1) or extends from the carbon atom 2 (when y=0),
the carbon atom 1 and the carbon atom 2 are arbitrarily same or different from each other, and when the carbon atom 1 and the carbon atom 2 are different, the carbon atom 1 and the carbon atom 2 arbitrarily belong to a same non-aromatic monocycle or different non-aromatic monocycles, and
an asterisk * denotes a bond].

10. The resist underlayer film-forming composition according to claim 9, wherein
the phenol unit structure is a chemical structure having at least one aromatic ring that is selected from among a benzene ring, a naphthalene ring, an anthracene ring, a pyrene ring, a fluorene ring, a benzofluorene ring, and a dibenzofluorene ring and that has at least one hydroxyl group bound to the aromatic ring, and
the aromatic rings are arbitrarily condensed with each other or arbitrarily bound to each other by a single bond or a linear, branched, or cyclic alkyl group having a carbon atom number of 1 to 8.

11. The resist underlayer film-forming composition according to claim 9, wherein
the phenol unit structure includes a structure derived from at least one monomer selected from the group consisting of monomers of the following Formulas 1 to 36 that each arbitrarily have a substituent, and
H in OH in Formulas 1 to 36 is arbitrarily replaced with any one of substituents shown below. 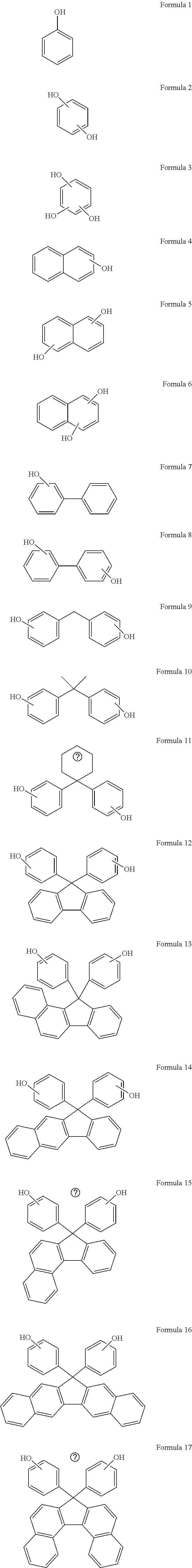 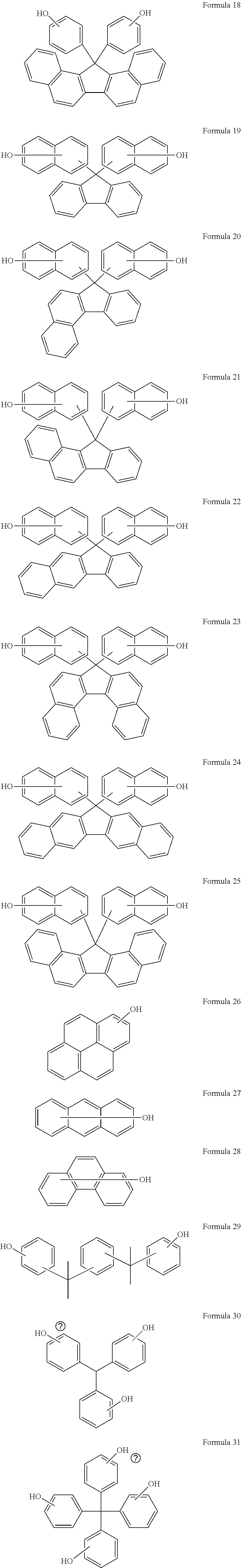 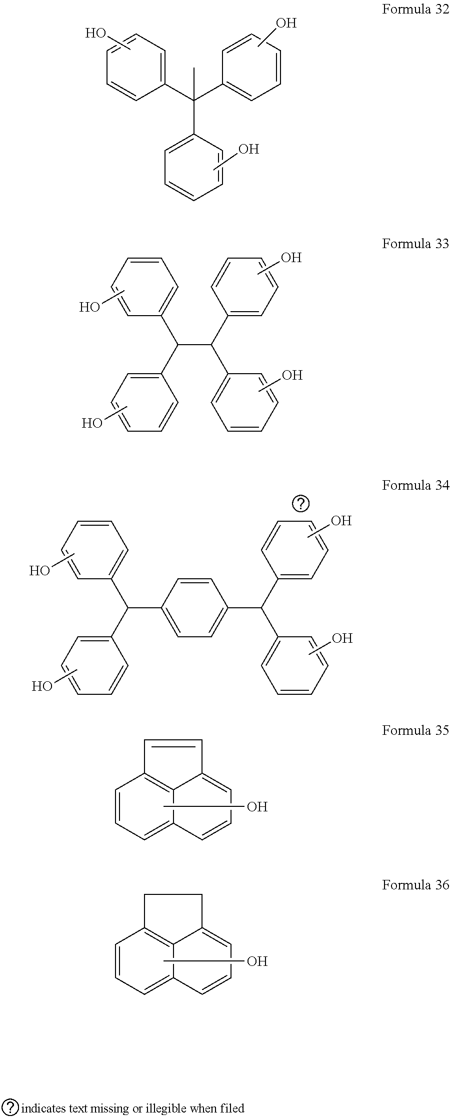
Substituents 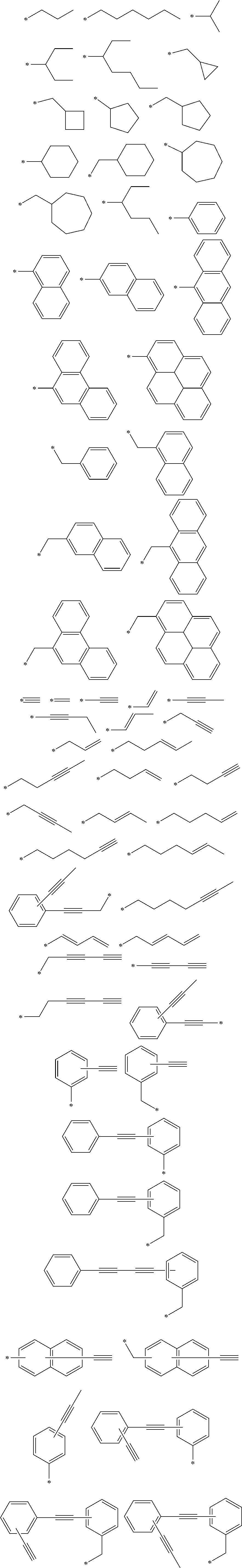 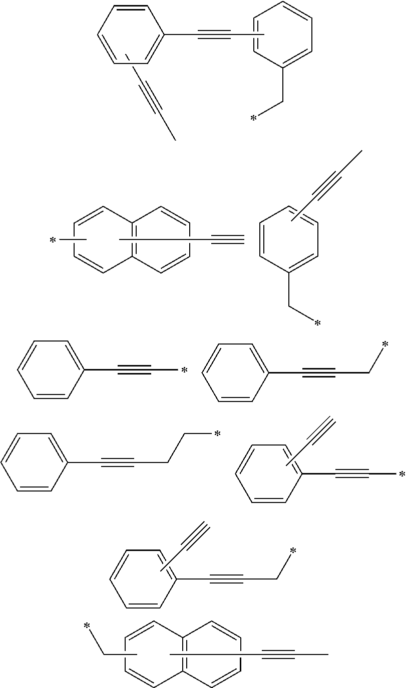
An asterisk * denotes a bond.
Substituents 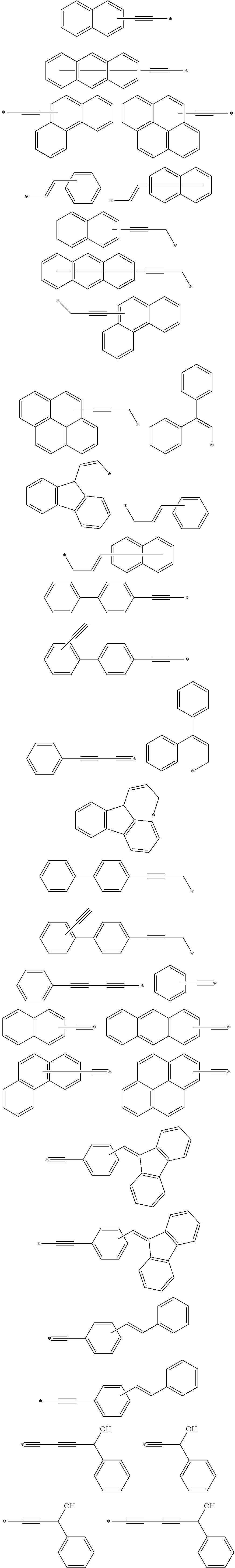 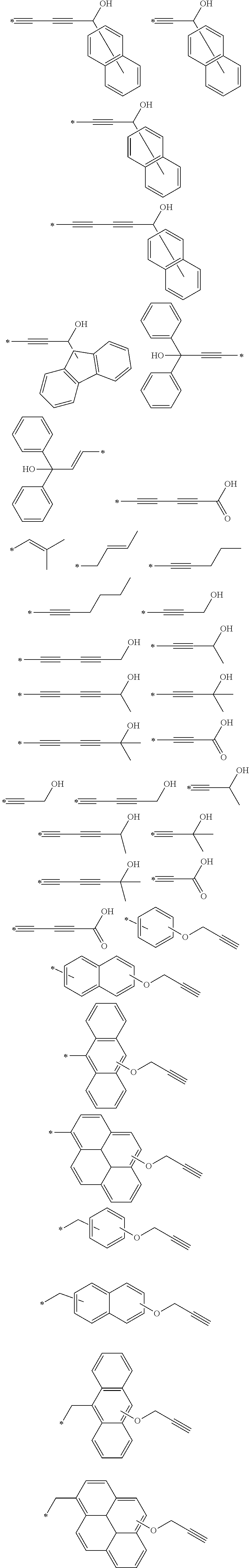
An asterisk * denotes a bond.

12. The resist underlayer film-forming composition according to claim 9, wherein the amine unit structure is a chemical structure having at least one heterocycle selected from among a pyrrole ring, an indole ring, and a carbazole ring or a unit structure in which two or more benzene rings or two or more naphthalene rings as aromatic rings are bound to each other through a nitrogen atom or the heterocycle and an aromatic ring are condensed with each other or the heterocycle and an aromatic ring are bound through a single bond, a quaternary carbon, or a C₅₋₇ aliphatic ring or condensed with each other.

13. The resist underlayer film-forming composition according to claim 9, wherein
the amine unit structure includes a structure derived from at least one monomer selected from the group consisting of monomers of the following Formulas 37 to 75 that each arbitrarily have a substituent, and
H in NH in Formulas 37 to 75 is replaced with any one of substituents shown below. 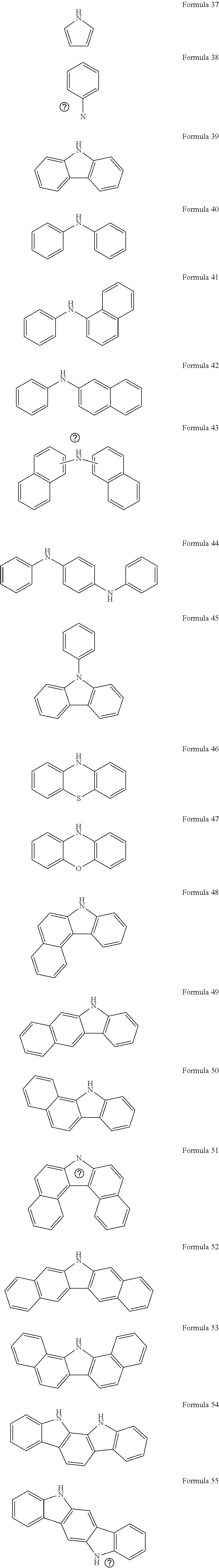 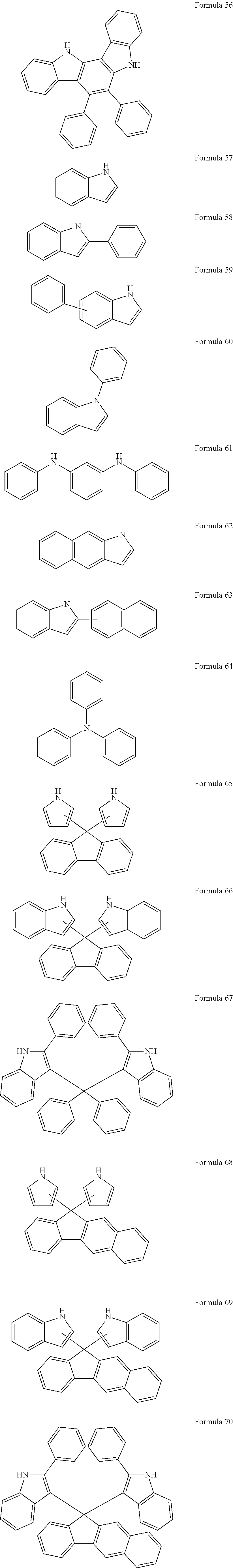 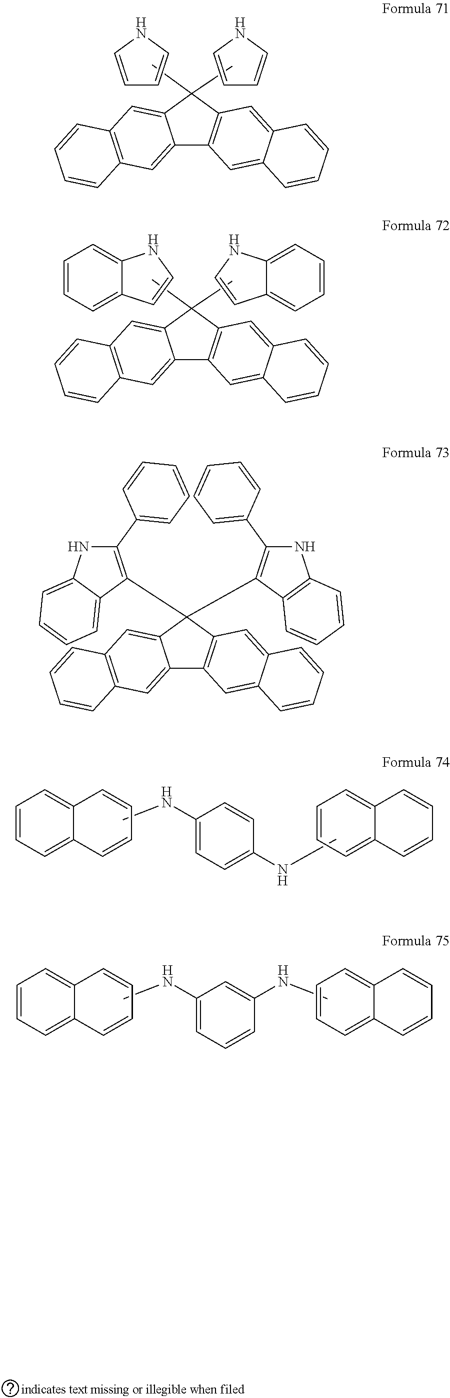
Substituents 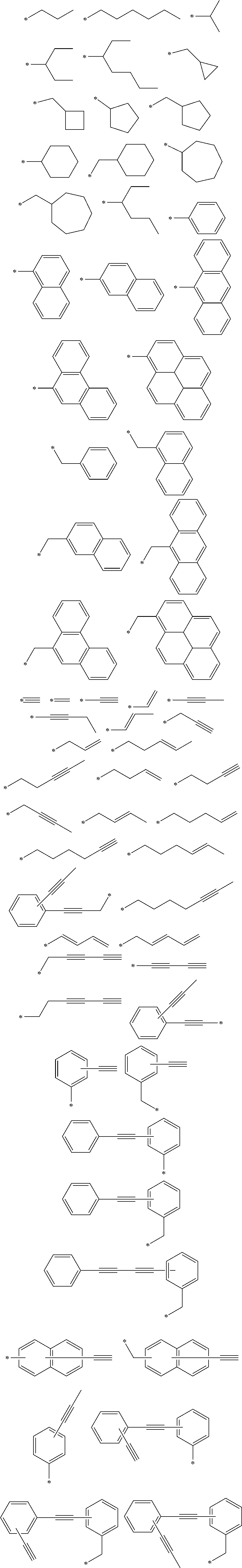 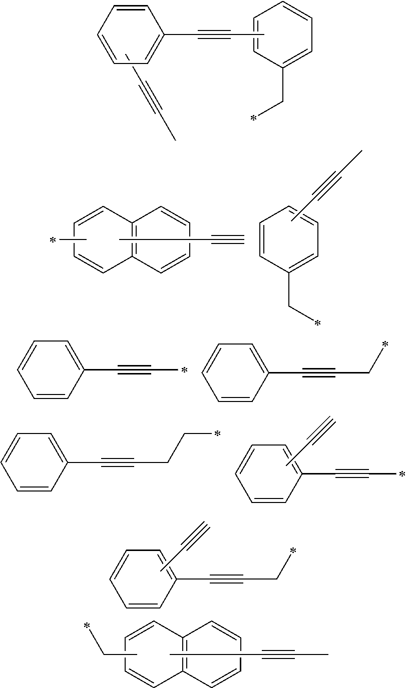
An asterisk * denotes a bond.
Substituents 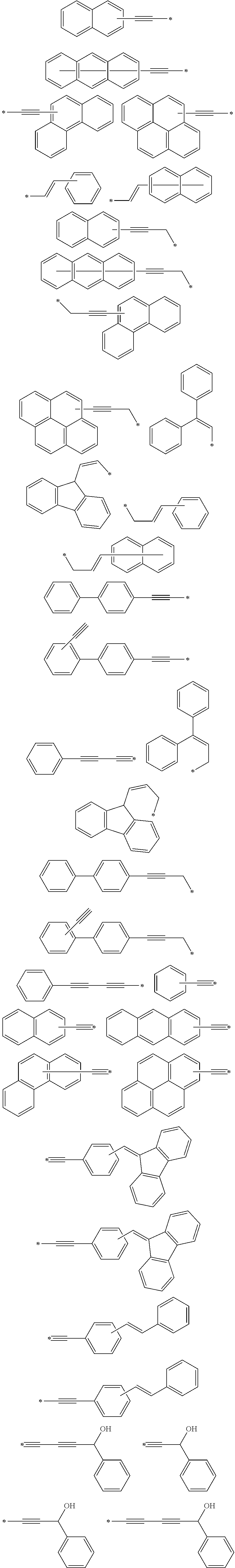 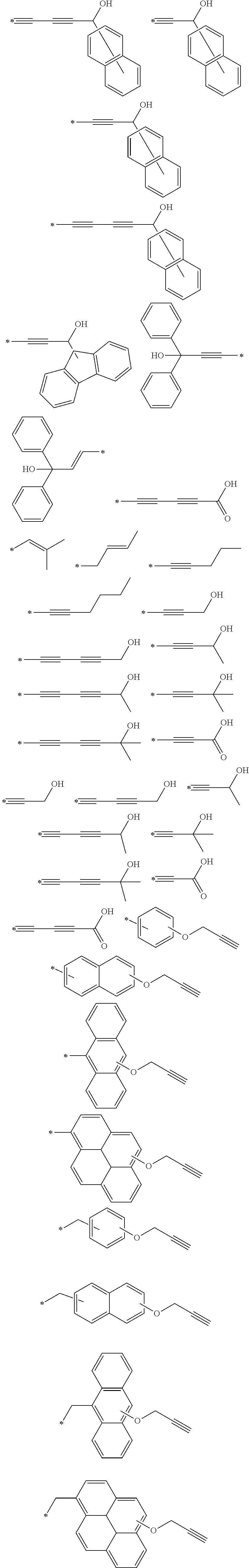
An asterisk * denotes a bond.

14. The resist underlayer film-forming composition according to claim 1, wherein the solvent is a solvent having a boiling point of 160° C., or more.

15. The resist underlayer film-forming composition according to claim 1, further comprising a crosslinking agent.

16. The resist underlayer film-forming composition according to claim 15, wherein the crosslinking agent is an aminoplast crosslinking agent or a phenoplast crosslinking agent.

17. The resist underlayer film-forming composition according to claim 1, further comprising a surfactant.

18. The resist underlayer film-forming composition according to claim 1, further comprising an acid and/or a salt of the acid and/or an acid generator.

19. A resist underlayer film obtained by baking a coating film formed of the composition according to claim 1.

20. A method for forming a resist pattern for use in production of a semiconductor, the method comprising the step of applying the resist underlayer film-forming composition according to claim 1 onto a semiconductor substrate and baking the composition to form a resist underlayer film.

21. A method for producing a semiconductor device, the method comprising the steps of:
forming a resist underlayer film on a semiconductor substrate with use of the resist underlayer film-forming composition according to claim 1;
forming a resist film on the resist underlayer film;
forming a resist pattern in the resist film;
subjecting the resist underlayer film to etching using the resist pattern; and
subjecting the semiconductor substrate to processing using the patterned resist underlayer film.

22. The method for producing a semiconductor device according to claim 21, wherein the forming of a resist pattern in the resist film is performed by light or electron beam irradiation and development.

23. The method for producing a semiconductor device according to claim 21, wherein the forming of a pattern in the resist film is performed by nanoimprinting or a self-assembled film.

24. A method for producing a semiconductor device, the method comprising the steps of:
forming a resist underlayer film on a semiconductor substrate with use of the resist underlayer film-forming composition according to claim 1;
forming a hard mask on the resist underlayer film;
further forming a resist film on the hard mask;
forming a resist pattern in the resist film;
subjecting the hard mask to etching using the resist pattern;
subjecting the resist underlayer film to etching using the patterned hard mask; and
subjecting the semiconductor substrate to processing using the patterned resist underlayer film.

25. The method for producing a semiconductor device according to claim 24, wherein the hard mask is formed by application of an inorganic material or vapor deposition of an inorganic material.

26. The method for producing a semiconductor device according to claim 24, wherein the forming of a resist pattern in the resist film is performed by light or electron beam irradiation and development.

27. The method for producing a semiconductor device according to claim 24, wherein the forming of a pattern in the resist film is performed by nanoimprinting or a self-assembled film.

28. A method for producing a semiconductor device, the method comprising the steps of:
forming a resist underlayer film on a semiconductor substrate with use of the resist underlayer film-forming composition according to claim 1;
forming a hard mask on the resist underlayer film;
further forming a resist film on the hard mask;
forming a resist pattern in the resist film;
subjecting the hard mask to etching using the resist pattern;
subjecting the resist underlayer film to etching using the patterned hard mask;
removing the hard mask; and
subjecting the semiconductor substrate to processing using the patterned resist underlayer film.

29. The method for producing a semiconductor device according to claim 28, wherein the hard mask is formed by application of a composition containing an inorganic material or vapor deposition of a composition containing an inorganic material.

30. The method for producing a semiconductor device according to claim 28, wherein the forming of a resist pattern in the resist film is performed by light or electron beam irradiation and development.

31. The method for producing a semiconductor device according to claim 28, wherein the forming of a pattern in the resist film is performed by nanoimprinting or a self-assembled film.

32. The method for producing a semiconductor device according to claim 28, wherein the removing of the hard mask is performed by etching or an alkali solution.

33. A method for producing a semiconductor device, the method comprising the steps of:
forming a resist underlayer film on a semiconductor substrate with use of the resist underlayer film-forming composition according to claim 1;
forming a hard mask on the resist underlayer film;
further forming a resist film on the hard mask;
forming a resist pattern in the resist film;
subjecting the hard mask to etching using the resist pattern;
subjecting the resist underlayer film to etching using the patterned hard mask;
removing the hard mask;
forming a vapor-deposited film (spacer) on the resist underlayer film after removing the hard mask;
processing the vapor-deposited film (spacer) by etching;
removing the patterned resist underlayer film such that that the patterned vapor-deposited film (spacer) remains; and
subjecting the semiconductor substrate to processing using the patterned vapor-deposited film (spacer).

34. The method for producing a semiconductor device according to claim 33, wherein the hard mask is formed by application of a composition containing an inorganic material or vapor deposition of a composition containing an inorganic material.

35. The method for producing a semiconductor device according to claim 33, wherein the forming of a resist pattern in the resist film is performed by light or electron beam irradiation and development.

36. The method for producing a semiconductor device according to claim 33, wherein the forming of a pattern in the resist film is performed by nanoimprinting or a self-assembled film.

37. The method for producing a semiconductor device according to claim 33, wherein the removing of the hard mask is performed by etching or an alkali solution.
